(19) United States
(12) Patent Application Publication
(10) Pub. No.: US 2010/0159392 A1
(43) Pub. Date: Jun. 24, 2010

(54) PATTERNING PROCESS AND RESIST COMPOSITION

(75) Inventors: Jun Hatakeyama, Joetsu-shi (JP); Takeru Watanabe, Joetsu-shi (JP); Masashi Iio, Joetsu-shi (JP); Kazuhiro Katayama, Joetsu-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SHIN-ETSU CHEMICAL CO., LTD., Tokyo (JP)

(21) Appl. No.: 12/639,621

(22) Filed: Dec. 16, 2009

(30) Foreign Application Priority Data
Dec. 22, 2008 (JP) 2008-325000
Apr. 17, 2009 (JP) 2009-100954

(51) Int. Cl. G03F 7/004; G03F 7/20

(52) U.S. Cl. 430/286.1; 430/326

(57) ABSTRACT

A pattern is formed by coating a first positive resist composition comprising a copolymer comprising lactone-containing recurring units and acid labile group-containing recurring units onto a substrate to form a first resist film, patternwise exposure, PEB, and development to form a first resist pattern, applying an amine or oxazoline compound to the first resist pattern for inactivation, coating a second positive resist composition comprising a C₃-C₈ alcohol and an optional C₆-C₁₂ ether onto the first resist pattern-bearing substrate to form a second resist film, patternwise exposure, PEB, and development to form a second resist pattern.

### CROSS-REFERENCE TO RELATED APPLICATION

This non-provisional application claims priority under 35 U.S.C. §119(a) on Patent Application Nos. 2008-325000 and 2009-100954 filed in Japan on Dec. 22, 2008 and Apr. 17, 2009, respectively, the entire contents of which are hereby incorporated by reference.

### TECHNICAL FIELD

This invention relates to a patterning process involving the steps of forming a first resist pattern from a first resist film through exposure and development, applying an amine or oxazoline compound onto the first pattern for inactivation to acid, coating a second positive resist composition comprising a solvent containing a C₃-C₈ alcohol and an optional C₆-C₁₂ ether and not dissolving away the first resist pattern, and forming a second resist pattern in a selected area of the first resist pattern where no pattern features are formed, thereby reducing the distance between pattern features. It also relates to a resist composition used in the process.

### BACKGROUND ART

In the recent drive for higher integration and operating speeds in LSI devices, the pattern rule is made drastically finer. The photolithography which is currently on widespread use in the art is approaching the essential limit of resolution determined by the wavelength of a light source. As the light source used in the lithography for resist pattern formation, g-line (436 nm) or i-line (365 nm) from a mercury lamp was widely used in 1980's. Reducing the wavelength of exposure light was believed effective as the means for further reducing the feature size. For the mass production process of 64 MB dynamic random access memories (DRAM, processing feature size 0.25 μm or less) in 1990's and later ones, the exposure light source of i-line (365 nm) was replaced by a KrF excimer laser having a shorter wavelength of 248 nm. However, for the fabrication of DRAM with a degree of integration of 256 MB and 1 GB or more requiring a finer patterning technology (processing feature size 0.2 μm or less), a shorter wavelength light source was required. Over a decade, photolithography using ArF excimer laser light (193 nm) has been under active investigation. It was expected at the initial that the ArF lithography would be applied to the fabrication of 180-nm node devices. However, the KrF excimer lithography survived to the mass-scale fabrication of 130-nm node devices. So, the full application of ArF lithography started from the 90-nm node. The ArF lithography combined with a lens having an increased numerical aperture (NA) of 0.9 is considered to comply with 65-nm node devices. For the next 45-nm node devices which required an advancement to reduce the wavelength of exposure light, the F₂ lithography of 157 nm wavelength became a candidate. However, for the reasons that the projection lens uses a large amount of expensive CaF₂ single crystal, the scanner thus becomes expensive, hard pellicles are introduced due to the extremely low durability of soft pellicles, the optical system must be accordingly altered, and the etch resistance of resist is low; the postponement of F₂ lithography and the early introduction of ArF immersion lithography were advocated (see Proc. SPIE, Vol. 4690 xxix, 2002).

In the ArF immersion lithography, the space between the projection lens and the wafer is filled with water. Since water has a refractive index of 1.44 at 193 nm, pattern formation is possible even using a lens having a numerical aperture (NA) of 1.0 or greater. Theoretically, it is possible to increase the NA to nearly 1.44. It was initially recognized that the resolution could be degraded and the focus be shifted by a variation of water's refractive index with a temperature change. The problem of refractive index variation could be solved by controlling the water temperature within a tolerance of 1/100° C. while it was recognized that the impact of heat from the resist film upon light exposure drew little concern. There was a likelihood that micro-bubbles in water could be transferred to the pattern. It was found that the risk of bubble generation is obviated by thorough deaeration of water and the risk of bubble generation from the resist film upon light exposure is substantially nil. At the initial phase in 1980's of the immersion lithography, a method of immersing an overall stage in water was proposed. Later proposed was a partial-fill method of using a water feed/drain nozzle for introducing water only between the projection lens and the wafer so as to comply with the operation of a high-speed scanner. In principle, the immersion technique using water enabled lens design to a NA of 1 or greater. In optical systems based on traditional refractive index materials, this leads to giant lenses, which would deform by their own weight. For the design of more compact lenses, a catadioptric system was proposed, accelerating the lens design to a NA of 1.0 or greater. A combination of a lens having NA of 1.2 or greater with strong resolution enhancement technology suggests a way to the 45-nm node (see Proc. SPIE, Vol. 5040, p 724, 2003). Efforts have also been made to develop lenses of NA 1.35.

One candidate for the 32-nm node lithography is lithography using extreme ultraviolet (EUV) radiation with wavelength 13.5 nm. The EUV lithography has many accumulative problems to be overcome, including increased laser output, increased sensitivity, increased resolution and minimized line edge roughness (LER) of resist film, defect-free MoSi laminate mask, reduced aberration of reflection mirror, and the like.

The water immersion lithography using a NA 1.35 lens achieves an ultimate resolution of 40 to 38 nm at the maximum NA, but cannot reach 32 nm. Efforts have been made to develop higher refractive index materials in order to further increase NA. It is the minimum refractive index among projection lens, liquid, and resist film that determines the NA limit of lenses. In the case of water immersion, the refractive index of water is the lowest in comparison with the projection lens (refractive index 1.5 for synthetic quartz) and the resist film (refractive index 1.7 for prior art methacrylate-based film). Thus the NA of projection lens is determined by the refractive index of water. Recent efforts succeeded in developing a highly transparent liquid having a refractive index of 1.65. In this situation, the refractive index of projection lens made of synthetic quartz is the lowest, suggesting a need to develop a projection lens material with a higher refractive index. LuAG (lutetium aluminum garnet Lu₃Al₅O₁₂) having a refractive index of at least 2 is the most promising material, but has the problems of birefringence and noticeable absorption. Even if a projection lens material with a refractive index of 1.8 or greater is developed, the liquid with a refractive index of 1.65 limits the NA to 1.55 at most, failing in resolution of 32 nm. For resolution of 32 nm, a liquid with a refractive index of 1.8 or greater is necessary. Such a liquid material has not been discovered because a tradeoff between absorption and refractive index is recognized in the art. In the case of alkane compounds, bridged cyclic compounds are preferred to linear ones in order to increase the refractive index, but the cyclic compounds undesirably have too high a viscosity to follow high-speed scanning on the exposure tool stage. If a liquid with a refractive index of 1.8 is developed, then the component having the lowest refractive index is the resist film, suggesting a need to increase the refractive index of a resist film to 1.8 or higher.

The process that now draws attention under the above-discussed circumstances is a double patterning process involving a first set of exposure and development to form a first pattern and a second set of exposure and development to form a pattern between features of the first pattern. See Proc. SPIE, Vol. 5992, 59921Q-1-16 (2005). A number of double patterning processes are proposed. One exemplary process involves a first set of exposure and development to form a photoresist pattern having lines and spaces at intervals of 1:3, processing the underlying layer of hard mask by dry etching, applying another layer of hard mask thereon, a second set of exposure and development of a photoresist film to form a line pattern in the spaces of the first exposure, and processing the hard mask by dry etching, thereby forming a line-and-space pattern at a half pitch of the first pattern. An alternative process involves a first set of exposure and development to form a photoresist pattern having spaces and lines at intervals of 1:3, processing the underlying layer of hard mask by dry etching, applying a photoresist layer thereon, a second set of exposure and development to form a second space pattern on the remaining hard mask portion, and processing the hard mask by dry etching. In either process, the hard mask is processed by two dry etchings.

While the former process requires two applications of hard mask, the latter process uses only one layer of hard mask, but requires to form a trench pattern which is difficult to resolve as compared with the line pattern. The latter process includes the use of a negative resist material in forming the trench pattern. This allows for use of high contrast light as in the formation of lines as a positive pattern. However, since the negative resist material has a lower dissolution contrast than the positive resist material, a comparison of the formation of lines from the positive resist material with the formation of a trench pattern of the same size from the negative resist material reveals that the resolution achieved with the negative resist material is lower. After a wide trench pattern is formed from the positive resist material by the latter process, there may be applied a thermal flow method of heating the substrate for shrinkage of the trench pattern, or a RELACS method of coating a water-soluble film on the trench pattern as developed and heating to induce crosslinking at the resist film surface for achieving shrinkage of the trench pattern. These have the drawbacks that the proximity bias is degraded and the process is further complicated, leading to reduced throughputs.

Both the former and latter processes require two etchings for substrate processing, leaving the issues of a reduced throughput and deformation and misregistration of the pattern by two etchings.

One method that proceeds with a single etching is by using a negative resist material in a first exposure and a positive resist material in a second exposure. Another method is by using a positive resist material in a first exposure and a negative resist material in an alcohol that does not dissolve away the positive resist material in a second exposure. Since negative resist materials with low resolution are used, these methods entail degradation of resolution (see JP-A 2008-078220).

If first exposure is followed by second exposure at a half-pitch shifted position, the optical energy of second exposure offsets the optical energy of first exposure so that the contrast becomes zero. If a contrast enhancement layer (CEL) is formed on the resist film, the incident light to the resist film becomes nonlinear so that the first and second exposures do not offset each other. Thus an image having a half pitch is formed. See Jpn. J. Appl. Phy. Vol. 33 (1994) p 6874-6877. It is expected that similar effects are produced by using an acid generator capable of two photon absorption to provide a nonlinear contrast.

The critical issue associated with double patterning is an overlay accuracy between first and second patterns. Since the magnitude of misregistration is reflected by a variation of line size, an attempt to form 32-nm lines at an accuracy of 10%, for example, requires an overlay accuracy within 3.2 nm. Since currently available scanners have an overlay accuracy of the order of 8 nm, a significant improvement in accuracy is necessary.

Now under investigation is the resist pattern freezing technology involving forming a first resist pattern on a substrate, taking any suitable means for insolubilizing the resist pattern with respect to the resist solvent and alkaline developer, applying a second resist thereon, and forming a second resist pattern in space portions of the first resist pattern. With this freezing technology, etching of the substrate is required only once, leading to improved throughputs and avoiding the problem of misregistration due to stress relaxation of the hard mask during etching.

With respect to the freezing technology, a number of reports have been published. Known are thermal insolubilization (Proc. SPIE Vol. 6923, p 69230G (2008)); coating of a cover film and thermal insolubilization (Proc. SPIE Vol. 6923, p 69230H (2008)); insolubilization by irradiation of light having an extremely short wavelength, for example, 172 nm wavelength (Proc. SPIE Vol. 6923, p 692321 (2008)); insolubilization by ion implantation (Proc. SPIE Vol. 6923, p 692322 (2008)); insolubilization through formation of thin-film oxide film by CVD; insolubilization by light irradiation and special gas treatment (Proc. SPIE Vol. 6923, p 69233C1 (2008)); insolubilization of a resist pattern by treatment of resist pattern surface with a metal alkoxide or metal halide (e.g., titanium, zirconium or aluminum) or an isocyanate-containing silane compound (JP-A 2008-033174); insolubilization of a resist pattern by coating its surface with water-soluble resin (JP-A 2008-083537); insolubilization by ethylene diamine gas and baking (J. Photopolym. Sci. Technol., Vol. 21, No. 5, p 655 (2008)); and insolubilization by coating of an amine-containing solution and hard-baking for crosslinking (WO 2008/070060).

With respect to the freezing technology, one basic idea is proposed in WO 2008/059440. JP-A 2008-192774 discloses a method including insolubilizing a first resist pattern by application of radiation and heat, coating the insolubilized pattern with a resist solution comprising a base polymer comprising recurring units having hexafluoroalcohol groups and acid labile groups in an alcohol solvent, and forming a second resist pattern therefrom. These insolubilization treatments give rise to problems of pattern deformation, film slimming, and size narrowing or widening, which must be overcome.

Citation List

| | |
|---|---|
| Patent Document 1: | JP-A 2008-033174 |
| Patent Document 2: | JP-A 2008-083537 |
| Patent Document 3: | WO 2008/070060 |
| Patent Document 4: | WO 2008/059440 |
| Patent Document 5: | JP-A 2008-192774 |
| Patent Document 6: | JP-A 2008-078220 |
| Non-Patent Document 1: | Proc. SPIE, Vol. 4690, xxix, |
| | 2002 |
| Non-Patent Document 2: | Proc. SPIE, Vol. 5040, p724, |
| | 2003 |
| Non-Patent Document 3: | Proc. SPIE, Vol. 5992, |
| | 59921Q-1-16, 2005 |
| Non-Patent Document 4: | Jpn. J. Appl. Phy., Vol. 33 |
| | (1994), p6874-6877 |
| Non-Patent Document 5: | Proc. SPIE, Vol. 6923, p69230G |
| | (2008) |
| Non-Patent Document 6: | Proc. SPIE, Vol. 6923, p69230H |
| | (2008) |
| Non-Patent Document 7: | Proc. SPIE, Vol. 6923, p692321 |
| | (2008) |
| Non-Patent Document 8: | Proc. SPIE, Vol. 6923, p692322 |
| | (2008) |
| Non-Patent Document 9: | Proc. SPIE, Vol. 6923, p69233C1 |
| | (2008) |
| Non-Patent Document 10: | J. Photopolym. Sci. Technol., |
| | Vol. 21, No. 5, p655 (2008) |

### SUMMARY OF INVENTION

It is understood that when substrate processing is carried out by double dry etchings using resist patterns fabricated by double exposures and developments, the throughput is reduced to one half. Also an issue of pattern misregistration by dry etchings occurs.

The above-mentioned methods of insolubilizing a resist pattern utilize high temperature and light irradiation which cause the pattern to be deformed due to shrinkage. Upon heating and irradiation, the resist pattern undesirably experiences a reduction in pattern height or line width and longitudinal shrinkage.

Therefore, an object of the invention is to provide a pattern forming process in order to enable a double patterning process of processing a substrate by a single dry etching; specifically a pattern forming process comprising coating a first positive resist composition comprising a copolymer comprising recurring units having lactone as an adhesive group and recurring units having an acid labile group, effecting first exposure and development to form a first resist pattern, applying an amine or oxazoline compound to the first resist pattern to inactivate it to acid, coating a second positive resist composition comprising an alcohol of 3 to 8 carbon atoms and an optional ether of 6 to 12 carbon atoms as a solvent onto the first resist pattern, and effecting second exposure and development to form a second resist pattern, wherein the inactivation treatment prevents intermixing between the first and second resist films and also prevents the first resist pattern from being dissolved in the second developer even when the acid is generated in the first resist pattern upon second exposure.

Another object of the invention is to provide a resist composition for use in the pattern forming process.

In a first aspect, the invention provides a process for forming a pattern, comprising the steps of coating a first positive resist composition comprising a copolymer comprising recurring units having lactone as an adhesive group and recurring units having an acid labile group onto a substrate to form a first resist film, exposing the first resist film to high-energy radiation, post-exposure baking, and developing the first resist film with a developer to form a first resist pattern; inactivating the first resist pattern to acid; coating a second positive resist composition comprising a solvent which contains an alcohol of 3 to 8 carbon atoms and an optional ether of 6 to 12 carbon atoms and which does not dissolve away the first resist pattern onto the first resist pattern-bearing substrate to form a second resist film, exposing the second resist film to high-energy radiation, post-exposure baking, and developing the second resist film with a developer to form a second resist pattern. The step of inactivating the first resist pattern to acid includes applying an amine or oxazoline compound to the first resist pattern; or applying an amine or oxazoline compound to the first resist pattern to inactivate it to acid and baking to remove the excess amine or oxazoline compound; or applying an amine or oxazoline compound to the first resist pattern to inactivate it to acid, baking, and applying a solution selected from the group consisting of water, aqueous alkaline developer, an alcohol of 3 to 8 carbon atoms and an ether of 6 to 12 carbon atoms to remove the excess amine or oxazoline compound,

In a preferred embodiment, the step of applying an amine or oxazoline compound to the first resist pattern includes spin coating a solution containing the amine or oxazoline compound onto the first resist pattern or spraying a vapor containing the amine or oxazoline compound to the first resist pattern.

In a preferred embodiment, the process may further comprise the step of irradiating the first resist pattern with radiation having a wavelength of 140 to 400 nm, prior to the step of applying an amine or oxazoline compound to the first resist pattern for inactivating the resulting acid.

In a preferred embodiment, the first resist pattern includes spaces where no pattern features are formed, and the second resist pattern is formed in the spaces of the first resist pattern, thereby reducing the distance between the first and second pattern features. In another preferred embodiment, the first resist pattern crosses the second resist pattern. In a further preferred embodiment, the second resist pattern is formed in an area where the first resist pattern is not formed and in a different direction from the first resist pattern.

In a preferred embodiment, one or both of the exposure steps to form the first and second resist patterns are by immersion lithography using water.

In a preferred embodiment, the second positive resist composition comprises a base polymer having a 2,2,2-trifluoro-1-hydroxyethyl group.

In a more preferred embodiment, the base polymer in the second positive resist composition comprises recurring units having a 2,2,2-trifluoro-1-hydroxyethyl group, represented by the general formula (1):

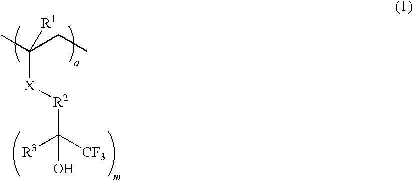

wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², and m is 1 or 2.

In a further preferred embodiment, the base polymer in the second positive resist composition is a copolymer comprising recurring units (a) having a 2,2,2-trifluoro-1-hydroxyethyl group and recurring units (b) having an acid labile group, represented by the general formula (2):

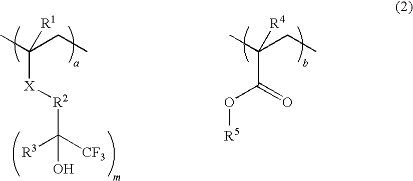

wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², R⁴ is hydrogen or methyl, R⁵ is an acid labile group, m is 1 or 2, a and b are numbers in the range: 0<a<1.0, 0<b<1.0, and 0<a+b≦1.0.

In a still further preferred embodiment, the base polymer in the second positive resist composition is a copolymer comprising recurring units (a) having a 2,2,2-trifluoro-1-hydroxyethyl group, recurring units (b) having an acid labile group, and recurring units (c−1) having a hydroxynaphthyl group, represented by the general formula (3):

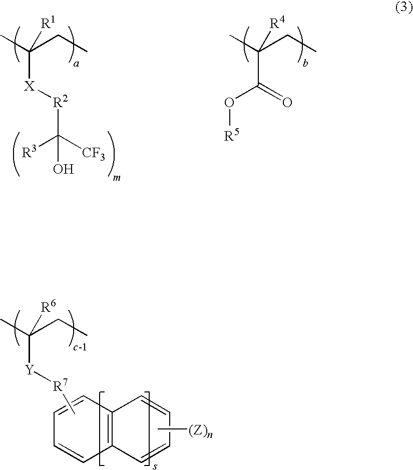

wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², R⁴ is hydrogen or methyl, R⁵ is an acid labile group, R⁶ is hydrogen or methyl, Y is a single bond or —C(═O)—O—, R⁷ is a single bond or a straight or branched C₁-C₆ alkylene group, m and n each are 1 or 2, s is 0 or 1, Z is hydroxy or carboxyl, a, b and c−1 are numbers in the range: 0<a<1.0, 0<b<1.0, 0<(c−1)<1.0, and 0<a+b+(c−1)≦1.0.

In a still further preferred embodiment, the base polymer in the second positive resist composition is a copolymer comprising recurring units (a) having a 2,2,2-trifluoro-1-hydroxyethyl group, recurring units (b) having an acid labile group, and recurring units (c−2) derived from hydroxyacenaphthylene, represented by the general formula (4):

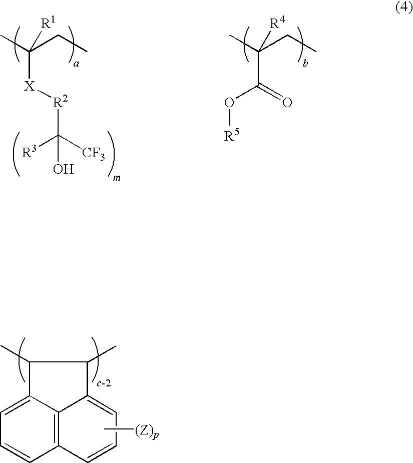

wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², R⁴ is hydrogen or methyl, R⁵ is an acid labile group, m and p each are 1 or 2, Z is hydroxy or carboxyl, a, b and c−2 are numbers in the range: 0<a<1.0, 0<b<1.0, 0<(c−2)<1.0, and 0<a+b+(c−2)≦1.0.

Specifically, the alcohol of 3 to 8 carbon atoms is selected from the group consisting of n-propanol, isopropyl alcohol, 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2,2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, 1-heptanol, cyclohexanol, and octanol, and mixtures of two or more of the foregoing.

Also specifically, the ether of 6 to 12 carbon atoms is selected from the group consisting of methyl cyclopentyl ether, methyl cyclohexyl ether, diisopropyl ether, diisobutyl ether, diisopentyl ether, di-n-pentyl ether, methyl cyclopentyl ether, methyl cyclohexyl ether, di-n-butyl ether, di-sec-butyl ether, di-sec-pentyl ether, di-tert-amyl ether, di-n-hexyl ether, anisole, 2-methylanisole, 3-methylanisole, 4-methylanisole, 2,3-dimethylanisole, 2,4-dimethylanisole, 3,4-dimethylanisole, 2,5-dimethylanisole, 2,6-dimethylanisole, 3,5-dimethylanisole, 3,6-dimethylanisole, 2,3,4-trimethylanisole, 2,3,6-trimethylanisole, 2,4,6-trimethylanisole, 2,4,5,6-tetramethylanisole, 2-ethylanisole, 3-ethylanisole, 4-ethylanisole, 2-isopropylanisole, 3-isopropylanisole, 4-isopropylanisole, 4-propylanisole, 2-butylanisole, 3-butylanisole, 4-butylanisole, 2-tert-butylanisole, 3-tert-butylanisole, 4-tert-butylanisole, pentamethylanisole, 2-vinylanisole, 3-vinylanisole, 4-methoxystyrene, ethyl phenyl ether, propyl phenyl ether, butyl phenyl ether, ethyl 3,5-xylyl ether, ethyl 2,6-xylyl ether, ethyl 2,4-xylyl ether, ethyl 3,4-xylyl ether, ethyl 2,5-xylyl ether, methyl benzyl ether, ethyl benzyl ether, isopropyl benzyl ether, propyl benzyl ether, methyl phenethyl ether, ethyl phenethyl ether, isopropyl phenethyl ether, propyl phenethyl ether, butyl phenethyl ether, vinyl phenyl ether, allyl phenyl ether, vinyl benzyl ether, allyl benzyl ether, vinyl phenethyl ether, allyl phenethyl ether, 4-ethylphenetole, and tert-butyl phenyl ether, and mixtures of two or more of the foregoing.

In the second positive resist composition, the solvent which contains an alcohol of 3 to 8 carbon atoms and an optional ether of 6 to 12 carbon atoms and which does not dissolve away the first resist pattern is preferably such that components of the second resist composition are dissolvable therein, and the first resist film experiences a slimming of not more than 10 nm when the solvent is dispensed on the first resist film for 30 seconds and then removed by spin drying and baking at a temperature not higher than 130° C.

In another aspect, the invention provides a resist composition comprising a base resin and a solvent, wherein the base resin is a copolymer comprising recurring units (a) having a 2,2,2-trifluoro-1-hydroxyethyl group and recurring units (b) having an acid labile group, represented by the general formula (2):

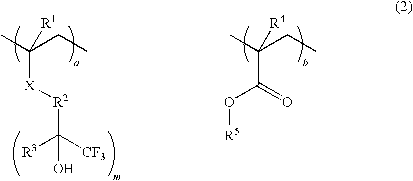

wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², R⁴ is hydrogen or methyl, R⁵ is an acid labile group, m is 1 or 2, a and b are numbers in the range: 0<a<1.0, 0<b<1.0, and 0<a+b≦1.0, and the solvent contains 50 to 98% by weight of 2-methyl-1-butanol or 3-methyl-1-butanol and 2 to 50% by weight of 1-hexanol, 1-heptanol or 1-octanol.

In a preferred embodiment, the solvent contains 50 to 98% by weight of 2-methyl-1-butanol or 3-methyl-1-butanol and 2 to 50% by weight of an ether selected from the group consisting of anisole, 2-methylanisole, 3-methylanisole, 4-methylanisole, 2,3-dimethylanisole, 2,4-dimethylanisole, 3,4-dimethylanisole, 2,5-dimethylanisole, 2,6-dimethylanisole, 3,5-dimethylanisole, 3,6-dimethylanisole, 2,3,4-trimethylanisole, 2,3,6-trimethylanisole, 2,4,6-trimethylanisole, 2,4,5,6-tetramethylanisole, 2-ethylanisole, 3-ethylanisole, 4-ethylanisole, 2-isopropylanisole, 3-isopropylanisole, 4-isopropylanisole, 4-propylanisole, 2-butylanisole, 3-butylanisole, 4-butylanisole, 2-tert-butylanisole, 3-tert-butylanisole, 4-tert-butylanisole, pentamethylanisole, 2-vinylanisole, 3-vinylanisole, 4-methoxystyrene, ethyl phenyl ether, propyl phenyl ether, butyl phenyl ether, ethyl 3,5-xylyl ether, ethyl 2,6-xylyl ether, ethyl 2,4-xylyl ether, ethyl 3,4-xylyl ether, ethyl 2,5-xylyl ether, methyl benzyl ether, ethyl benzyl ether, isopropyl benzyl ether, propyl benzyl ether, methyl phenethyl ether, ethyl phenethyl ether, isopropyl phenethyl ether, propyl phenethyl ether, butyl phenethyl ether, vinyl phenyl ether, allyl phenyl ether, vinyl benzyl ether, allyl benzyl ether, vinyl phenethyl ether, allyl phenethyl ether, 4-ethylphenetole, and tert-butyl phenyl ether.

### ADVANTAGEOUS EFFECTS OF INVENTION

The pattern forming process ensures that as a result of double patterning including two exposures, a second resist pattern can be formed in a space portion of a first resist pattern without deformation of the first resist pattern.

According to the invention, a pattern is formed by coating a first positive resist composition comprising a copolymer comprising recurring units having lactone as an adhesive group and recurring units having an acid labile group onto a substrate to form a first resist film, exposing the first resist film to high-energy radiation, post-exposure baking, and developing the first resist film with a developer to form a first resist pattern, applying an amine or oxazoline compound to the first resist pattern to inactivate it to acid, coating a second positive resist composition comprising a C₃-C₈ alcohol or a mixture of a C₃-C₈ alcohol and a C₆-C₁₂ ether as a solvent onto the first resist pattern-bearing substrate to form a second resist film, exposing the second resist film to high-energy radiation, post-exposure baking, and developing the second resist film with a developer to form a second resist pattern. When the second pattern is formed in an area of the first pattern where first pattern features are not formed, for example, this double patterning reduces the pitch between pattern features to one half. The substrate can be processed by a single dry etching.

### BRIEF DESCRIPTION OF THE DRAWINGS

FIG. 1 is a cross-sectional view of a double patterning process according one embodiment of the invention.

FIG. 1A shows a laminate of substrate, processable layer, hard mask and first resist film, FIG. 1B shows the first resist film being exposed and developed, FIG. 10 shows the first resist film being inactivated to acid, FIG. 1D shows a second resist film being formed, exposed and developed, FIG. 1E shows the hard mask being etched, and FIG. 1F shows the processable layer being etched.

FIG. 2 is a cross-sectional view of a double patterning process according one embodiment of the invention. FIG. 2A shows a first pattern being formed, and FIG. 2B shows a second pattern being formed.

FIG. 3 is a cross-sectional view of a double patterning process according another embodiment of the invention. FIG. 3A shows a first pattern being formed, and FIG. 3B shows a second pattern being formed.

FIG. 4 is a cross-sectional view illustrating one exemplary process of inactivating the first resist pattern. FIG. 4A shows the step of developing the first resist pattern, FIG. 4B shows the step of irradiating the first resist pattern as developed with radiation, FIG. 4C shows the step of coating an amine or oxazoline compound thereon and baking, and FIG. 4D shows the step of removing the amine or oxazoline compound.

FIG. 5 is a cross-sectional view illustrating another exemplary process of inactivating the first resist pattern. FIG. 5A shows the step of developing the first resist pattern, FIG. 5B shows the step of coating an amine or oxazoline compound thereon and baking, and FIG. 5C shows the step of removing the amine or oxazoline compound.

FIG. 6 is a cross-sectional view illustrating a further exemplary process of inactivating the first resist pattern. FIG. 6A shows the step of developing the first resist pattern, FIG. 6B shows the step of irradiating the first resist pattern as developed with radiation, FIG. 6C shows the step of vapor priming or spin coating an amine or oxazoline compound thereon, baking, and then removing it.

FIG. 7 is a cross-sectional view illustrating a still further exemplary process of inactivating the first resist pattern. FIG. 7A shows the step of developing the first resist pattern, FIG. 7B shows the step of vapor priming or spin coating an amine or oxazoline compound thereon, baking, and then removing it.

FIG. 8 is a cross-sectional view of an exemplary prior art double patterning process. FIG. 8A shows a laminate of substrate, processable layer, hard mask and resist film, FIG. 8B shows the resist film being exposed and developed, FIG. 8C shows the hard mask being etched, FIG. 8D shows a second resist film being formed, exposed and developed, and FIG. 8E shows the processable layer being etched.

FIG. 9 is a cross-sectional view of another exemplary prior art double patterning process. FIG. 9A shows a laminate of substrate, processable layer, 1st and 2nd hard masks and resist film, FIG. 9B shows the resist film being exposed and developed, FIG. 9C shows the 2nd hard mask being etched, FIG. 9D shows, after removal of the first resist film, a second resist film being formed, exposed and developed, FIG. 9E shows the 1st hard mask being etched, and FIG. 9F shows the processable layer being etched.

FIG. 10 is a cross-sectional view of a further exemplary prior art double patterning process. FIG. 10A shows a laminate of substrate, processable layer, hard mask and resist film, FIG. 10B shows the resist film being exposed and developed, FIG. 100 shows the hard mask being etched, FIG. 10D shows, after removal of the first resist film, a second resist film being formed, exposed and developed, FIG. 10E shows the hard mask being etched, and FIG. 10F shows the processable layer being etched.

FIG. 11 is a plan view of a resist pattern evaluated by double patterning tests I and II.

FIG. 12 is a plan view of a resist pattern evaluated by double patterning test III.

### DESCRIPTION OF THE PREFERRED EMBODIMENT

The singular forms “a,” “an” and “the” include plural referents unless the context clearly dictates otherwise. As used herein, the terminology “(Cₓ-C_{y})”, as applied to a particular unit, such as, for example, a chemical compound or a chemical substituent group, means having a carbon atom content of from “x” carbon atoms to “y” carbon atoms per such unit. As used herein, the term “film” is used interchangeably with “coating” or “layer.” The term “processable layer” is interchangeable with patternable layer and refers to a layer that can be processed such as by etching to form a pattern therein.

In connection with the double patterning lithography involving double exposures and developments to form a half-pitch pattern, the inventors made efforts to develop a positive resist material which enables to process a substrate by a single dry etching.

The inventors have discovered that a double patterning process capable of reducing the pitch between pattern features to one half can be practiced by coating a first positive resist composition on a substrate, forming a first resist pattern through exposure and development, applying an amine or oxazoline compound to the first resist pattern to inactivate it to acid, coating a second positive resist composition comprising a solvent which contains a C₃-C₈ alcohol or a mixture of a C₃-C₈ alcohol and a C₆-C₁₂ ether and which does not dissolve away the first resist pattern onto the first resist pattern-bearing substrate, and forming a second resist pattern through exposure and development while retaining the first resist pattern. Then the substrate can be processed by a single dry etching. The present invention is predicated on this discovery.

The first and second positive resist compositions are chemically amplified positive resist compositions each comprising a base polymer and a solvent. At least the first positive resist composition should not be dissolvable in the solvent of the second positive resist composition. When the first positive resist composition comprises a base polymer containing lactone as the main adhesive group, it is not dissolvable in alcohol and ether solvents. On the other hand, in order that the second positive resist composition be dissolvable in alcohol and ether solvents, the presence of weakly acidic hydroxyl groups in the base polymer of the second positive resist composition is essential. The weakly acidic hydroxyl groups include hexafluoroalcohol groups having 2,2,2-trifluoro-1-hydroxyethyl partial structure, and phenol groups. Although phenol groups cannot be used as the base polymer for resist material on account of the strong absorption at wavelength 193 nm of benzene ring, naphthol groups can be applied to the resist base polymer because the absorption peak wavelength is shifted toward the longer wavelength side.

Most methods of insolubilizing the first resist pattern which have been proposed thus far rely on heat treatment to induce crosslinking reaction for curing. The heat treatment to induce crosslinking reaction is generally at high temperatures above 140° C. If heated at temperatures above the glass transition temperature, the pattern may flow or the pattern may shrink due to deprotection of acid labile groups. Shrinkage of the pattern leads to a problem of reducing the line width, pattern height, and pattern length. To minimize pattern deformation, a means for insolubilizing the first resist pattern without resorting to heat treatment or at a sufficiently low temperature to cause no pattern deformation is desired.

Upon patternwise exposure of the second resist film to radiation, the first resist pattern is also exposed to radiation. If a solvent which does not dissolve away the first resist pattern is used in the second resist composition, this prevents intermixing with the first resist pattern or dissolution of the first resist pattern during coating of the second resist composition. However, since the acid is generated in the first resist pattern upon exposure of the second resist film, the first resist pattern can be dissolved away during development of the second resist film.

If an amine component is present in the first resist pattern and in excess relative to the acid generated upon second exposure, it neutralizes the acid generated upon second exposure, preventing the first resist pattern from being dissolved away during development of the second resist film. Usually, an amine quencher is added to photoresist material for the purposes of increasing contrast and suppressing acid diffusion, but in a smaller amount than the acid generator. In order that amine be available in a larger amount than the amount of the acid generated by the acid generator in the first resist pattern upon second exposure, it is contemplated to supply amine or oxazoline after the first resist pattern is formed by development.

The most effective measure for inactivating the acid generated in the first resist pattern upon second exposure is that the first resist pattern is irradiated with radiation so as to decompose the acid generator and an amine or oxazoline compound is applied thereto to inactivate the acid generated by photolysis, before the second resist composition is coated. The wavelength of radiation used in irradiation of the first resist pattern is not particularly limited because this irradiation merely aims to decompose the acid generator. Examples of useful radiation include ArF excimer light of 193 nm wavelength, Xe₂ excimer light of 172 nm wavelength, F₂ excimer light of 157 nm wavelength, Kr₂ excimer light of 146 nm wavelength, Ar₂ excimer light of 126 nm wavelength, electron beam, KrBr excimer light of 206 nm wavelength, KrCl excimer light of 222 nm wavelength, KrF excimer light of 248 nm wavelength, XeBr excimer light of 283 nm wavelength, XeCl excimer light of 308 nm wavelength, i-line of 365 nm wavelength, and emissions spanning 254 nm wavelength from a low-pressure mercury lamp, high-pressure mercury lamp and metal halide lamp. The high-pressure mercury lamp and metal halide lamp produce a broadband of emission including less than 300 nm wavelength so that no standing waves are generated within the resist film during irradiation, achieving uniform irradiation throughout the resist film. The ArF light is a single wavelength and has a possibility of generating standing waves although the generation of standing waves may be suppressed by providing an underlying antireflective coating. The dose of irradiation is preferably 5 mJ/cm² to 10 J/cm², and more preferably 10 mJ/cm² to 1 J/cm².

When radiation of 193 nm wavelength is irradiated, an antireflective coating optimized to that wavelength is provided so that little standing waves are generated. When radiation of wavelength other than 193 nm is irradiated, standing waves are generated due to reflection by the substrate, with a likelihood that the decomposition of the acid generator is insufficient in some regions. Insufficient decomposition of the acid generator at this point leads to a possibility that the acid generator in the first resist pattern is decomposed upon exposure to ArF excimer laser for second patterning, and if the amine or oxazoline is present in a low concentration, the acid labile groups are deprotected, allowing the first resist pattern to be dissolved in the developer. Thus in the embodiment where radiation of wavelength other than 193 nm is irradiated, it is preferable to use a broadband of emission or radiation of plural wavelengths rather than radiation of a single wavelength which causes generation of standing waves.

Following light irradiation, an amine or oxazoline compound is applied to the first resist pattern. This step is effective for neutralizing the acid resulting from decomposition of the acid generator during the irradiation without a need for heating the substrate. The process of decomposing the acid generator and neutralizing the resultant acid without heating is beneficial because it eliminates a possibility that the first resist pattern is deformed by heating or shrunk as a result of deprotection of acid labile groups by heating.

For supplying the amine or oxazoline compound to the first resist pattern, several methods may be employed including spin coating of an amine or oxazoline-containing solution and vapor priming of the amine or oxazoline compound.

Examples of the amine compound which can be used herein include primary, secondary, and tertiary aliphatic amines, mixed amines, aromatic amines, heterocyclic amines, nitrogen-containing compounds with carboxyl group, nitrogen-containing compounds with sulfonyl group, nitrogen-containing compounds with hydroxyl group, nitrogen-containing compounds with hydroxyphenyl group, alcoholic nitrogen-containing compounds, amides, imides, and carbamates.

The preferred amines for inactivating acid are high basicity compounds. Since a dissociation constant (pKa) is often used as an index of basicity, the preferred compounds have a pKa value of at least 7, more preferably at least 8.

Examples of suitable primary aliphatic amines include ammonia, methylamine, ethylamine, n-propylamine, isopropylamine, n-butylamine, isobutylamine, sec-butylamine, tert-butylamine, pentylamine, tert-amylamine, cyclopentylamine, hexylamine, cyclohexylamine, heptylamine, octylamine, nonylamine, decylamine, dodecylamine, cetylamine, methylenediamine, ethylenediamine, and tetraethylenepentamine. Examples of suitable secondary aliphatic amines include dimethylamine, diethylamine, di-n-propylamine, diisopropylamine, di-n-butylamine, diisobutylamine, di-sec-butylamine, dipentylamine, dicyclopentylamine, dihexylamine, dicyclohexylamine, diheptylamine, dioctylamine, dinonylamine, didecylamine, didodecylamine, dicetylamine, N,N-dimethylmethylenediamine, N,N-dimethylethylenediamine, and dimethyltetraethylenepentamine. Examples of suitable tertiary aliphatic amines include trimethylamine, triethylamine, tri-n-propylamine, triisopropylamine, tri-n-butylamine, triisobutylamine, tri-sec-butylamine, tripentylamine, tricyclopentylamine, trihexylamine, tricyclohexylamine, triheptylamine, trioctylamine, trinonylamine, tridecylamine, tridodecylamine, tricetylamine, hexamethylenetetramine, 1,8-diazabicyclo[5.4.0]-7-undecene (DBU), 1,5-diazabicyclo[4.3.0]-5-nonene (DBN), 1,4-diazabicyclo[2.2.2]octane (DABCO), 1,4,7-trimethyl-1,4,7-triazacyclononane, 1,5,9-trimethyl-1,5,9-triazacyclododecane, 1,4,8,11-tetramethyl-1,4,8,11-tetraazacyclotetradecane, and 4,4′-trimethylenebis(1-methylpiperidine).

Also useful are compounds having a plurality of amino groups. Examples include, but are not limited to, hydrazine, hydrazine hydrate, methylhydrazine, dimethylhydrazine, trimethylhydrazine, tetramethylhydrazine, ethylhydrazine, diethylhydrazine, propylhydrazine, butylhydrazine, phenylhydrazine, benzylhydrazine, phenethylhydrazine, cyclopropylhydrazine, cyclopentylhydrazine, cyclohexylhydrazine, ethylenediamine, 1,2-diaminopropane, 1,3-diaminopropane, 1,2-diamino-2-methylpropane, N-methylethylenediamine, N-ethylethylenediamine, N-isopropylethylenediamine, N-hexylethylenediamine, N-cyclohexylethylenediamine, N-octylethylenediamine, N-decylethylenediamine, N-dodecylethylenediamine, N,N-dimethylethylenediamine, N,N′-dimethylethylenediamine, N,N-diethylethylenediamine, N,N′-diethylethylenediamine, N,N′-diisopropylethylenediamine, N,N,N′-trimethylethylenediamine, diethylenetriamine, N-isopropyldiethylenetriamine, N-(2-aminoethyl)-1,3-propanediamine, triethylenetetramine, N,N′-bis(3-aminopropyl)ethylenediamine, N,N′-bis(2-aminoethyl)-1,3-propanediamine, tris(2-aminoethyl)amine, tetraethylenepentamine, pentaethylenehexamine, 2-(2-aminoethylamino)ethanol, N,N′-bis(hydroxyethyl)ethylenediamine, N-(hydroxyethyl)diethylenetriamine, N-(hydroxyethyl)triethylenetetramine, piperazine, 1-(2-aminoethyl)piperazine, 4-(2-aminoethyl)morpholine, and polyethyleneimine. Diamines other than the ethylenediamines and polyamines are also useful. Exemplary other diamines and polyamines include, but are not limited to, 1,3-diaminopropane, 1,4-diaminobutane, 1,3-diaminopentane, 1,5-diaminopentane, 2,2-dimethyl-1,3-propanediamine, hexamethylenediamine, 2-methyl-1,5-diaminopropane, 1,7-diaminoheptane, 1,8-diaminooctane, 2,2,4-trimethyl-1,6-hexanediamine, 2,4,4-trimethyl-1,6-hexanediamine, 1,9-diaminononane, 1,10-diaminodecane, 1,12-diaminododecane, N-methyl-1,3-propanediamine, N-ethyl-1,3-propanediamine, N-isopropyl-1,3-propanediamine, N,N-dimethyl-1,3-propanediamine, N,N′-dimethyl-1,3-propanediamine, N,N′-diethyl-1,3-propanediamine, N,N′-diisopropyl-1,3-propanediamine, N,N,N′-trimethyl-1,3-propanediamine, 2-butyl-2-ethyl-1,5-pentanediamine, N,N′-dimethyl-1,6-hexanediamine, 3,3′-diamino-N-methyldipropylamine, N-(3-aminopropyl)-1,3-propanediamine, spermidine, bis(hexamethylene)triamine, N,N′,N″-trimethylbis(hexamethylene)triamine, 4-aminomethyl-1,8-octanediamine, N,N′-bis(3-aminopropyl)-1,3-propanediamine, spermine, 4,4′-methylenebis(cyclohexylamine), 1,2-diaminocyclohexane, 1,4-diaminocyclohexane, 1,3-cyclohexanebis(methylamine), 1,4-cyclohexanebis(methylamine), 1,2-bis(aminoethoxy)ethane, 4,9-dioxa-1,12-dodecanediamine, 4,7,10-trioxa-1,13-tridecanediamine, 1,3-diaminohydroxypropane, 4,4′-methylenedipiperidine, 4-(aminomethyl)piperidine, homopiperazine, 3-aminopyrrolidine, 4-aminopiperidine, 3-(4-aminobutyl)piperidine, and polyallylamine. Also modified forms of the foregoing primary and secondary amines, ethylenediamines, other diamines and polyamines in which some or all nitrogen atoms are carbamated are similarly applicable. Suitable carbamates include, but are not limited to, t-butyl carbamates (BOC) and t-amyl carbamates, and specifically, N,N′-di(t-butoxycarbonyl)ethylenediamine, N,N′-di(t-amyloxycarbonyl)ethylenediamine, N,N′-di(t-butoxycarbonyl)hexamethylenediamine, and N,N′-di(t-amyloxycarbonyl)hexamethylenediamine.

Examples of suitable mixed amines include dimethylethylamine, methylethylpropylamine, benzylamine, phenethylamine, and benzyldimethylamine. Examples of suitable aromatic and heterocyclic amines include aniline derivatives (e.g., aniline, N-methylaniline, N-ethylaniline, N-propylaniline, N,N-dimethylaniline, 2-methylaniline, 3-methylaniline, 4-methylaniline, ethylaniline, propylaniline, trimethylaniline, 2-nitroaniline, 3-nitroaniline, 4-nitroaniline, 2,4-dinitroaniline, 2,6-dinitroaniline, 3,5-dinitroaniline, and N,N-dimethyltoluidine), diphenyl(p-tolyl)amine, methyldiphenylamine, triphenylamine, phenylenediamine, naphthylamine, diaminonaphthalene, pyrrole derivatives (e.g., pyrrole, 2H-pyrrole, 1-methylpyrrole, 2,4-dimethylpyrrole, 2,5-dimethylpyrrole, and N-methylpyrrole), oxazole derivatives (e.g., oxazole and isooxazole), thiazole derivatives (e.g., thiazole and isothiazole), imidazole derivatives (e.g., imidazole, 4-methylimidazole, and 4-methyl-2-phenylimidazole), pyrazole derivatives, furazane derivatives, pyrroline derivatives (e.g., pyrroline and 2-methyl-1-pyrroline), pyrrolidine derivatives (e.g., pyrrolidine, N-methylpyrrolidine, pyrrolidinone, and N-methylpyrrolidone), imidazoline derivatives, imidazolidine derivatives, pyridine derivatives (e.g., pyridine, methylpyridine, ethylpyridine, propylpyridine, butylpyridine, 4-(1-butylpentyl)pyridine, dimethylpyridine, trimethylpyridine, triethylpyridine, phenylpyridine, 3-methyl-2-phenylpyridine, 4-tert-butylpyridine, diphenylpyridine, benzylpyridine, methoxypyridine, butoxypyridine, dimethoxypyridine, 4-pyrrolidinopyridine, 2-(1-ethylpropyl)pyridine, aminopyridine, and dimethylaminopyridine), pyridazine derivatives, pyrimidine derivatives, pyrazine derivatives, pyrazoline derivatives, pyrazolidine derivatives, piperidine derivatives, piperazine derivatives, morpholine derivatives, indole derivatives, isoindole derivatives, 1H-indazole derivatives, indoline derivatives, quinoline derivatives (e.g., quinoline and 3-quinolinecarbonitrile), isoquinoline derivatives, cinnoline derivatives, quinazoline derivatives, quinoxaline derivatives, phthalazine derivatives, purine derivatives, pteridine derivatives, carbazole derivatives, phenanthridine derivatives, acridine derivatives, phenazine derivatives, 1,10-phenanthroline derivatives, adenine derivatives, adenosine derivatives, guanine derivatives, guanosine derivatives, uracil derivatives, uridine derivatives, and Proton Sponge.

Examples of suitable nitrogen-containing compounds with carboxyl group include aminobenzoic acid, indolecarboxylic acid, and amino acid derivatives (e.g. nicotinic acid, alanine, alginine, aspartic acid, glutamic acid, glycine, histidine, isoleucine, glycylleucine, leucine, methionine, phenylalanine, threonine, lysine, 3-aminopyrazine-2-carboxylic acid, and methoxyalanine). Suitable nitrogen-containing compounds with sulfonyl group include 3-pyridinesulfonic acid and pyridinium p-toluenesulfonate. Examples of suitable nitrogen-containing compounds with hydroxyl group, nitrogen-containing compounds with hydroxyphenyl group, and alcoholic nitrogen-containing compounds include 2-hydroxypyridine, aminocresol, 2,4-quinolinediol, 3-indolemethanol hydrate, monoethanolamine, diethanolamine, triethanolamine, N-ethyldiethanolamine, N,N-diethylethanolamine, triisopropanolamine, 2,2′-iminodiethanol, 2-aminoethanol, 3-amino-1-propanol, 4-amino-1-butanol, 4-(2-hydroxyethyl)morpholine, 2-(2-hydroxyethyl)pyridine, 1-(2-hydroxyethyl)piperazine, 1-[2-(2-hydroxyethoxy)ethyl]piperazine, piperidine ethanol, 1-(2-hydroxyethyl)pyrrolidine, 1-(2-hydroxyethyl)-2-pyrrolidinone, 3-piperidino-1,2-propanediol, 3-pyrrolidino-1,2-propanediol, 8-hydroxyjulolidine, 3-quinuclidinol, 3-tropanol, tropine, lupinine, 1-methyl-2-pyrrolidine ethanol, 1-aziridine ethanol, N-(2-hydroxyethyl)phthalimide, and N-(2-hydroxyethyl)isonicotinamide. Examples of suitable amides include formamide, N-methylformamide, N,N-dimethylformamide, acetamide, N-methylacetamide, N,N-dimethylacetamide, propionamide, benzamide, and 1-cyclohexylpyrrolidone. Suitable imides include phthalimide, succinimide, and maleimide. Suitable carbamates include N-tert-butoxycarbonyl-N,N-dicyclohexylamine, N-tert-butoxycarbonylbenzimidazole, and oxazolidinone.

Organic nitrogen-containing compounds of the following general formula (B)-1 are also useful.

N(X)ₙ(Y)₃₋n (B)-1

In the formula, n is equal to 1, 2 or 3. The side chain X may be the same or different and is selected from groups of the following general formulae (X1) to (X3). The side chain Y may be the same or different and is hydrogen or a straight, branched or cyclic C₁-C₂₀ alkyl group which may contain an ether or hydroxyl group. Two or three X's may bond together to form a ring.

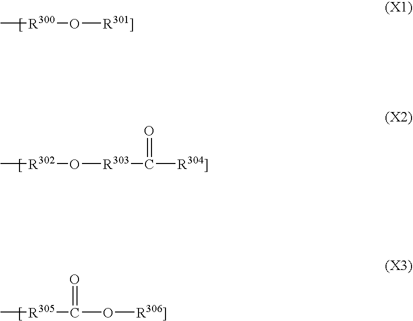

Herein R³⁰⁰, R³⁰² and R³⁰⁵ are independently straight or branched C₁-C₄ alkylene groups; R³⁰¹ and R³⁰⁴ are independently hydrogen or straight, branched or cyclic C₁-C₂₀ alkyl groups which may contain one or more hydroxyl, ether, ester groups or lactone rings; R³⁰³ is a single bond or a straight or branched C₁-C₄ alkylene group; R³⁰³ is a straight, branched or cyclic C₁-C₂₀ alkyl group which may contain one or more hydroxyl, ether, ester groups or lactone rings.

Examples of suitable compounds having formula (B)-1 include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine, 4,7,13,16,21,24-hexaoxa-1,10-diazabicyclo[8.8.8]hexacosane, 4,7,13,18-tetraoxa-1,10-diazabicyclo[8.5.5]eicosane, 1,4,10,13-tetraoxa-7,16-diazabicyclooctadecane, 1-aza-12-crown-4, 1-aza-15-crown-5, 1-aza-18-crown-6, tris(2-formyloxyethyl)amine, tris(2-acetoxyethyl)amine, tris(2-propionyloxyethyl)amine, tris(2-butyryloxyethyl)amine, tris(2-isobutyryloxyethyl)amine, tris(2-valeryloxyethyl)amine, tris(2-pivaloyloxyethyl)amine, N,N-bis(2-acetoxyethyl)-2-(acetoxyacetoxy)ethylamine, tris(2-methoxycarbonyloxyethyl)amine, tris(2-tert-butoxycarbonyloxyethyl)amine, tris[2-(2-oxopropoxy)ethyl]amine, tris[2-(methoxycarbonylmethyl)oxyethyl]amine, tris[2-(tert-butoxycarbonylmethyloxy)ethyl]amine, tris[2-(cyclohexyloxycarbonylmethyloxy)ethyl]amine, tris(2-methoxycarbonylethyl)amine, tris(2-ethoxycarbonylethyl)amine, N,N-bis(2-hydroxyethyl)-2-(methoxycarbonyl)ethylamine, N,N-bis(2-acetoxyethyl)-2-(methoxycarbonyl)ethylamine, N,N-bis(2-hydroxyethyl)-2-(ethoxycarbonyl)ethylamine, N,N-bis(2-acetoxyethyl)-2-(ethoxycarbonyl)ethylamine, N,N-bis(2-hydroxyethyl)-2-(2-methoxyethoxycarbonyl)ethylamine, N,N-bis(2-acetoxyethyl)-2-(2-methoxyethoxycarbonyl)ethylamine, N,N-bis(2-hydroxyethyl)-2-(2-hydroxyethoxycarbonyl)ethylamine, N,N-bis(2-acetoxyethyl)-2-(2-acetoxyethoxycarbonyl)ethylamine, N,N-bis(2-hydroxyethyl)-2-[(methoxycarbonyl)methoxycarbonyl]-ethylamine, N,N-bis(2-acetoxyethyl)-2-[(methoxycarbonyl)methoxycarbonyl]-ethylamine, N,N-bis(2-hydroxyethyl)-2-(2-oxopropoxycarbonyl)ethylamine, N,N-bis(2-acetoxyethyl)-2-(2-oxopropoxycarbonyl)ethylamine, N,N-bis(2-hydroxyethyl)-2-(tetrahydrofurfuryloxycarbonyl)ethylamine, N,N-bis(2-acetoxyethyl)-2-(tetrahydrofurfuryloxycarbonyl)ethylamine, N,N-bis(2-hydroxyethyl)-2-[(2-oxotetrahydrofuran-3-yl)oxycarbonyl]ethylamine, N,N-bis(2-acetoxyethyl)-2-[(2-oxotetrahydrofuran-3-yl)oxycarbonyl]ethylamine, N,N-bis(2-hydroxyethyl)-2-(4-hydroxybutoxycarbonyl)ethylamine, N,N-bis(2-formyloxyethyl)-2-(4-formyloxybutoxycarbonyl)ethylamine, N,N-bis(2-formyloxyethyl)-2-(2-formyloxyethoxycarbonyl)ethylamine, N,N-bis(2-methoxyethyl)-2-(methoxycarbonyl)ethylamine, N-(2-hydroxyethyl)-bis[2-(methoxycarbonyl)ethyl]amine, N-(2-acetoxyethyl)-bis[2-(methoxycarbonyl)ethyl]amine, N-(2-hydroxyethyl)-bis[2-(ethoxycarbonyl)ethyl]amine, N-(2-acetoxyethyl)-bis[2-(ethoxycarbonyl)ethyl]amine, N-(3-hydroxy-1-propyl)-bis[2-(methoxycarbonyl)ethyl]amine, N-(3-acetoxy-1-propyl)-bis[2-(methoxycarbonyl)ethyl]amine, N-(2-methoxyethyl)-bis[2-(methoxycarbonyl)ethyl]amine, N-butylbis[2-(methoxycarbonyl)ethyl]amine, N-butylbis[2-(2-methoxyethoxycarbonyl)ethyl]amine, N-methylbis(2-acetoxyethyl)amine, N-ethylbis(2-acetoxyethyl)amine, N-methylbis(2-pivaloyloxyethyl)amine, N-ethylbis[2-(methoxycarbonyloxy)ethyl]amine, N-ethylbis[2-(tert-butoxycarbonyloxy)ethyl]amine, tris(methoxycarbonylmethyl)amine, tris(ethoxycarbonylmethyl)amine, N-butylbis(methoxycarbonylmethyl)amine, N-hexylbis(methoxycarbonylmethyl)amine, and β-(diethylamino)-δ-valerolactone.

Also useful are organic nitrogen-containing compounds of cyclic structure having the general formula (B)-2.

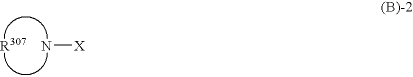

Herein X is as defined above, and R³⁰⁷ is a straight or branched C₂-C₂₀ alkylene group which may contain one or more carbonyl, ether, ester or sulfide groups.

Examples of the compounds having formula (B)-2 include 1-[2-(methoxymethoxy)ethyl]pyrrolidine, 1-[2-(methoxymethoxy)ethyl]piperidine, 4-[2-(methoxymethoxy)ethyl]morpholine, 1-[2-[(2-methoxyethoxy)methoxy]ethyl]pyrrolidine, 1-[2-[(2-methoxyethoxy)methoxy]ethyl]piperidine, 4-[2-[(2-methoxyethoxy)methoxy]ethyl]morpholine, 2-(1-pyrrolidinyl)ethyl acetate, 2-piperidinoethyl acetate, 2-morpholinoethyl acetate, 2-(1-pyrrolidinyl)ethyl formate, 2-piperidinoethyl propionate, 2-morpholinoethyl acetoxyacetate, 2-(1-pyrrolidinyl)ethyl methoxyacetate, 4-[2-(methoxycarbonyloxy)ethyl]morpholine, 1-[2-(t-butoxycarbonyloxy)ethyl]piperidine, 4-[2-(2-methoxyethoxycarbonyloxy)ethyl]morpholine, methyl 3-(1-pyrrolidinyl)propionate, methyl 3-piperidinopropionate, methyl 3-morpholinopropionate, methyl 3-(thiomorpholino)propionate, methyl 2-methyl-3-(1-pyrrolidinyl)propionate, ethyl 3-morpholinopropionate, methoxycarbonylmethyl 3-piperidinopropionate, 2-hydroxyethyl 3-(1-pyrrolidinyl)propionate, 2-acetoxyethyl 3-morpholinopropionate, 2-oxotetrahydrofuran-3-yl 3-(1-pyrrolidinyl)propionate, tetrahydrofurfuryl 3-morpholinopropionate, glycidyl 3-piperidinopropionate, 2-methoxyethyl 3-morpholinopropionate, 2-(2-methoxyethoxy)ethyl 3-(1-pyrrolidinyl)propionate, butyl 3-morpholinopropionate, cyclohexyl 3-piperidinopropionate, α-(1-pyrrolidinyl)methyl-γ-butyrolactone, β-piperidino-γ-butyrolactone, β-morpholino-δ-valerolactone, methyl 1-pyrrolidinylacetate, methyl piperidinoacetate, methyl morpholinoacetate, methyl thiomorpholinoacetate, ethyl 1-pyrrolidinylacetate, 2-methoxyethyl morpholinoacetate, 2-morpholinoethyl 2-methoxyacetate, 2-morpholinoethyl 2-(2-methoxyethoxy)acetate, 2-morpholinoethyl 2-[2-(2-methoxyethoxy)ethoxy]acetate, 2-morpholinoethyl hexanoate, 2-morpholinoethyl octanoate, 2-morpholinoethyl decanoate, 2-morpholinoethyl laurate, 2-morpholinoethyl myristate, 2-morpholinoethyl palmitate, and 2-morpholinoethyl stearate.

Also useful are organic nitrogen-containing compounds having cyano represented by the general formulae (B)-3 to (B)-6.

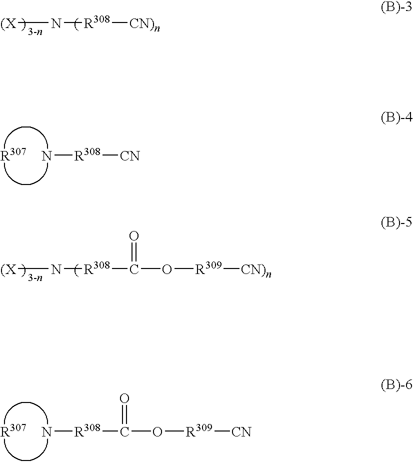

Herein, X, R³⁰⁷ and n are as defined above, and R³⁰⁸ and R³⁰⁹ are each independently a straight or branched C₁-C₄ alkylene group.

Examples of the organic nitrogen-containing compounds having cyano represented by formulae (B)-3 to (B)-6 include 3-(diethylamino)propiononitrile, N,N-bis(2-hydroxyethyl)-3-aminopropiononitrile, N,N-bis(2-acetoxyethyl)-3-aminopropiononitrile, N,N-bis(2-formyloxyethyl)-3-aminopropiononitrile, N,N-bis(2-methoxyethyl)-3-aminopropiononitrile, N,N-bis[2-(methoxymethoxy)ethyl]-3-aminopropiononitrile, methyl N-(2-cyanoethyl)-N-(2-methoxyethyl)-3-aminopropionate, methyl N-(2-cyanoethyl)-N-(2-hydroxyethyl)-3-aminopropionate, methyl N-(2-acetoxyethyl)-N-(2-cyanoethyl)-3-aminopropionate, N-(2-cyanoethyl)-N-ethyl-3-aminopropiononitrile, N-(2-cyanoethyl)-N-(2-hydroxyethyl)-3-aminopropiononitrile, N-(2-acetoxyethyl)-N-(2-cyanoethyl)-3-aminopropiononitrile, N-(2-cyanoethyl)-N-(2-formyloxyethyl)-3-aminopropiononitrile, N-(2-cyanoethyl)-N-(2-methoxyethyl)-3-aminopropiononitrile, N-(2-cyanoethyl)-N-[2-(methoxymethoxy)ethyl]-3-aminopropiononitrile, N-(2-cyanoethyl)-N-(3-hydroxy-1-propyl)-3-aminopropiononitrile, N-(3-acetoxy-1-propyl)-N-(2-cyanoethyl)-3-aminopropiononitrile, N-(2-cyanoethyl)-N-(3-formyloxy-1-propyl)-3-aminopropiononitrile, N-(2-cyanoethyl)-N-tetrahydrofurfuryl-3-aminopropiononitrile, N,N-bis(2-cyanoethyl)-3-aminopropiononitrile, diethylaminoacetonitrile, N,N-bis(2-hydroxyethyl)aminoacetonitrile, N,N-bis(2-acetoxyethyl)aminoacetonitrile, N,N-bis(2-formyloxyethyl)aminoacetonitrile, N,N-bis(2-methoxyethyl)aminoacetonitrile, N,N-bis[2-(methoxymethoxy)ethyl]aminoacetonitrile, methyl N-cyanomethyl-N-(2-methoxyethyl)-3-aminopropionate, methyl N-cyanomethyl-N-(2-hydroxyethyl)-3-aminopropionate, methyl N-(2-acetoxyethyl)-N-cyanomethyl-3-aminopropionate, N-cyanomethyl-N-(2-hydroxyethyl)aminoacetonitrile, N-(2-acetoxyethyl)-N-(cyanomethyl)aminoacetonitrile, N-cyanomethyl-N-(2-formyloxyethyl)aminoacetonitrile, N-cyanomethyl-N-(2-methoxyethyl)aminoacetonitrile, N-cyanomethyl-N-[2-(methoxymethoxy)ethyl)aminoacetonitrile, N-cyanomethyl-N-(3-hydroxy-1-propyl)aminoacetonitrile, N-(3-acetoxy-1-propyl)-N-(cyanomethyl)aminoacetonitrile, N-cyanomethyl-N-(3-formyloxy-1-propyl)aminoacetonitrile, N,N-bis(cyanomethyl)aminoacetonitrile, 1-pyrrolidinepropiononitrile, 1-piperidinepropiononitrile, 4-morpholinepropiononitrile, 1-pyrrolidineacetonitrile, 1-piperidineacetonitrile, 4-morpholineacetonitrile, cyanomethyl 3-diethylaminopropionate, cyanomethyl N,N-bis(2-hydroxyethyl)-3-aminopropionate, cyanomethyl N,N-bis(2-acetoxyethyl)-3-aminopropionate, cyanomethyl N,N-bis(2-formyloxyethyl)-3-aminopropionate, cyanomethyl N,N-bis(2-methoxyethyl)-3-aminopropionate, cyanomethyl N,N-bis[2-(methoxymethoxy)ethyl]-3-aminopropionate, 2-cyanoethyl 3-diethylaminopropionate, 2-cyanoethyl N,N-bis(2-hydroxyethyl)-3-aminopropionate, 2-cyanoethyl N,N-bis(2-acetoxyethyl)-3-aminopropionate, 2-cyanoethyl N,N-bis(2-formyloxyethyl)-3-aminopropionate, 2-cyanoethyl N,N-bis(2-methoxyethyl)-3-aminopropionate, 2-cyanoethyl N,N-bis[2-(methoxymethoxy)ethyl]-3-aminopropionate, cyanomethyl 1-pyrrolidinepropionate, cyanomethyl 1-piperidinepropionate, cyanomethyl 4-morpholinepropionate, 2-cyanoethyl 1-pyrrolidinepropionate, 2-cyanoethyl 1-piperidinepropionate, and 2-cyanoethyl 4-morpholinepropionate.

Also included are organic nitrogen-containing compounds of imidazole structure having a polar functional group, represented by the general formula (B)-7.

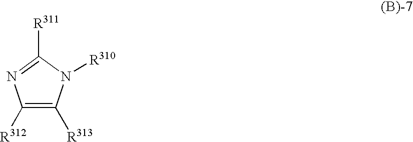

Herein, R³¹⁰ is a straight, branched or cyclic C₂-C₂₀ alkyl group having a polar functional group which is selected from among hydroxyl, carbonyl, ester, ether, sulfide, carbonate, cyano and acetal groups and mixtures thereof. R³¹¹, R³¹² and R³¹³ are each independently hydrogen, a straight, branched or cyclic C₁-C₁₀ alkyl group, aryl group or aralkyl group.

Also included are organic nitrogen-containing compounds of benzimidazole structure having a polar functional group, represented by the general formula (B)-8.

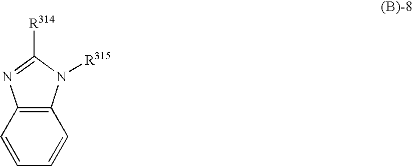

Herein R³¹⁴ is hydrogen, a straight, branched or cyclic C₁-C₁₀ alkyl group, aryl group or aralkyl group. R³¹⁵ is a straight, branched or cyclic C₁-C₂₀ alkyl group having a polar functional group. The alkyl group contains as the polar functional group at least one group selected from among ester, acetal and cyano groups, and may additionally contain at least one group selected from among hydroxyl, carbonyl, ether, sulfide and carbonate groups.

Further included are heterocyclic nitrogen-containing compounds having a polar functional group, represented by the general formulae (B)-9 and (B)-10.

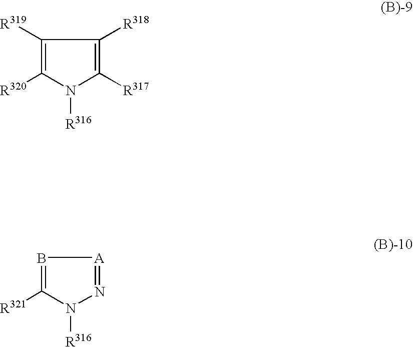

Herein, A is a nitrogen atom or ≡C—R³²². B is a nitrogen atom or ≡C—R³²³. R³¹⁶ is a straight, branched or cyclic C₂-C₂₀ alkyl group which has one or more polar functional groups selected from among hydroxyl, carbonyl, ester, ether, sulfide, carbonate, cyano and acetal groups and mixtures thereof. R³¹⁷, R³¹⁸, R³¹⁹ and R³²⁰ are each independently hydrogen, a straight, branched or cyclic C₁-C₁₀ alkyl group or aryl group, or a pair of R³¹⁷ and R³¹⁸ and a pair of R³¹⁹ and R³²⁰, taken together, may form a benzene, naphthalene or pyridine ring with the carbon atoms to which they are attached. R³²¹ is hydrogen, a straight, branched or cyclic C₁-C₁₀ alkyl group or C₆-C₁₀ aryl group. R³²² and R³²³ each are hydrogen, a straight, branched or cyclic C₁-C₁₀ alkyl group or aryl group, or a pair of R³²¹ and R³²³, taken together, may form a benzene or naphthalene ring with the carbon atoms to which they are attached.

Also included are organic nitrogen-containing compounds of aromatic carboxylic acid ester structure, represented by the general formulae (B)-11 to (B)-14.

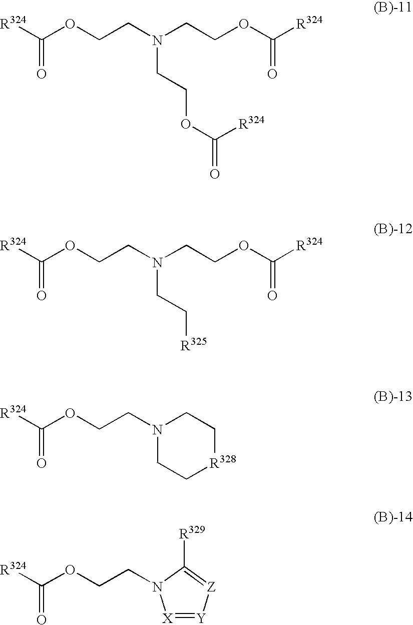

Herein R³²⁴ is a C₆-C₂₀ aryl group or C₄-C₂₀ hetero-aromatic group, in which some or all hydrogen atoms may be replaced by halogen atoms, straight, branched or cyclic C₁-C₂₀ alkyl groups, C₆-C₂₀ aryl groups, C₇-C₂₀ aralkyl groups, C₁-C₁₀ alkoxy groups, C₁-C₁₀ acyloxy groups or C₁-C₁₀ alkylthio groups. R³²⁵ is CO₂R³²⁶, OR³²⁷ or cyano group. R³²⁶ is a C₁-C₁₀ alkyl group in which some methylene groups may be replaced by oxygen atoms. R³²⁷ is a C₁-C₁₀ alkyl or acyl group in which some methylene groups may be replaced by oxygen atoms. R³²⁸ is a single bond, methylene, ethylene, sulfur atom or —O(CH₂CH₂O)ₙ— group wherein n is 0, 1, 2, 3 or 4. R³²⁹ is hydrogen, methyl, ethyl or phenyl. X is a nitrogen atom or CR³³⁰. Y is a nitrogen atom or CR³³¹. Z is a nitrogen atom or CR³³². R³³⁰, R³³¹ and R³³² are each independently hydrogen, methyl or phenyl. Alternatively, a pair of R³³⁰ and R³³¹ or a pair of R³³¹ and R³³² may bond together to form a C₆-C₂₀ aromatic ring or C₂-C₂₀ hetero-aromatic ring with the carbon atoms to which they are attached.

Further included are nitrogen-containing compounds of 7-oxanorbornane-2-carboxylic ester structure, represented by the general formula (B)-15.

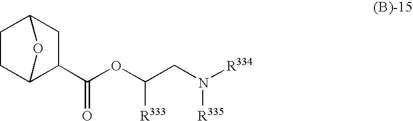

Herein R³³³ is hydrogen or a straight, branched or cyclic C₁-C₁₀ alkyl group. R³³⁴ and R³³⁵ are each independently a C₂-C₂₀ alkyl group, C₆-C₂₀ aryl group or C₇-C₂₀ aralkyl group, which may contain one or more polar functional groups selected from among ether, carbonyl, ester, alcohol, sulfide, nitrile, amine, imine, and amide and in which some hydrogen atoms may be replaced by halogen atoms. R³³⁴ and R³³⁵, taken together, may form a C₂-C₂₀ heterocyclic or hetero-aromatic ring with the nitrogen atom to which they are attached.

Also useful are those compounds which will generate a base when heated. Exemplary compounds are benzyl carbamates as described in Journal of Photopolymer Science and Technology, Vol. 3, No. 3, p 419 (1990).

Further useful are amine compounds having hydrolyzable silicon represented by the general formulae (S1) and (S2).

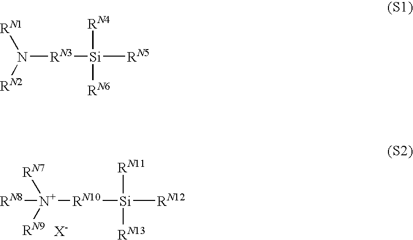

Herein R^{N1}, R^{N2}, R^{N7}, R^{N8}, and R^{N9} are each independently hydrogen, a straight, branched or cyclic C₁-C₁₀ alkyl group which may have an amino, ether (—O—), ester (—COO—) or hydroxyl group, or a C₆-C₁₀ aryl, C₂-C₁₂ alkenyl or C₇-C₁₂ aralkyl group which may have an amino group, or R^{N1} and R^{N2}, R^{N7} and R^{N8}, R^{N8} and R^{N9}, or R^{N7} and R^{N9} may bond together to form a ring with the nitrogen atom to which they are attached. R^{N3} and R^{N10} are each independently a straight, branched or cyclic C₁-C₁₂ alkylene group which may have an ether (—O—), ester (—COO—), thioether (—S—), phenylene or hydroxyl group. R^{N4} to R^{N6} and R^{N11} to R^{N13} are each independently hydrogen, a C₁-C₆ alkyl, C₆-C₁₀ aryl, C₂-C₁₂ alkenyl, C₁-C₆ alkoxy, C₆-C₁₀ aryloxy, C₂-C₁₂ alkenyloxy, C₇-C₁₂ aralkyloxy or hydroxyl group, at least one of R^{N4} to R^{N6} and R^{N1} to R^{N13} being alkoxy or hydroxyl. X⁻ is an anion.

Examples of the compound having formula (S1) include, but are not limited to, 3-aminopropyltrimethoxysilane, 3-aminopropyltriethoxysilane, 3-aminopropyltripropoxysilane, 3-aminopropyltriisopropoxysilane, 3-aminopropyltrihydroxysilane, 2-aminoethylaminomethyltrimethoxysilane, 2-aminoethylaminomethyltriethoxysilane, 2-aminoethylaminomethyltripropoxysilane, 2-aminoethylaminomethyltrihydroxysilane, isopropylaminomethyltrimethoxysilane, 2-(2-aminoethylthio)ethyltrimethoxysilane, allyloxy-2-aminoethylaminomethyldimethylsilane, butylaminomethyltrimethoxysilane, 3-aminopropyldiethoxymethylsilane, 3-(2-aminoethylamino)propyldimethoxymethylsilane, 3-(2-aminoethylamino)propyltrimethoxysilane, 3-(2-aminoethylamino)propyltriethoxysilane, 3-(2-aminoethylamino)propyltriisopropoxysilane, piperidinomethyltrimethoxysilane, 3-(allylamino)propyltrimethoxysilane, 4-methylpiperazinomethyltrimethoxysilane, 2-(2-aminoethylthio)ethyldiethoxymethylsilane, morpholinomethyltrimethoxysilane, 4-acetylpiperazinomethyltrimethoxysilane, cyclohexylaminotrimethoxysilane, 2-piperidinoethyltrimethoxysilane, 2-morpholinoethylthiomethyltrimethoxysilane, dimethoxymethyl-2-piperidinoethylsilane, 3-morpholinopropyltrimethoxysilane, dimethoxymethyl-3-piperazinopropylsilane, 3-piperazinopropyltrimethoxysilane, 3-butylaminopropyltrimethoxysilane, 3-dimethylaminopropyldiethoxymethylsilane, 2-(2-aminoethylthio)ethyltriethoxysilane, 3-[2-(2-aminoethylamino)ethylamino]propyltrimethoxysilane, 3-phenylaminopropyltrimethoxysilane, 2-aminoethylaminomethylbenzyloxydimethylsilane, 3-(4-acetylpiperazinopropyl)trimethoxysilane, 3-(3-methylpiperidinopropyl)trimethoxysilane, 3-(4-methylpiperidinopropyl)trimethoxysilane, 3-(2-methylpiperidinopropyl)trimethoxysilane, 3-(2-morpholinoethylthiopropyl)trimethoxysilane, dimethoxymethyl-3-(4-methylpiperidinopropyl)silane, 3-cyclohexylaminopropyltrimethoxysilane, 3-benzylaminopropyltrimethoxysilane, 3-(2-piperidinoethylthiopropyl)trimethoxysilane, 3-hexamethyleneiminopropyltrimethoxysilane, 3-pyrrolidinopropyltrimethoxysilane, 3-(6-aminohexylamino)propyltrimethoxysilane, 3-(methylamino)propyltrimethoxysilane, 3-(ethylamino)-2-methylpropyltrimethoxysilane, 3-(butylamino)propyltrimethoxysilane, 3-(t-butylamino)propyltrimethoxysilane, 3-(diethylamino)propyltrimethoxysilane, 3-(cyclohexylamino)propyltrimethoxysilane, 3-anilinopropyltrimethoxysilane, 4-aminobutyltrimethoxysilane, 11-aminoundecyltrimethoxysilane, 11-aminoundecyltriethoxysilane, 11-(2-aminoethylamino)undecyltrimethoxysilane, p-aminophenyltrimethoxysilane, m-aminophenyltrimethoxysilane, 3-(m-aminophenoxy)propyltrimethoxysilane, 2-(2-pyridyl)ethyltrimethoxysilane, 2-[(2-aminoethylamino)methylphenyl]ethyltrimethoxysilane, diethylaminomethyltriethoxysilane, 3-[(3-acryloyloxy-2-hydroxypropyl)amino]propyltriethoxysilane, 3-(ethylamino)-2-methylpropyl(methyldiethoxysilane), and 3-[bis(hydroxyethyl)amino]propyltriethoxysilane.

The aminosilane compounds of formula (S1) may be used alone or in a blend of two or more. Also useful are (partial) hydrolytic condensates of the aminosilane compounds.

Suitable aminosilane compounds of formula (S1) further include reaction products of an oxirane-containing silane compound with an amine compound, as represented by the general formula (S3).

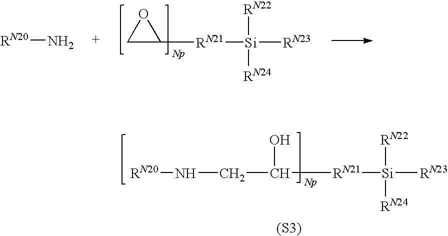

Herein R^{N20} is hydrogen, or a straight, branched or cyclic C₁-C₂₀ alkyl, C₆-C₁₀ aryl or C₂-C₁₂ alkenyl group which may have a hydroxyl, ether, ester or amino group. The subscript Np is 1 or 2. When Np is 1, R^{N21} is a straight, branched or cyclic C₁-C₂₀ alkylene group which may have an ether, ester or phenylene group. When Np is 2, R^{N21} is the alkylene group with one hydrogen atom being eliminated. R^{N22} to R^{N24} are each independently hydrogen, or a C₁-C₆ alkyl, C₆-C₁₀ aryl, C₂-C₁₂ alkenyl, C₁-C₆ alkoxy, C₆-C₁₀ aryloxy, C₂-C₁₂ alkenyloxy, C₇-C₁₂ aralkyloxy or hydroxyl group, at least one of R^{N22} to R^{N24} being alkoxy or hydroxyl.

Particularly when an aminosilane compound of formula (S1) wherein R^{N1} is hydrogen, i.e., aminosilane having a secondary amino group or an aminosilane compound of formula (S1) wherein both R^{N1} and R^{N2} are hydrogen, i.e., aminosilane having a primary amino group is admixed with an oxirane-containing silane compound, a silane compound having the general formula (S4) forms through the reaction shown below, for example. When a mixture of a primary or secondary amino group-containing aminosilane and an oxirane-containing silane compound is used, the silane compound of formula (S4) adsorbs on the resist surface.

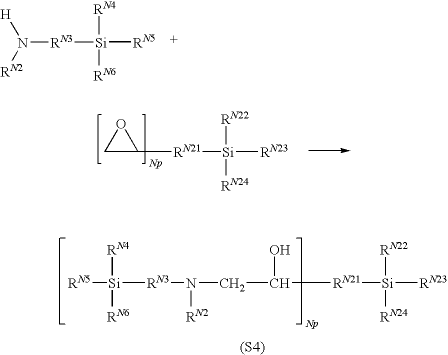

Herein R^{N2} to R^{N6}, R^{N21} to R^{N24}, and Np are as defined above.

Examples of the oxirane-containing silane compound used herein are given below.

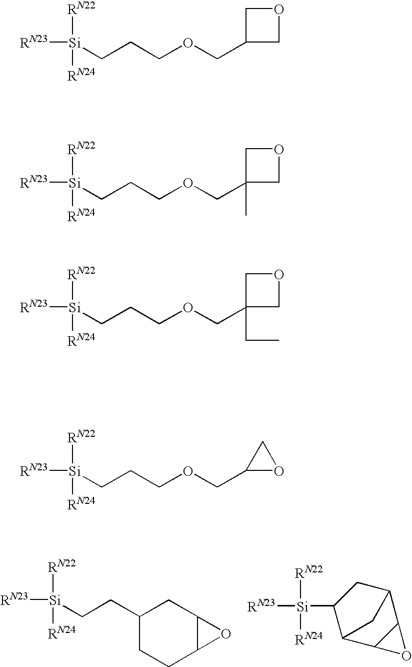

Herein R^{N22} to R^{N24} are as defined above.

Analogous silane compounds containing oxetane instead of oxirane are also useful.

Desired among the amine compounds which are to react with the silane compound containing oxiran or oxetane are primary and secondary amine compounds. Suitable primary amine compounds include ammonia, methylamine, ethylamine, n-propylamine, isopropylamine, n-butylamine, isobutylamine, sec-butylamine, tert-butylamine, pentylamine, tert-amylamine, cyclopentylamine, hexylamine, cyclohexylamine, heptylamine, octylamine, nonylamine, decylamine, dodecylamine, cetylamine, methylenediamine, ethylenediamine, tetraethylenepentamine, ethanolamine, N-hydroxyethylethylamine, and N-hydroxypropylethylamine. Suitable secondary aliphatic amines include dimethylamine, diethylamine, di-n-propylamine, diisopropylamine, di-n-butylamine, diisobutylamine, di-sec-butylamine, dipentylamine, dicyclopentylamine, dihexylamine, dicyclohexylamine, diheptylamine, dioctylamine, dinonylamine, didecylamine, didodecylamine, dicetylamine, N,N-dimethylmethylenediamine, N,N-dimethylethylenediamine, and N,N-dimethyltetraethylenepentamine.

The aminosilane compound may be blended with another silane compound. Blends of aminosilanes and epoxy-containing silanes are described in, for example, JP-A 2005-248169.

Examples of the silane compound having an ammonium salt represented by formula (S2) include, but are not limited to, N-trimethoxysilylpropyl-N,N,N-trimethylammonium hydroxide, N-triethoxysilylpropyl-N,N,N-trimethylammonium hydroxide, N,N,N-trimethyl-N-(tripropoxysilylpropyl)ammonium hydroxide, N,N,N-tributyl-N-(trimethoxysilylpropyl)ammonium hydroxide, N,N,N-triethyl-N-(trimethoxysilylpropyl)ammonium hydroxide, N-trimethoxysilylpropyl-N,N,N-tripropylammonium hydroxide, N-(2-trimethoxysilylethyl)benzyl-N,N,N-trimethylammonium hydroxide, N-trimethoxysilylpropyl-N,N,N-trimethylammonium hydroxide, and N-trimethoxysilylpropyl-N,N-dimethyl-N-tetradecylammonium hydroxide. In addition to the hydroxide ion described just above, examples of the anion X⁻ include halide ions such as chloride and bromide, and anions derived from acetic acid, formic acid, oxalic acid, citric acid, nitric acid, sulfonic acid, methanesulfonic acid, trifluoromethanesulfonic acid, tosylic acid, and benzenesulfonic acid. In order that ammonium ions adsorb on the resist surface via anion exchange with carboxyl groups on the resist surface, the anion X is preferably a weak acid or base anion, and most preferably hydroxy anion.

Suitable oxazoline compounds which can be used herein include 2,4,4-trimethyl-2-oxazoline, 2-methyl-2-oxazoline, 2-ethyl-2-oxazoline, 2-isopropyl-2-oxazoline, 2-cyclohexyl-2-oxazoline, 2-cyclopentyl-2-oxazoline, 2-isopropenyl-2-oxazoline, 2-phenyl-2-oxazoline, 2,2′-isopropylidenebis(4-benzyl-2-oxazoline), 2,2′-isopropylidenebis(4-phenyl-2-oxazoline), 2,2′-isopropylidenebis(4-phenyl-2-oxazoline), 2-(2-methoxyphenyl)-4,4-dimethyl-2-oxazoline, 2,2′-methylenebis(4,5-diphenyl-2-oxazoline), 2,2′-methylenebis(4-phenyl-2-oxazoline), 2,2′-methylenebis(4-tert-butyl-2-oxazoline), 4,4-dimethyl-2-(4′-methyl-2-oxazoline), 4,4-dimethyl-2-phenyl-2-oxazoline, 1,3-bis(4,5-dihydro-2-oxazolyl)benzene, 1,4-bis(4,5-dihydro-2-oxazolyl)benzene, and 2,2′-bis(2-oxazoline).

When the amine or oxazoline compound is coated onto the first resist pattern-bearing substrate, preferably the compound is dissolved in an organic solvent or water or a mixture thereof to form a solution which is ready for coating. The solvent used herein should not dissolve the first resist pattern. Such non-attacking solvents include C₃-C₈ alcohols, C₆-C₁₂ ethers, C₄-C₁₆ alkanes, alkenes, and aromatic hydrocarbons, mixtures of two or more of these organic solvents, and mixtures of any organic solvent and water. When a mixture of an organic solvent and water is used, the resulting solution can be coated using a developer cup. Namely, an aqueous solution of the amine or oxazoline compound can be coated immediately after development of the first resist pattern. If the coating step using the development cup is incorporated in the development sequence, advantageously the coating step may be carried out on the existing system without a need for an additional coating cup.

Suitable C₃-C₈ alcohols include n-propanol, isopropyl alcohol, 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2,2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, 1-heptanol, cyclohexanol, and octanol.

Suitable C₆-C₁₂ ethers include methyl cyclopentyl ether, methyl cyclohexyl ether, anisole, diisopropyl ether, diisobutyl ether, diisopentyl ether, di-n-pentyl ether, methyl cyclopentyl ether, methyl cyclohexyl ether, di-n-butyl ether, di-sec-butyl ether, diisopentyl ether, di-sec-pentyl ether, di-tert-amyl ether, and di-n-hexyl ether.

Suitable C₄-C₁₆ alkanes include hexane, heptane, octane, decane, cyclohexane, cycloheptane, cyclooctane, cyclodecane, methylcyclohexane, dimethylcyclohexane, methyladamantane, dimethyladamantane, decahydronaphthalene; suitable alkenes include heptene and octene; and suitable aromatic hydrocarbons include benzene, toluene, and xylene.

Once a solution containing the amine or oxazoline compound is coated onto the first resist pattern-bearing substrate, the coating is baked so that the amine or oxazoline compound is adsorbed to the resist surface. Since carboxyl groups resulting from partial deprotection of acid labile groups are present on the resist surface, the amine compound forms a salt with the carboxyl group and the oxazoline forms an amide ester. The amine salt with carboxyl group or the amide group neutralizes the acid and deactivates the acid. The baking also functions to evaporate off the excess amine or oxazoline compound. Since the amine or oxazoline compound deposited on the substrate deactivates the acid generated in the second resist film upon second exposure and thus causes a footing profile, the excess amine or oxazoline compound must be removed. For removal of the amine or oxazoline compound, it is effective to rinse the structure with the solvent which does not attack the resist pattern (as used in coating of the amine or oxazoline compound), water, alkaline developer or a mixture thereof. Rinsing may be followed by baking, which is effective not only for evaporating off the rinse liquid, but also for causing the amine or oxazoline compound to more tenaciously adhere to the resist pattern.

At this stage, the baking temperature is preferably in a range of 50 to 200° C., and more preferably up to 190° C. For minimizing deformation of the first resist pattern, the baking temperature is desirably up to 180° C., and more desirably up to 170° C.

To a solution of the amine or oxazoline compound, a base polymer may be added.

The base polymer used herein is desirably a polymer which is water soluble or strippable with an aqueous alkaline solution that is a developer. Suitable base polymers include polyvinylpyrrolidone, polyvinylalcohol, polyacrylic acid, polymethacrylic acid, polyhydroxyethylmethacrylic acid, polyethylene oxide, amylose, dextran, cellulose, pullulan and copolymers thereof.

Also polymers comprising recurring units having the general formula (5) may be used.

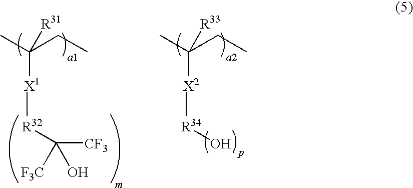

Herein R³¹ and R³³ are each independently hydrogen, methyl or hydroxymethyl. R³² is a single bond or a straight, branched or cyclic C₁-C₁₀ alkylene or alkylidene group. R³⁴ is a (p+1)-valent straight, branched or cyclic C₁-C₁₂ aliphatic unsaturated hydrocarbon group, or a C₆-C₁₂ aromatic hydrocarbon group, benzyl or naphthalenemethyl, which may have an ether bond. The subscript m is 1 or 2, and p is an integer of 1 to 5. X¹ and X² are each independently —C(═O)—O—R³⁵—, —C(═O)—NH—R³⁶—, —C(═O)—N(R³⁶)₂—, or phenylene or naphthylene. R³⁵ is a single bond, or a C₁-C₆ alkylene or C₆-C₁₀ arylene group which may have an ether or ester radical. R³⁶ is a single bond, or a C₁-C₆ alkylene or C₆-C₁₀ arylene group which may have an ether or ester radical. The subscripts a1 and a2 are numbers in the range: 0≦a1<1.0, 0<a2≦1.0, and 0<a1+a2≦1.0.

For example, the recurring units having formula (5) are derived from monomers Ma1 and Ma2 having the general formula (6), respectively.

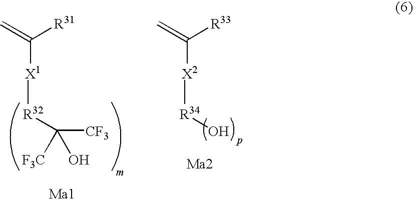

Herein R³¹ to R³⁴, X¹, X², m, and p are as defined above. Those polymers obtained from polymerization of hydroxy-bearing monomers Ma1 and Ma2 are soluble in C₃-C₈ alcohols and form tough films as a result of crosslinking of hydroxy moieties.

Examples of suitable monomers Ma1 are shown below. R³¹ is as defined above.

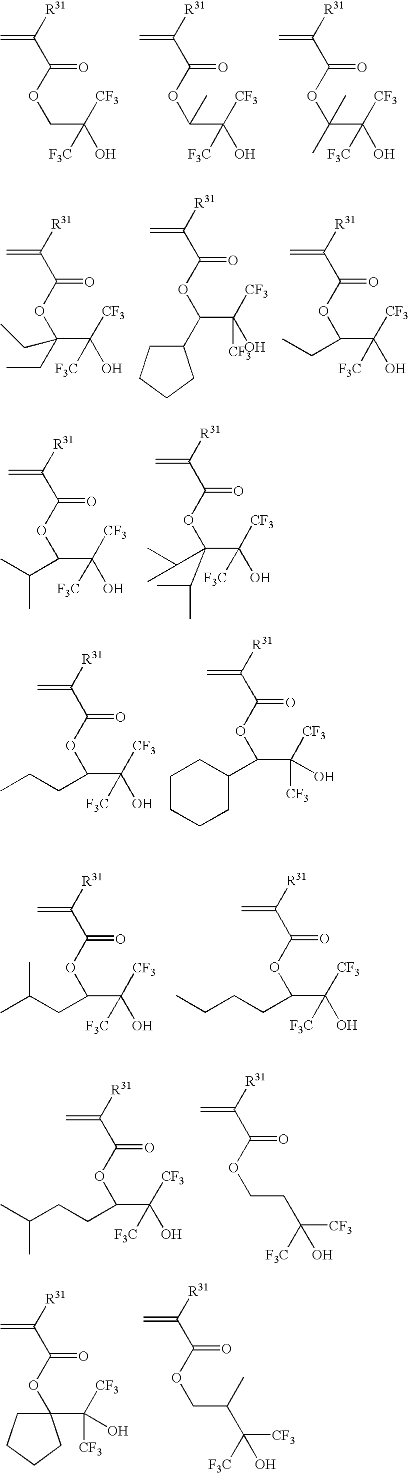

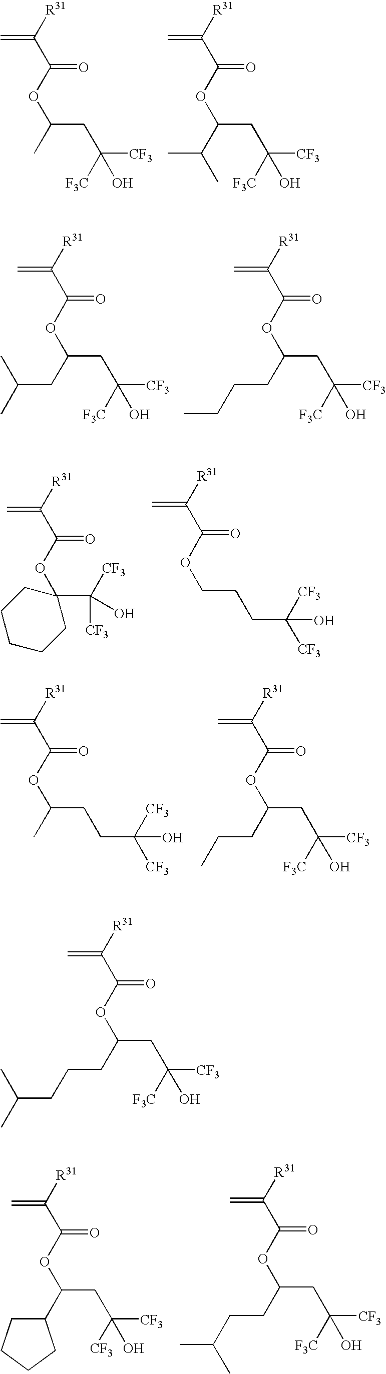

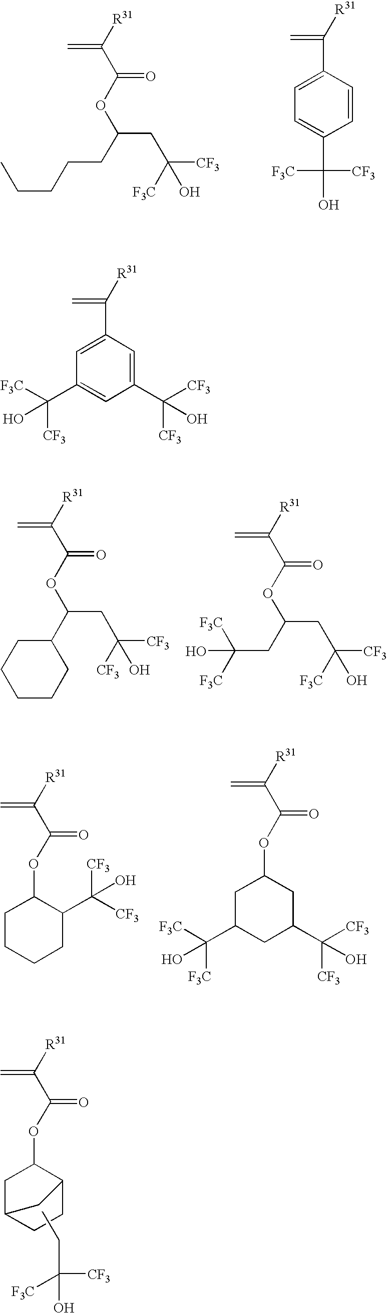

Of these, monomers of the structure having the general formula (7) are preferred because recurring units which are improved in alcohol solubility and alkaline solubility can be derived therefrom.

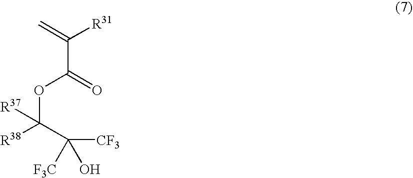

Herein R³¹ is as defined above, R³⁷ and R³⁸ are each hydrogen or a straight, branched or cyclic C₁-C₆ alkyl group, or R³⁷ and R³⁸ may bond together to form a ring, preferably C₃-C₆ alicyclic, with the carbon atom to which they are attached.

Monomers Ma2 are useful in that recurring units which are alcohol soluble and facilitate crosslinking are derived therefrom. A combination of monomers Ma1 and Ma2 increases alcohol solubility and facilitates cure by crosslinking.

Examples of suitable monomers Ma2 are shown below. R³³ is as defined above.

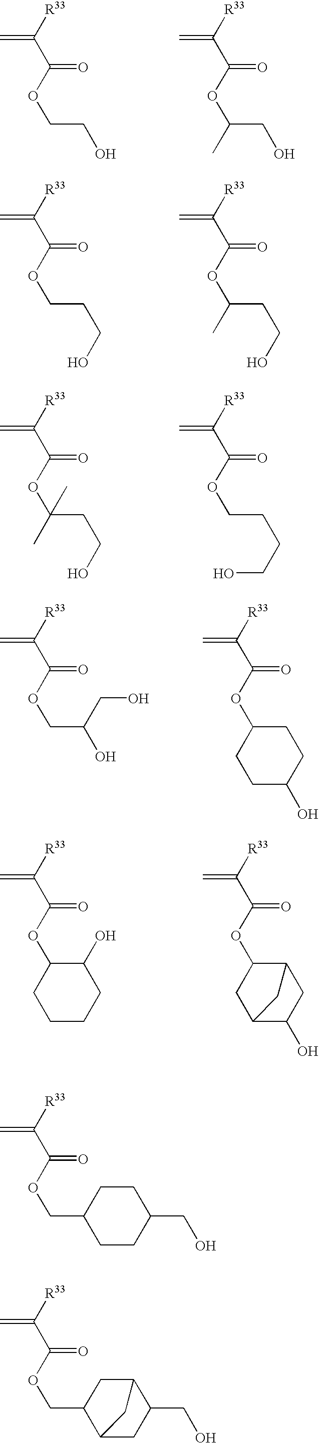

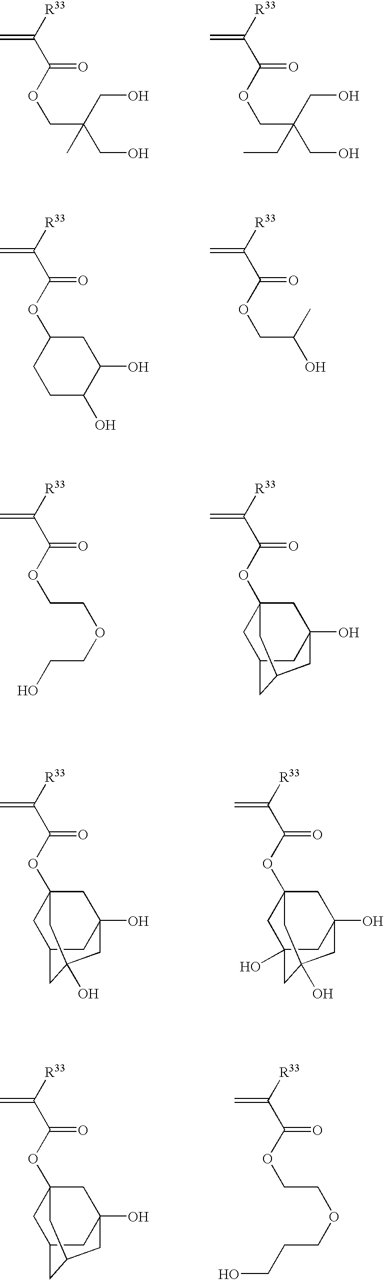

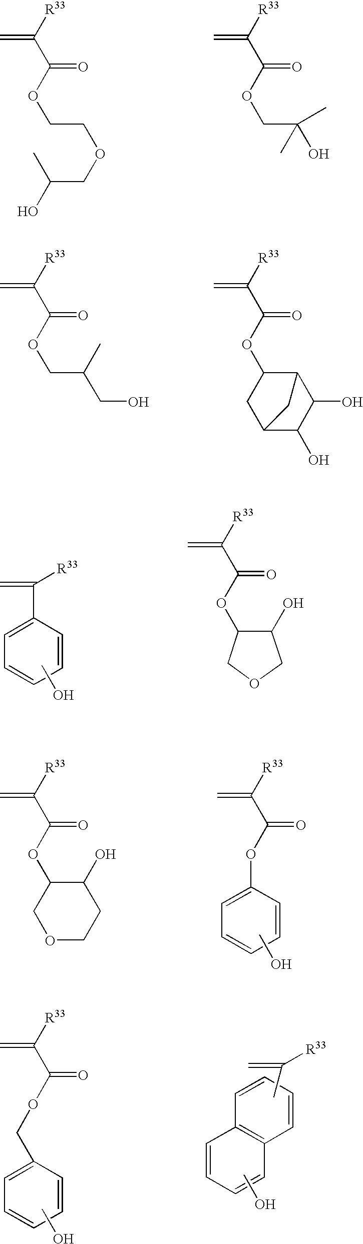

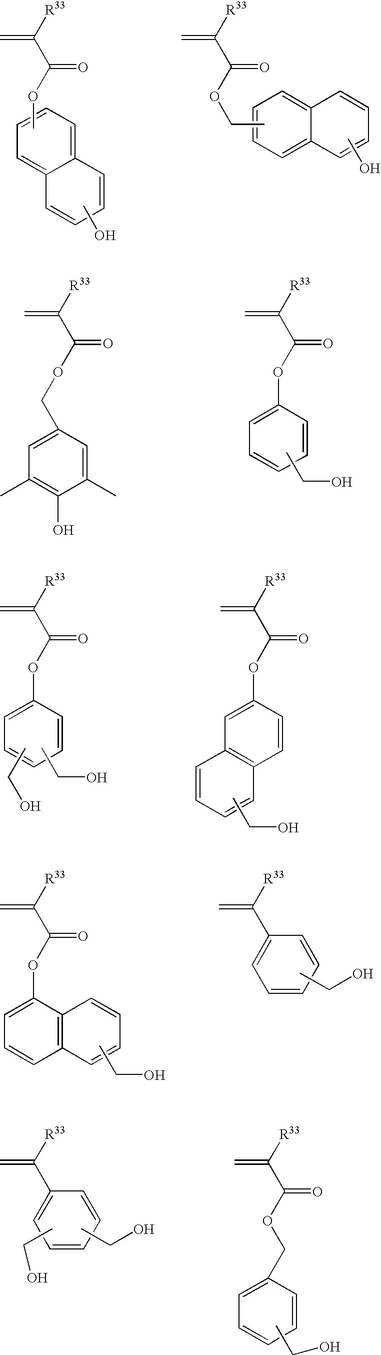

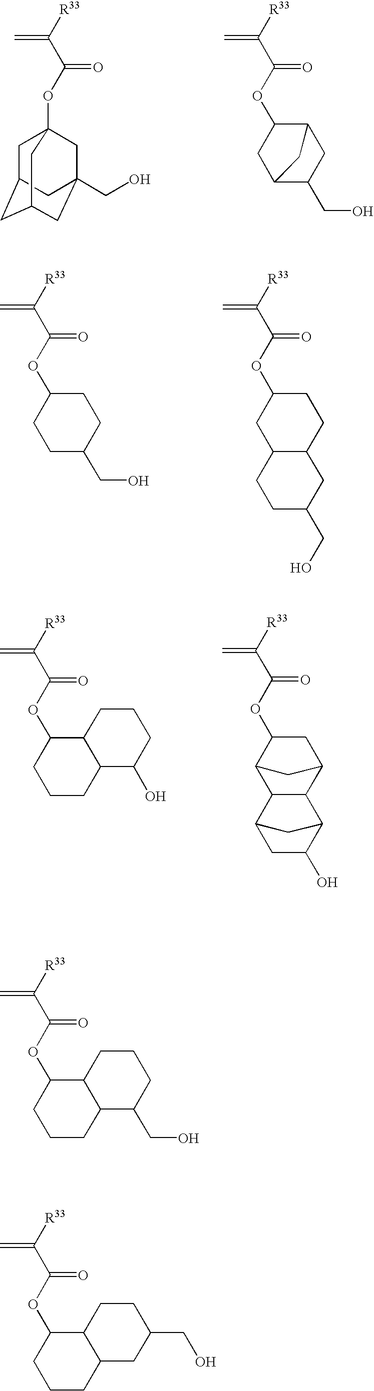

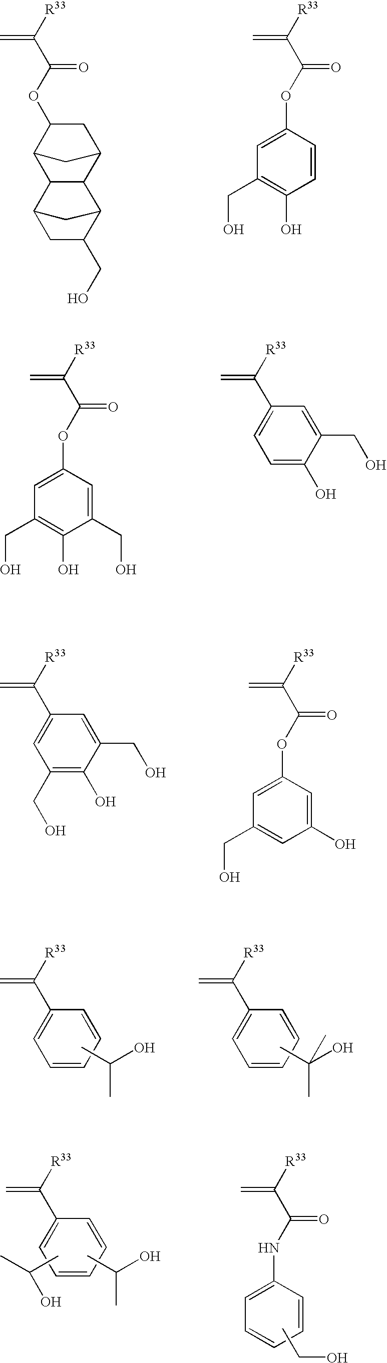

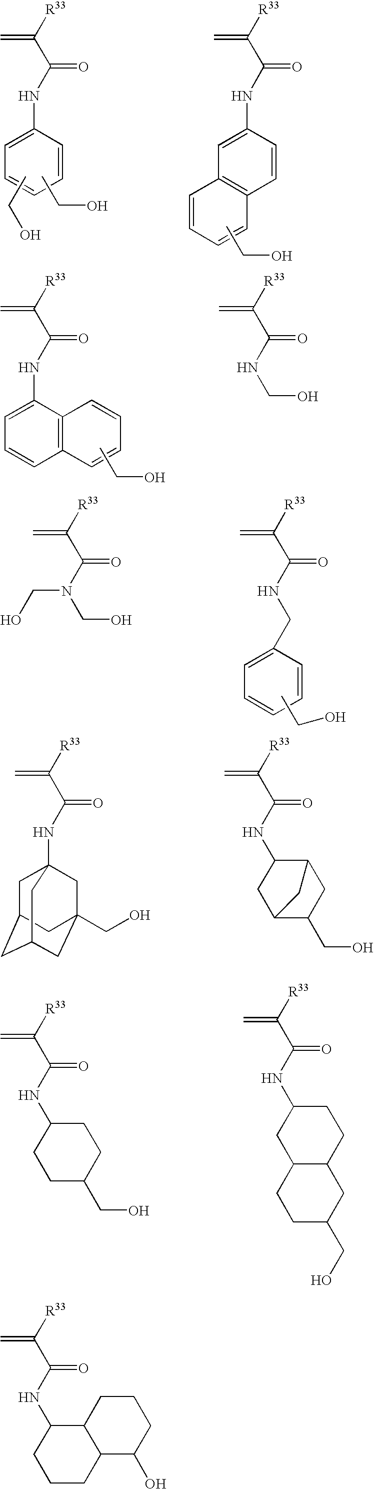

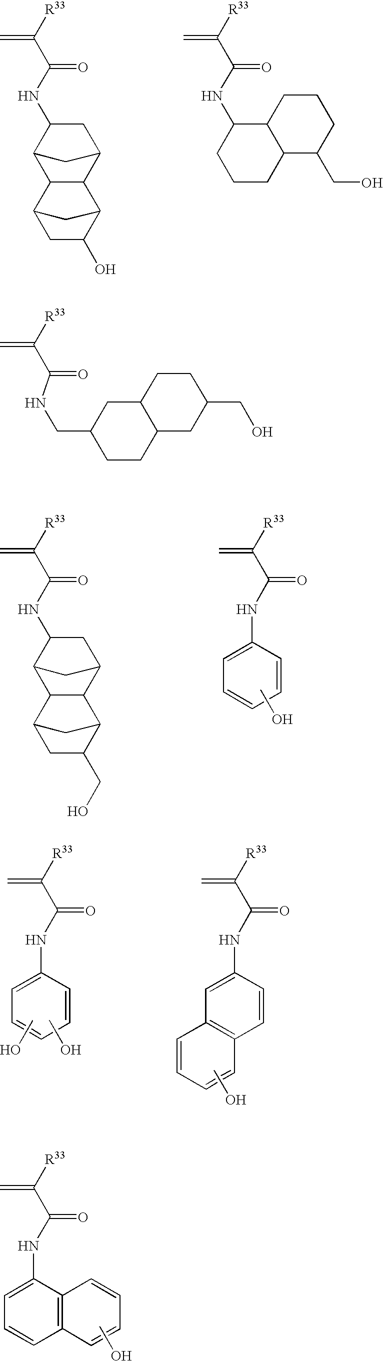

In addition to the alcohol group-containing recurring units derived from monomers Ma1 and Ma2, recurring units having an epoxy or oxetanyl group as represented by the general formula (8) may be incorporated as the crosslinkable recurring units. To incorporate such recurring units, monomers Ma3 may be copolymerized.

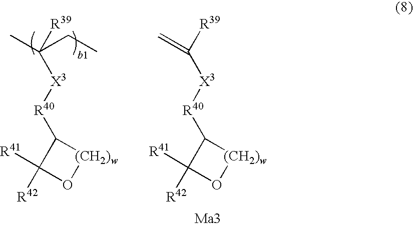

Herein R³⁹ is hydrogen or methyl. X³ is —C(═O)—O—R⁴³—, phenylene or naphthylene. R⁴³ is a single bond, or a C₁-C₆ alkylene or C₆-C₁₀ arylene group which may have an ether, ester, hydroxy or carboxyl radical. R⁴⁰ is a straight, branched or cyclic C₁-C₁₂ alkylene group. R⁴¹ is hydrogen or a straight, branched or cyclic C₁-C₆ alkyl group, or may bond with R⁴⁰ to form a C₃-C₈ non-aromatic ring with the carbon atoms to which they are attached. R⁴² is hydrogen or a straight, branched or cyclic C₁-C₆ alkyl group, and w is 0 or 1.

Examples of suitable monomers Ma3 from which recurring units having formula (8) are derived are shown below. R³⁹ is as defined above.

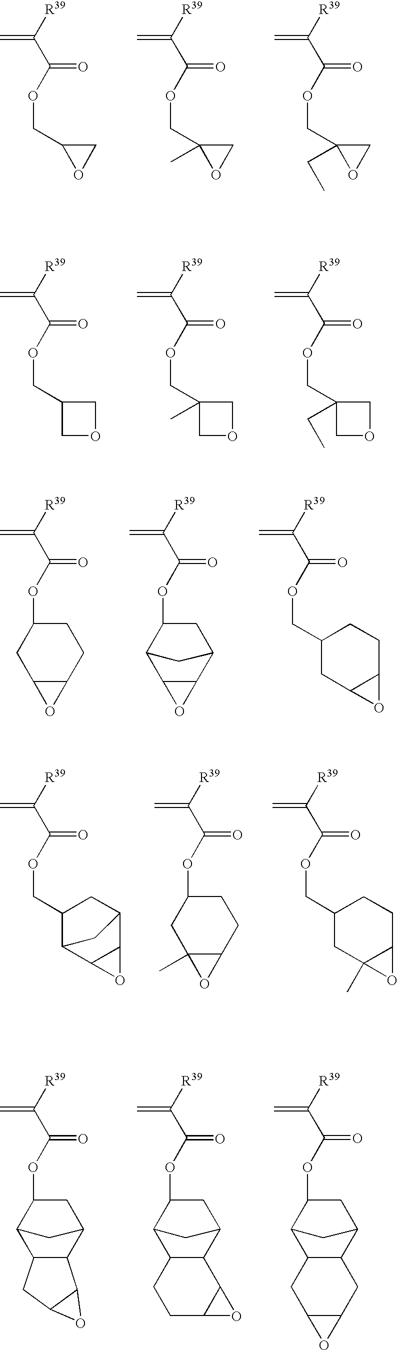

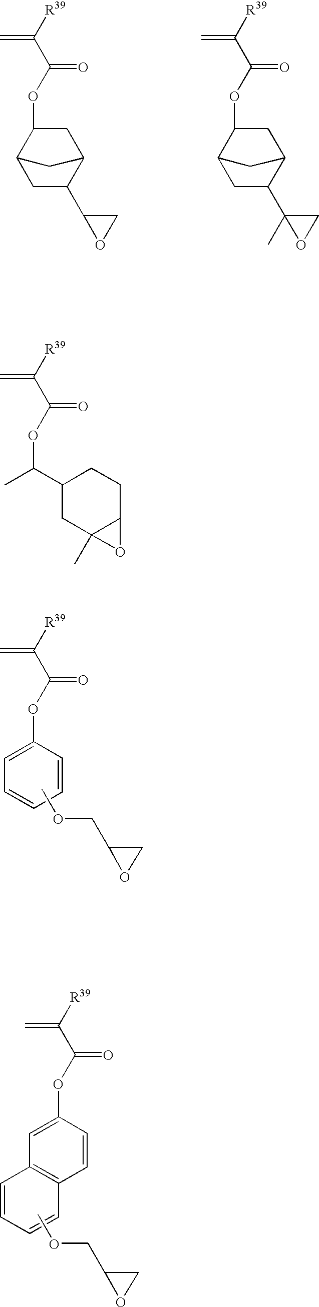

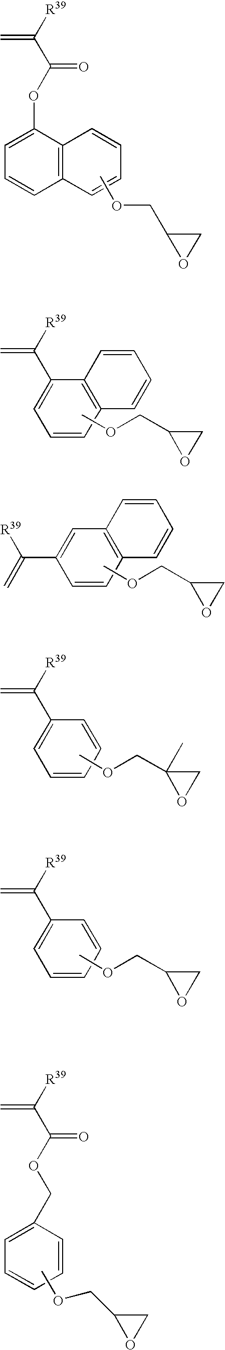

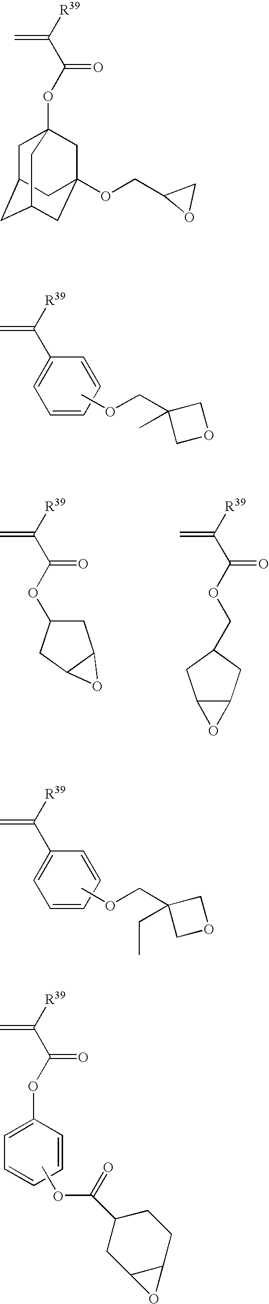

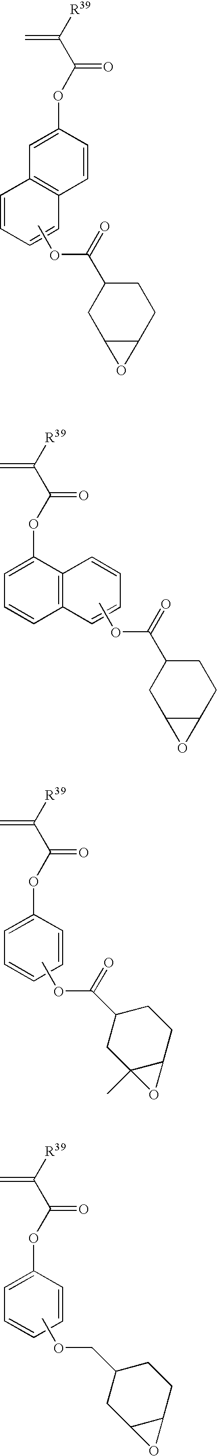

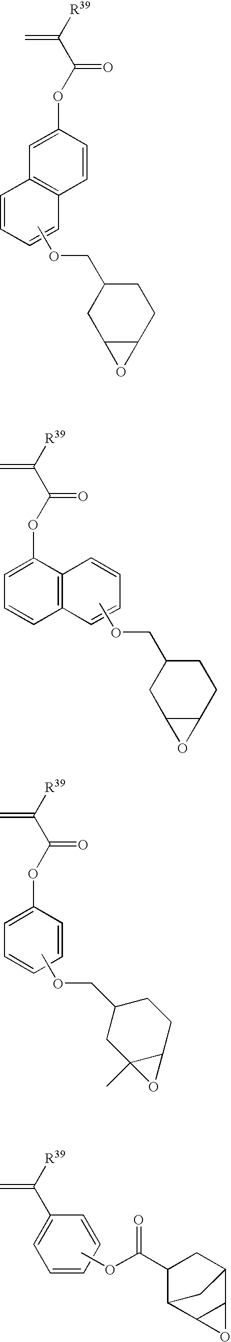

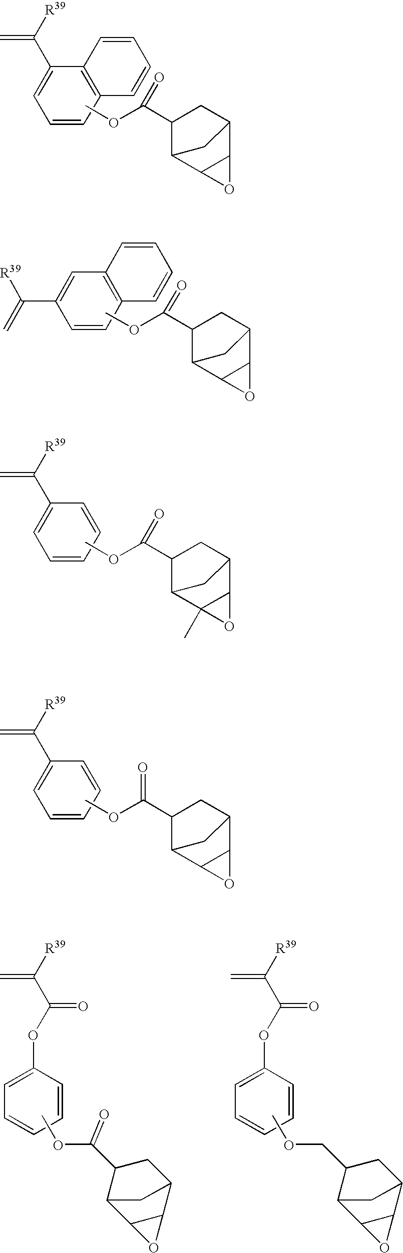

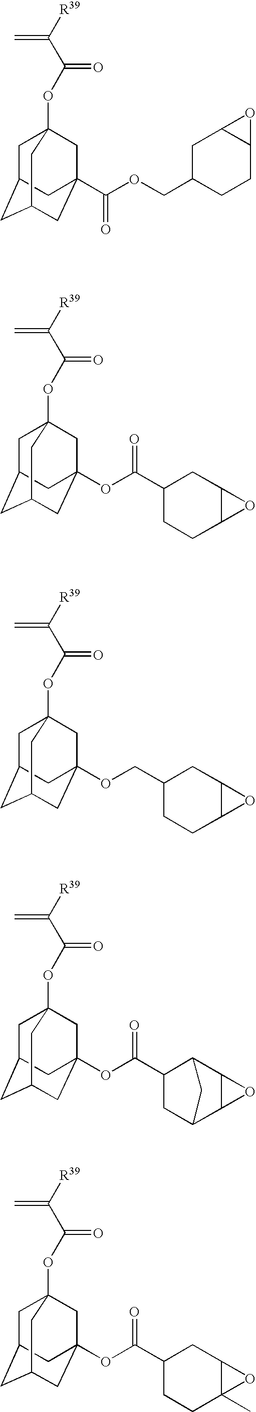

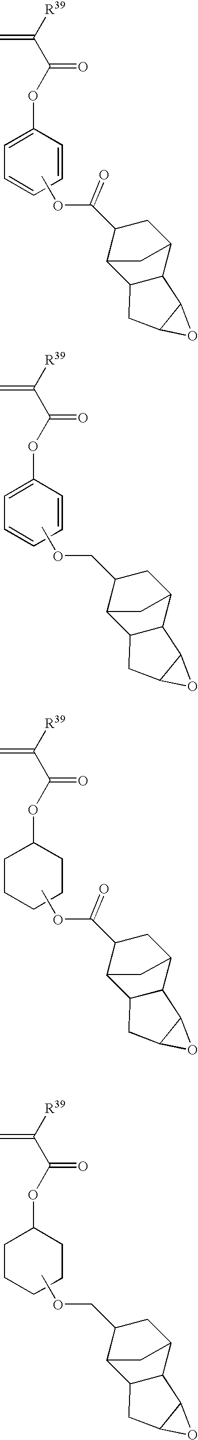

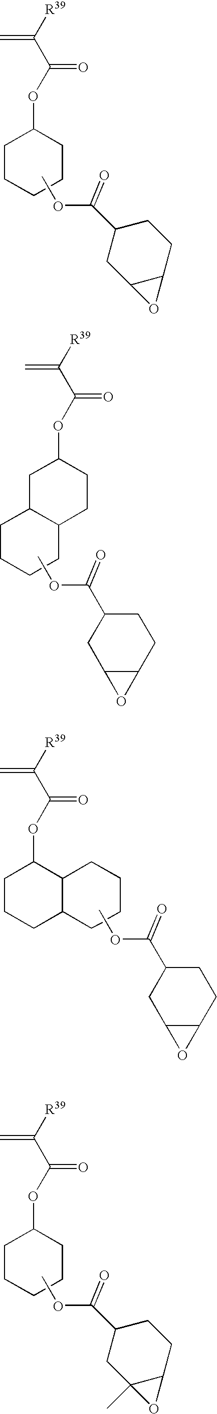

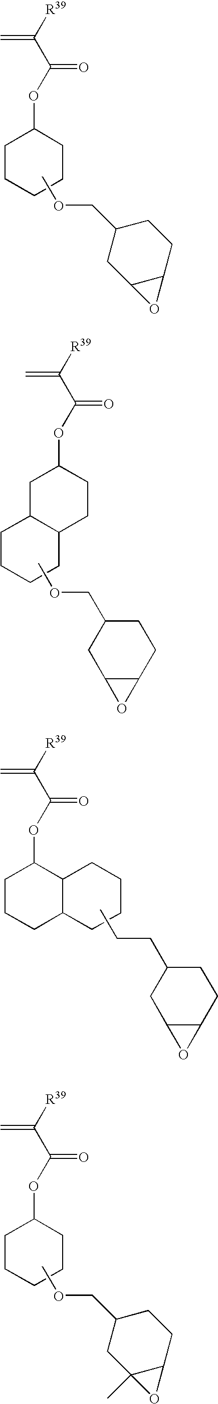

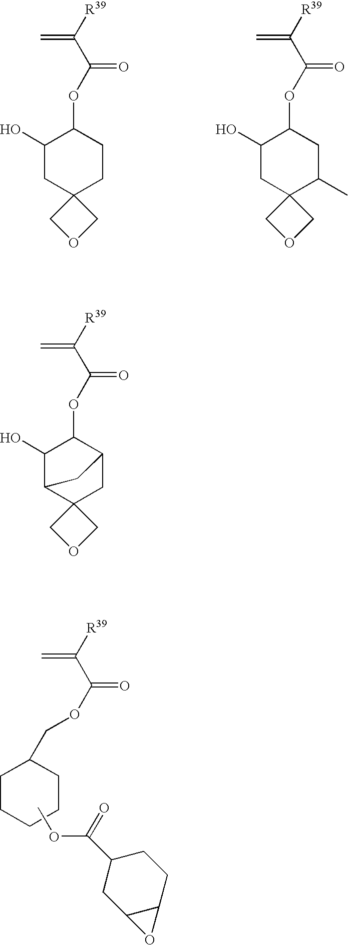

Some of the monomers from which epoxy or oxetanyl-containing recurring units are derived are disclosed in JP-A 2003-55362, JP-A 2005-08847, and JP-A 2005-18012.

Monomer Ma1 from which fluoroalcohol-containing recurring units are derived is fully soluble in alcohol solvents and alkaline solutions, but lacks crosslinking ability. Thus monomer Ma1 must be copolymerized with monomer Ma2 and/or epoxy or oxetanyl-containing monomer Ma3, before the resist surface can be covered with the polymer. A homopolymer of epoxy or oxetanyl-containing monomer Ma3 is fully crosslinkable, but lacks solubility in alcohol solvents. Thus monomer Ma3 must be copolymerized with monomer Ma1 and/or Ma2.

In the resultant copolymer, a1, a2 and b1 indicative of proportions of respective recurring units are in the range: 0≦a1≦1.0, 0≦a2≦1.0, 0<a1+a2≦1.0, especially 0.1≦a1+a2≦1.0, and 0≦b1≦0.9; and preferably 0≦a1≦0.8, 0≦a2≦0.8, 0.2≦a1+a2≦1.0, and 0≦b1≦0.8. Note that a1+a2+b≦1.

In another embodiment, the first resist pattern is vapor primed with the amine or oxazoline compound. Vapor priming may be done by bubbling nitrogen or similar gas into a solution of the amine or oxazoline compound and spraying the resultant gas against the first resist pattern. It is a common practice in the art that silicon substrates are vapor primed with hexamethyldisilazane (HMDS) in the track for the purpose of facilitating adhesion of substrates. The vapor priming technique may be implemented simply by replacing HMDS with the amine or oxazoline compound. The amine or oxazoline compound which can be used in vapor priming takes the form of a solution which can be bubbled and which should have a boiling point of up to 300° C. During vapor priming, the substrate may be baked at a temperature of 50 to 150° C. for the purpose of facilitating adsorption of the amine or oxazoline compound to the resist pattern. Following the vapor priming, the substrate may be baked again for the purpose of removing the amine or oxazoline compound deposited on the substrate. The solution for vapor priming may consist of 100% the amine or oxazoline compound or be diluted with an organic solvent.

### Resist Composition

The first resist composition for forming the first resist pattern comprises as a base resin a polymer comprising recurring units (a⁰) having lactone as an adhesive group and recurring units (b) having an acid labile group, preferably represented by the formula (A).

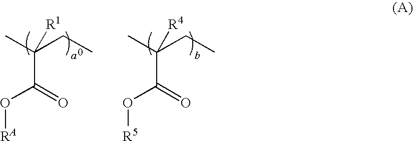

Herein R¹ and R⁴ are hydrogen or methyl, R^{A} is a monovalent organic group having lactone structure, R⁵ is an acid labile group, a⁰ and b are numbers in the range: 0<a⁰<1.0, 0<b<1.0, and 0<a⁰+b≦1.0.

Examples of recurring units (a⁰) are the same as will be later exemplified for the recurring units having lactone structure among recurring units (d). Recurring units (b) will be described later. In addition to the recurring units) (a⁰) and (b), the base resin in the first resist composition may further comprise recurring units belonging to recurring units (d) except those having lactone structure.

The second resist composition is used to form a second resist pattern through second coating, exposure and development steps. The second positive resist composition comprises a base resin and a solvent which contains an alcohol of 3 to 8 carbon atoms or a mixture of an alcohol of 3 to 8 carbon atoms and an ether of 6 to 12 carbon atoms and which does not dissolve away the first resist pattern. The base polymer must be dissolved in this solvent. The polymer to be dissolvable in this solvent should preferably have a 2,2,2-trifluoro-1-hydroxyethyl group or hydroxynaphthyl group, and is typically a copolymer comprising recurring units having the general formula (9).

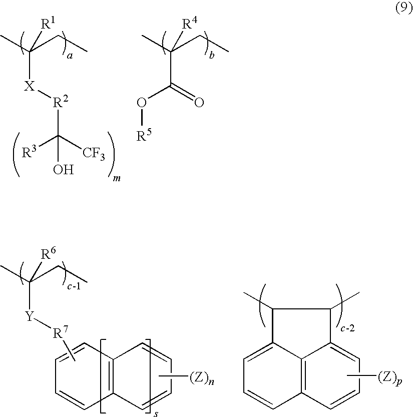

Herein R¹, R⁴ and R⁶ each are hydrogen or methyl. X is —O— or —C(═O)—O—. R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R². R⁵ is an acid labile group. R⁶ is hydrogen or methyl, Y is a single bond or —C(═O)—O—, R⁷ is a single bond or a straight or branched C₁-C₆ alkylene group. Z is a hydroxy or carboxyl group. The subscripts m, n and p each are 1 or 2, and s is 0 or 1. The subscripts a, b, c−1, and c−2 are numbers in the range: 0<a<1.0, 0<b<1.0, 0≦(c−1)<1.0, 0≦(c−2)<1.0, and 0<a+b+(c−1)+(c−2)≦1.0, and preferably 0<(c−1)+(c−2)<1.0.

Monomers from which recurring units (a) are derived include the aforementioned monomers Ma1 and the following monomers wherein R¹ is as defined above.

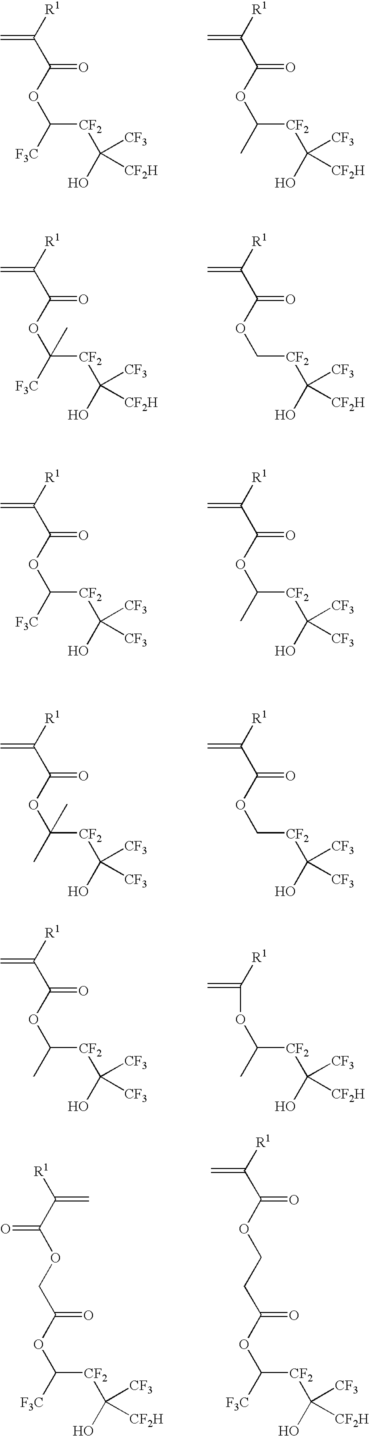

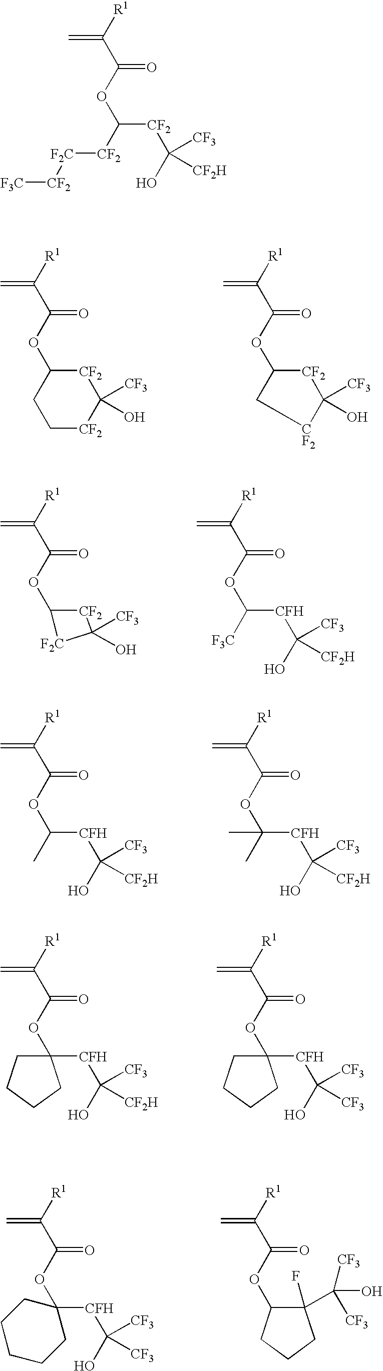

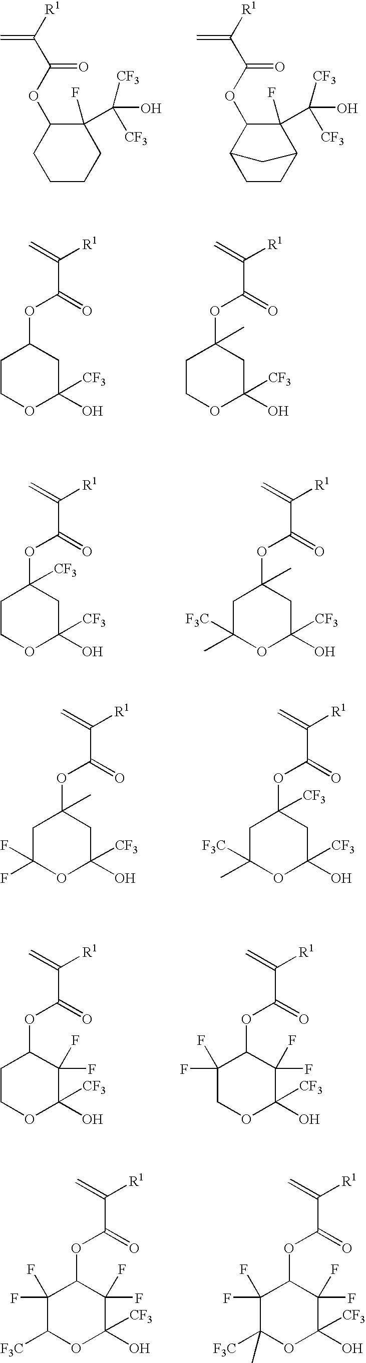

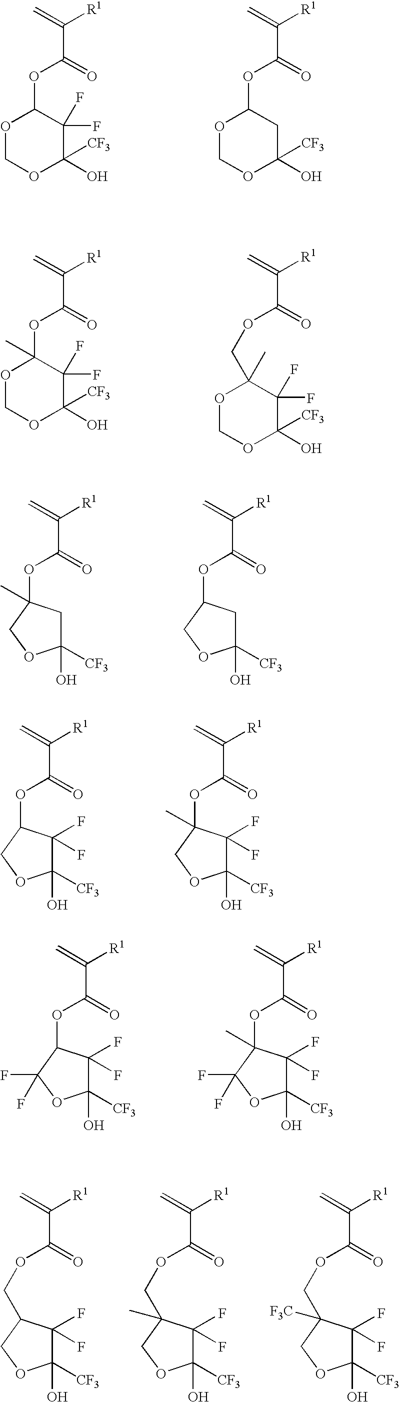

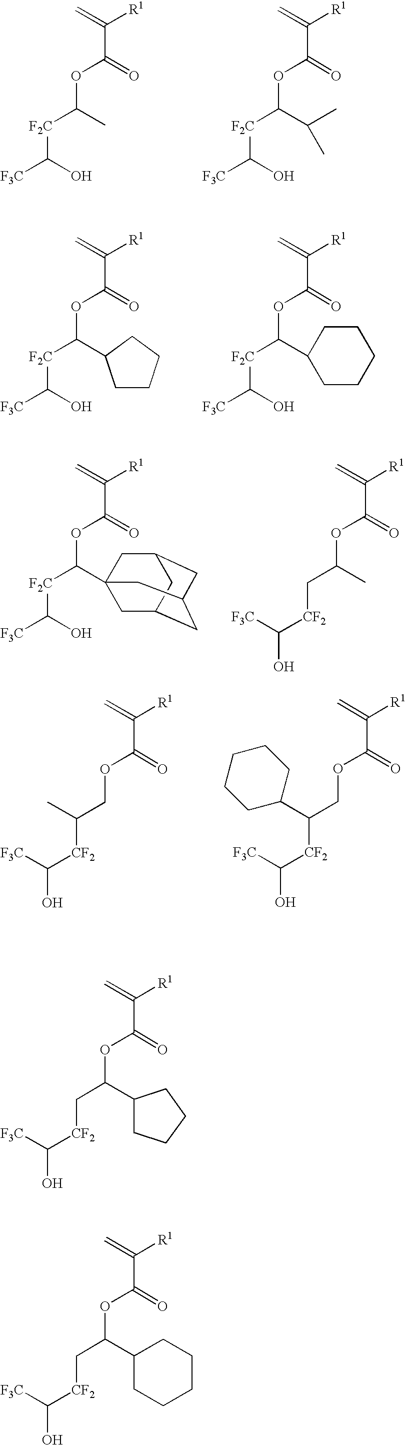

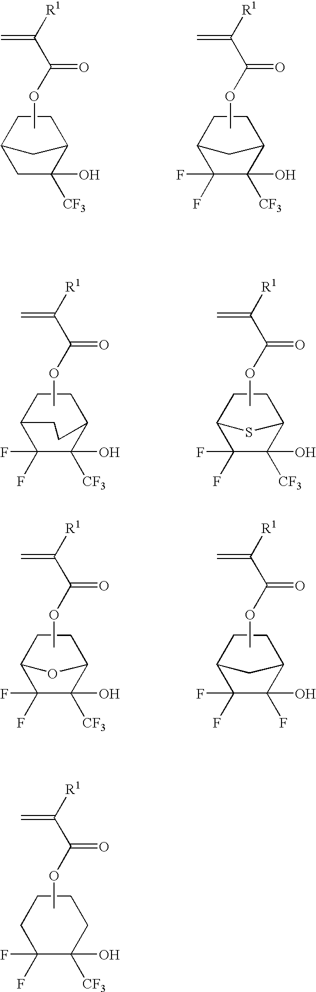

Monomers from which recurring units (c−1) and (c−2) are derived are given below wherein R⁶ is as defined above. It is noted that hydroxyvinylnaphthalene copolymers are described in JP 3829913 and hydroxyacenaphthylene copolymers are described in JP 3796568.

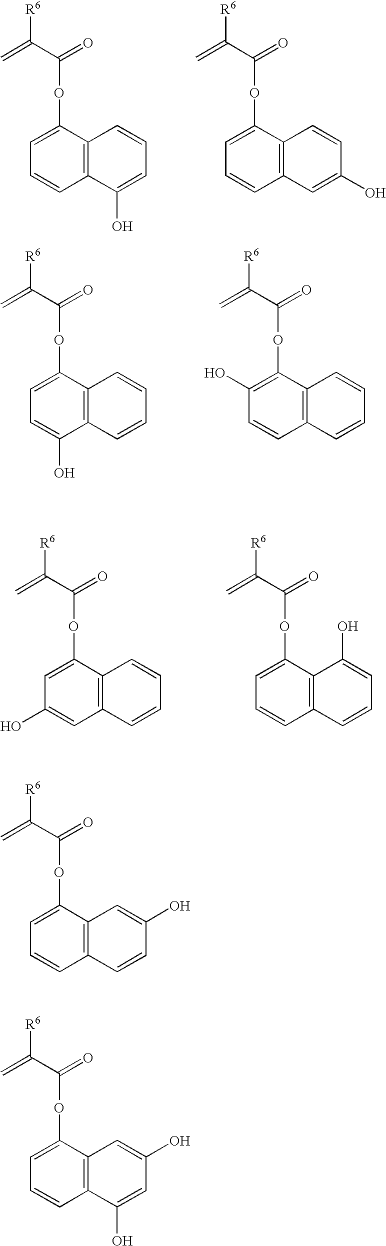

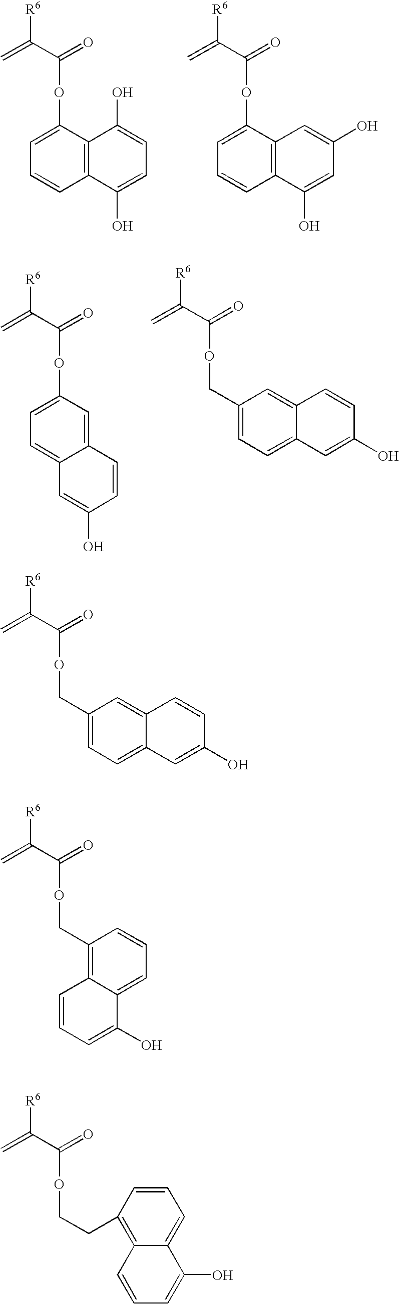

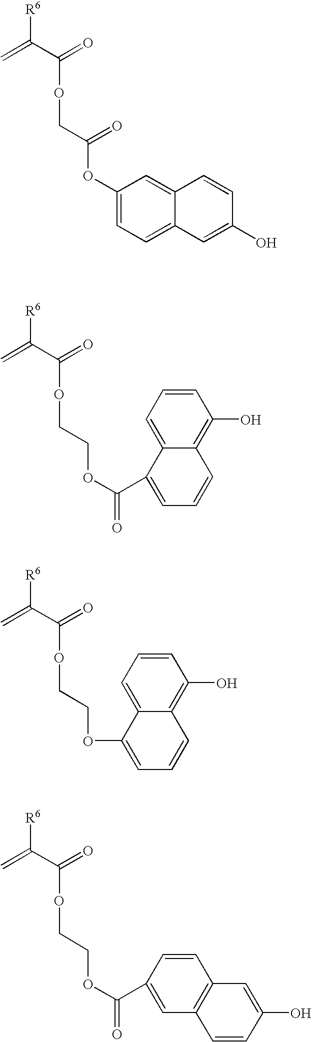

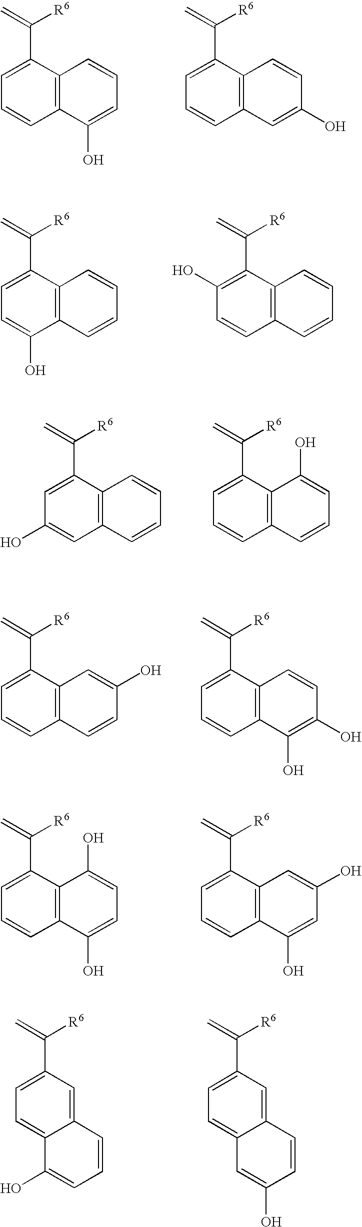

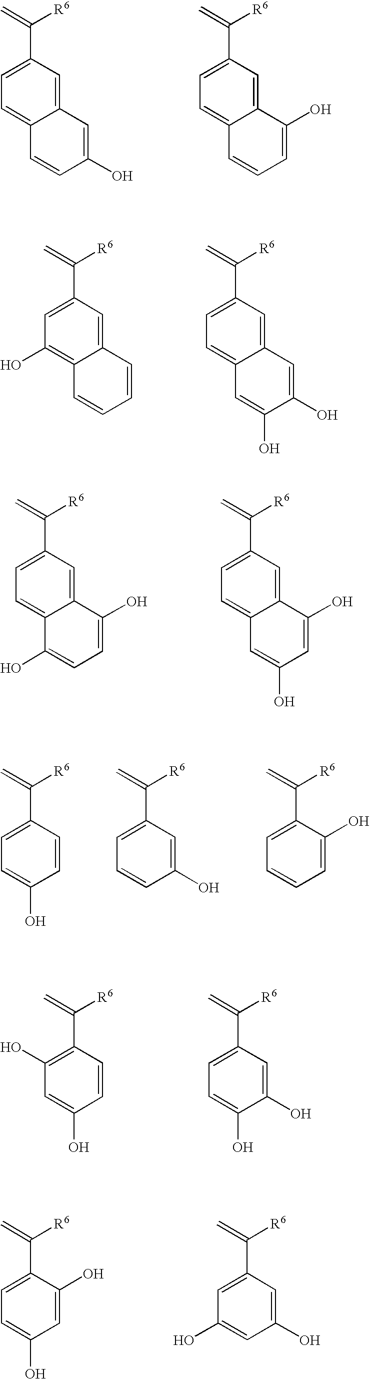

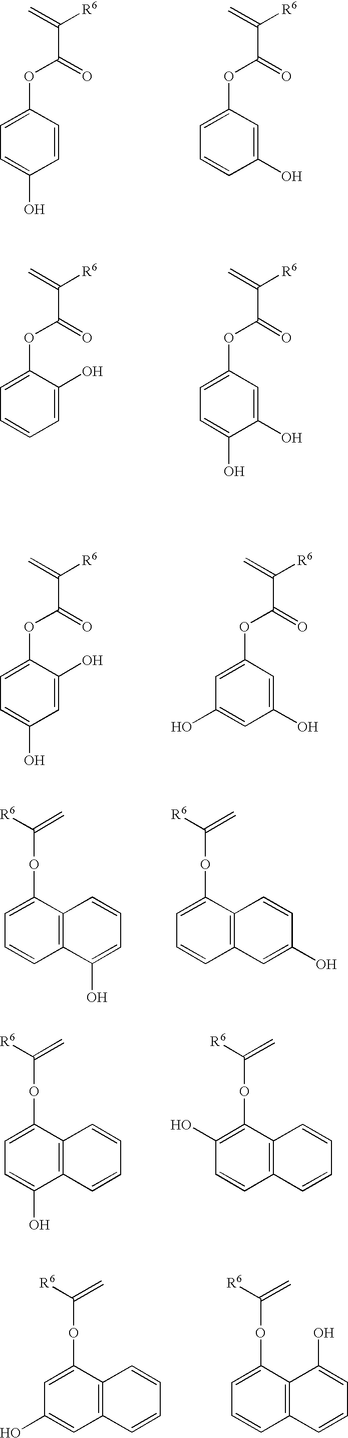

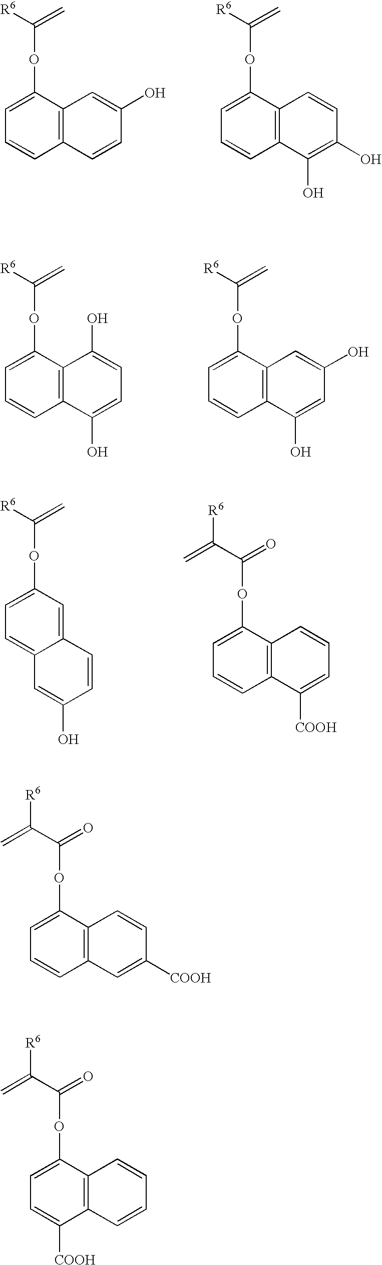

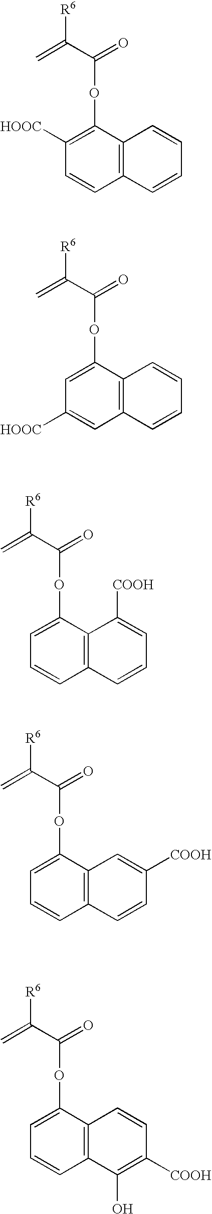

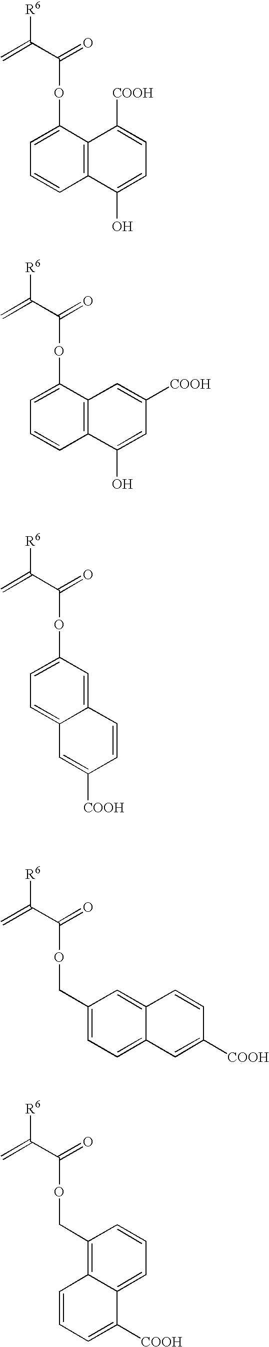

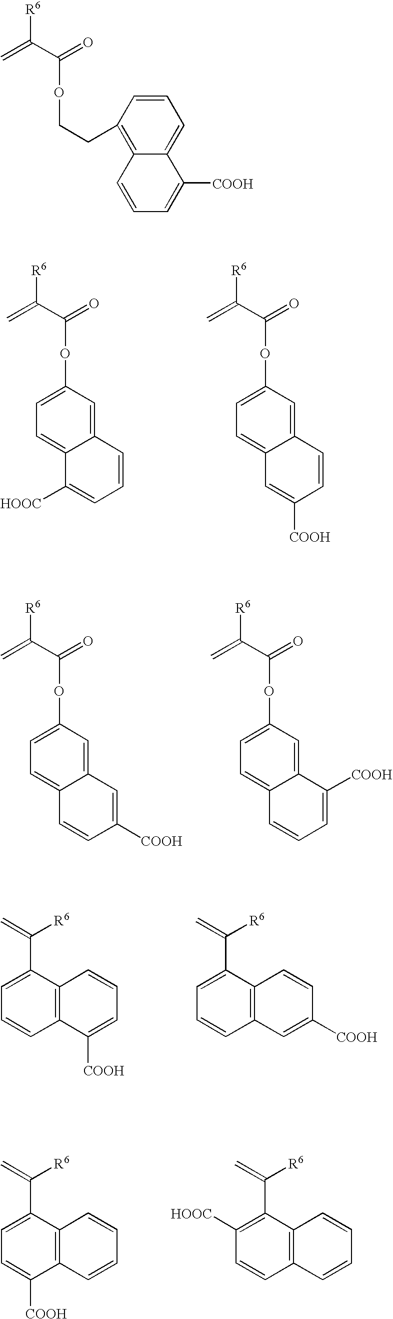

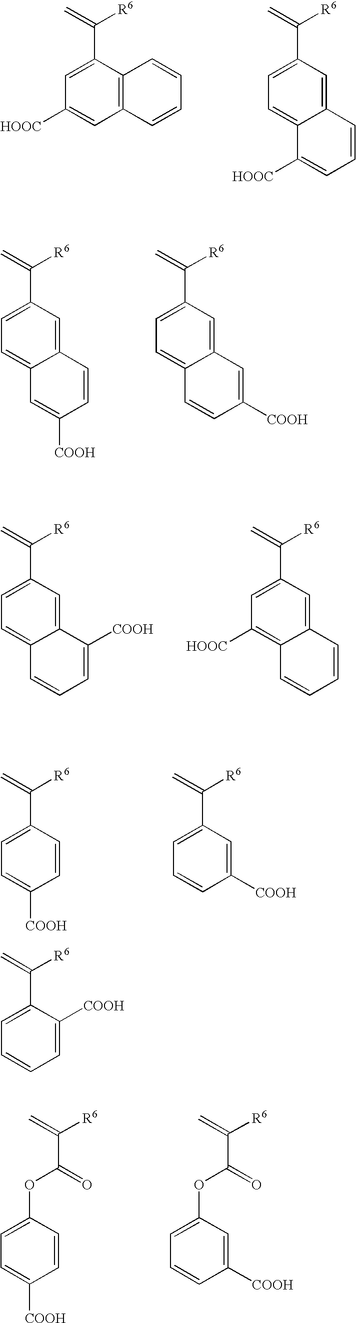

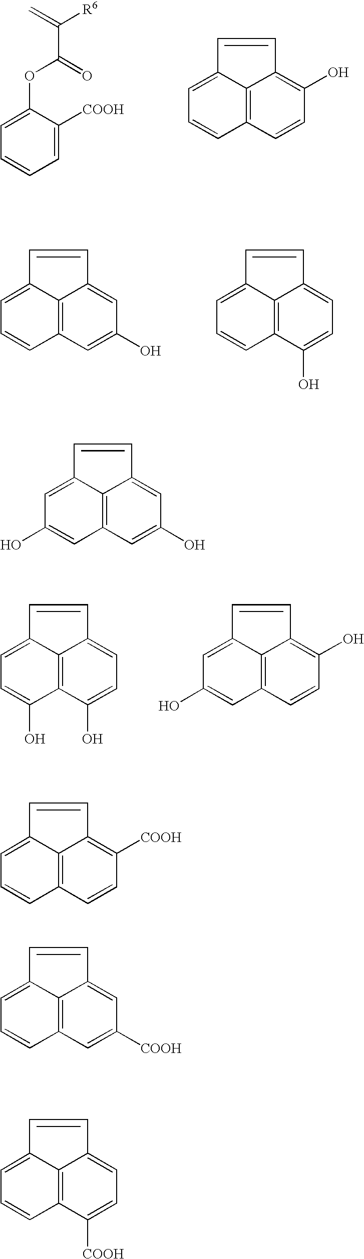

As the monomers corresponding to recurring units (a), (c−1) and (c−2), those monomers wherein a hydroxyl group is substituted by an acetal group or a formyl, acetyl or pivaloyl group may be used in polymerization. After polymerization, the acetal group can be converted back to a hydroxy group by hydrolysis with an acid. The formyl, acetyl or pivaloyl group can be converted back to a hydroxy group by alkaline hydrolysis.

The polymer used as the base resin in the second resist composition comprises recurring units (b) having an acid labile group in addition to the recurring units (a). It is noted that the polymer used as the base resin in the first resist composition also comprises similar recurring units (b) having an acid labile group.

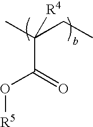

Herein R⁴ is hydrogen or methyl, and R⁵ is an acid labile group.

Monomers Mb from which recurring units (b) are derived are given below wherein R⁴ and R⁵ are as defined above.

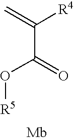

The acid labile group represented by R⁵ may be selected from a variety of such groups. The acid labile groups may be the same or different and preferably include groups of the following formulae (A-1) to (A-3).

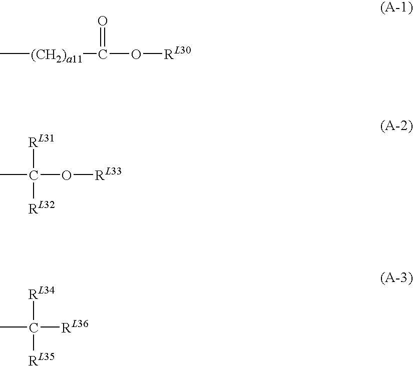

In formula (A-1), R^{L30} is a tertiary alkyl group of 4 to 20 carbon atoms, preferably 4 to 15 carbon atoms, a trialkylsilyl group in which each alkyl moiety has 1 to 6 carbon atoms, an oxoalkyl group of 4 to 20 carbon atoms, or a group of formula (A-3). Exemplary tertiary alkyl groups are tert-butyl, tert-amyl, 1,1-diethylpropyl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, and 2-methyl-2-adamantyl. Exemplary trialkylsilyl groups are trimethylsilyl, triethylsilyl, and dimethyl-tert-butylsilyl. Exemplary oxoalkyl groups are 3-oxocyclohexyl, 4-methyl-2-oxooxan-4-yl, and 5-methyl-2-oxooxolan-5-yl. Letter all is an integer of 0 to 6.

In formula (A-2), R^{L31} and R^{L32} are hydrogen or straight, branched or cyclic alkyl groups of 1 to 18 carbon atoms, preferably 1 to 10 carbon atoms. Exemplary alkyl groups include methyl, ethyl, propyl, isopropyl, n-butyl, sec-butyl, tert-butyl, cyclopentyl, cyclohexyl, 2-ethylhexyl, and n-octyl. R^{L33} is a monovalent hydrocarbon group of 1 to 18 carbon atoms, preferably 1 to 10 carbon atoms, which may contain a heteroatom such as oxygen, examples of which include straight, branched or cyclic alkyl groups and substituted forms of such alkyl groups in which some hydrogen atoms are replaced by hydroxyl, alkoxy, oxo, amino, alkylamino or the like. Illustrative examples of the substituted alkyl groups are shown below.

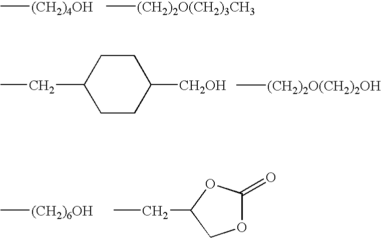

A pair of R^{L31} and R^{L32}, R^{L31} and R^{L33}, or R^{L32} and R^{L33} may bond together to form a ring with the carbon and oxygen atoms to which they are attached. Each of R^{L31}, R^{L32} and R^{L33} is a straight or branched alkylene group of 1 to 18 carbon atoms, preferably 1 to 10 carbon atoms when they form a ring, while the ring preferably consists of 3 to 10 carbon atoms, more preferably 4 to 10 carbon atoms.

Examples of the acid labile groups of formula (A-1) include tert-butoxycarbonyl, tert-butoxycarbonylmethyl, tert-amyloxycarbonyl, tert-amyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxyethoxycarbonylmethyl, 2-tetrahydropyranyloxycarbonylmethyl, and 2-tetrahydrofuranyloxycarbonylmethyl groups.

Also included are substituent groups having the formulae (A-1)-1 to (A-1)-10.

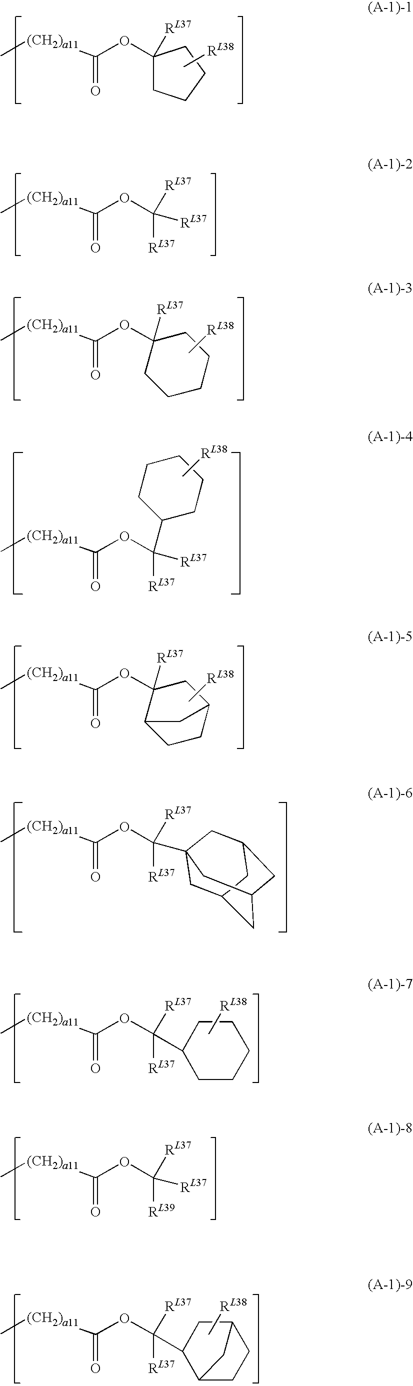

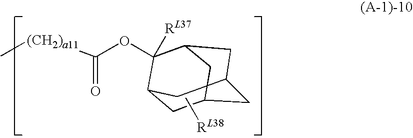

Herein R^{L37} is each independently a straight, branched or cyclic C₁-C₁₀ alkyl group or C₆-C₂₀ aryl group, R^{L38} is hydrogen or a straight, branched or cyclic C₁-C₁₀ alkyl group, R^{L39} is each independently a straight, branched or cyclic C₂-C₁₀ alkyl group or C₆-C₂₀ aryl group, and all is as defined above.

Of the acid labile groups of formula (A-2), the straight and branched ones are exemplified by the following groups having formulae (A-2)-1 to (A-2)-35.

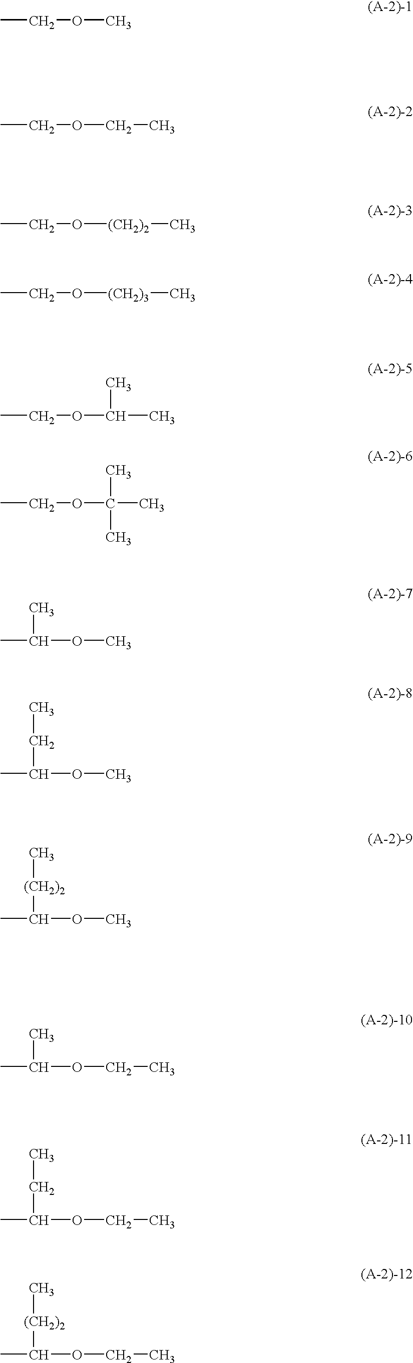

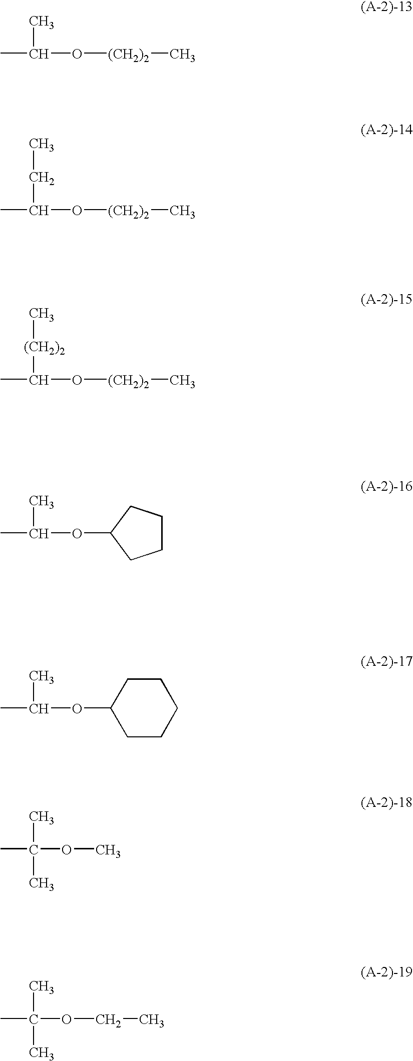

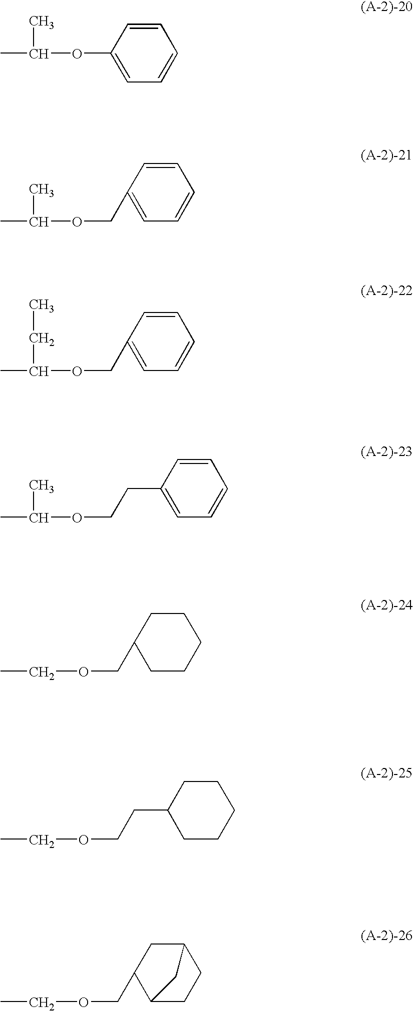

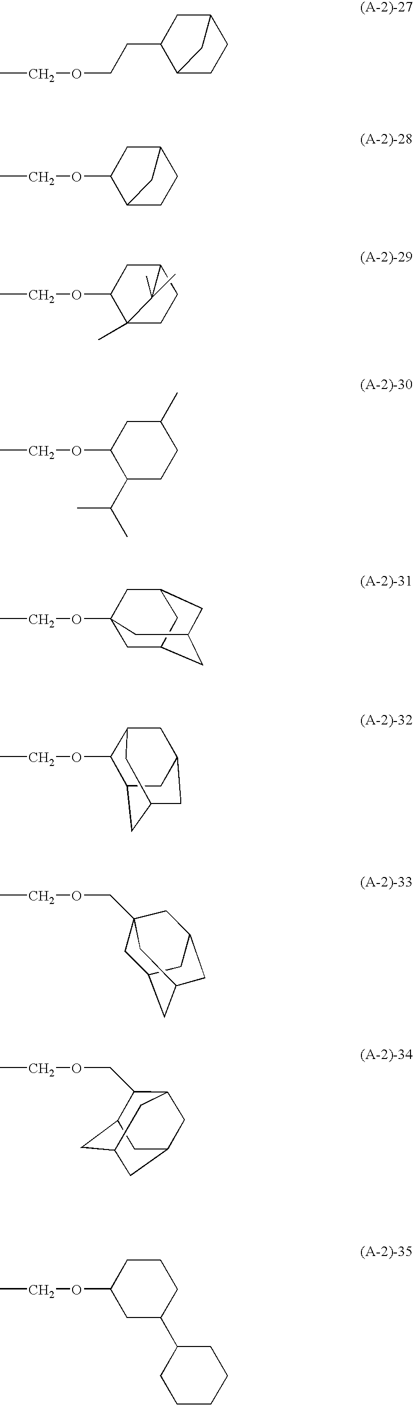

Of the acid labile groups of formula (A-2), the cyclic ones are, for example, tetrahydrofuran-2-yl, 2-methyltetrahydrofuran-2-yl, tetrahydropyran-2-yl, and 2-methyltetrahydropyran-2-yl.

Other examples of acid labile groups include those of the following formula (A-2a) or (A-2b) while the polymer may be crosslinked within the molecule or between molecules with these acid labile groups.

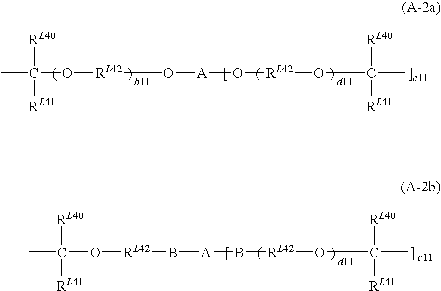

Herein R^{L40} and R^{L41} each are hydrogen or a straight, branched or cyclic C₁-C₈ alkyl group, or R^{L40} and R^{L41}, taken together, may form a ring with the carbon atom to which they are attached, and R^{L40} and R^{L41} are straight or branched C₁-C₈ alkylene groups when they form a ring. R^{L42} is a straight, branched or cyclic C₁-C₁₀ alkylene group. Each of b11 and d11 is 0 or an integer of 1 to 10, preferably 0 or an integer of 1 to 5, and c11 is an integer of 1 to 7. “A” is a (c11+1)-valent aliphatic or alicyclic saturated hydrocarbon group, aromatic hydrocarbon group or heterocyclic group having 1 to 50 carbon atoms, which may be separated by a heteroatom or in which some of the hydrogen atoms attached to carbon atoms may be substituted by hydroxyl, carboxyl, carbonyl groups or fluorine atoms. “B” is —CO—O—, —NHCO—O— or —NHCONH—.

Preferably, “A” is selected from divalent to tetravalent, straight, branched or cyclic C₁-C₂₀ alkylene, alkyltriyl and alkyltetrayl groups, and C₆-C₃₀ arylene groups, which may contain a heteroatom or in which some of the hydrogen atoms attached to carbon atoms may be substituted by hydroxyl, carboxyl, acyl groups or halogen atoms. The subscript c11 is preferably an integer of 1 to 3.

The crosslinking acetal groups of formulae (A-2a) and (A-2b) are exemplified by the following formulae (A-2)-36 through (A-2)-43.

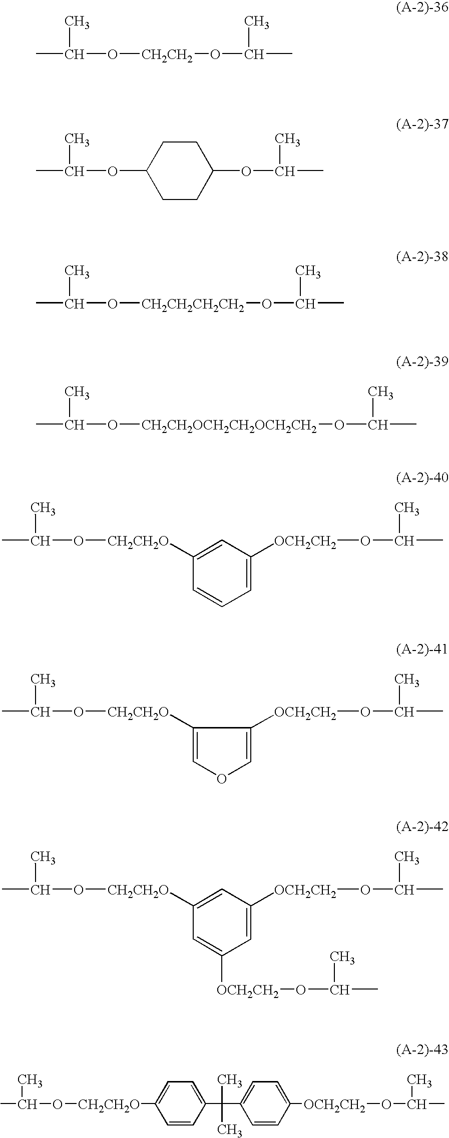

In formula (A-3), R^{L34}, R^{L35} and R^{L36} each are a monovalent hydrocarbon group, typically a straight, branched or cyclic C₁-C₂₀ alkyl group, which may contain a heteroatom such as oxygen, sulfur, nitrogen or fluorine. A pair of R^{L34} and R^{L35}, R^{L34} and R^{L36}, or R^{L35} and R^{L36} may bond together to form a C₃-C₂₀ alicyclic ring with the carbon atom to which they are attached.

Exemplary tertiary alkyl groups of formula (A-3) include tert-butyl, triethylcarbyl, 1-ethylnorbornyl, 1-methylcyclohexyl, 1-ethylcyclopentyl, 2-(2-methyl)adamantyl, 2-(2-ethyl)adamantyl, and tert-amyl.

Other exemplary tertiary alkyl groups include those of the following formulae (A-3)-1 to (A-3)-18.

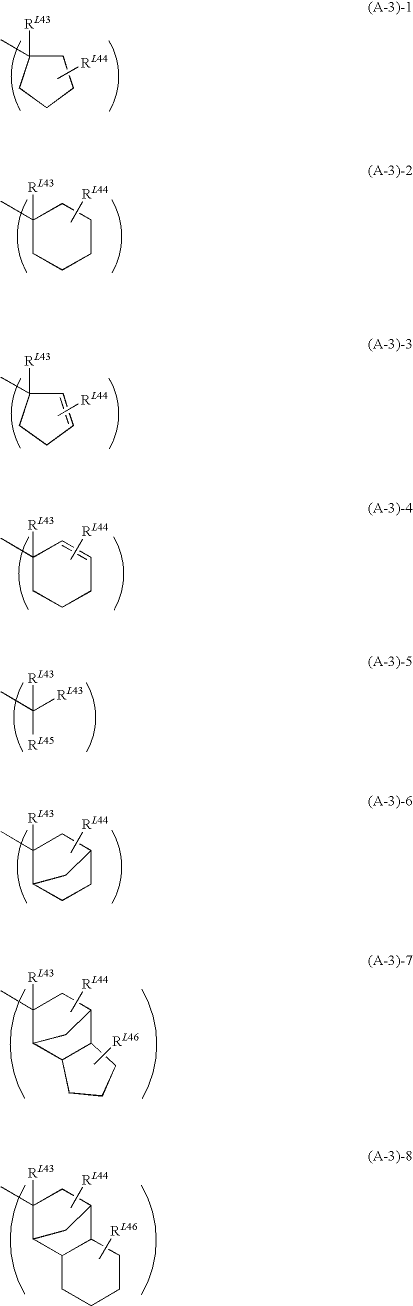

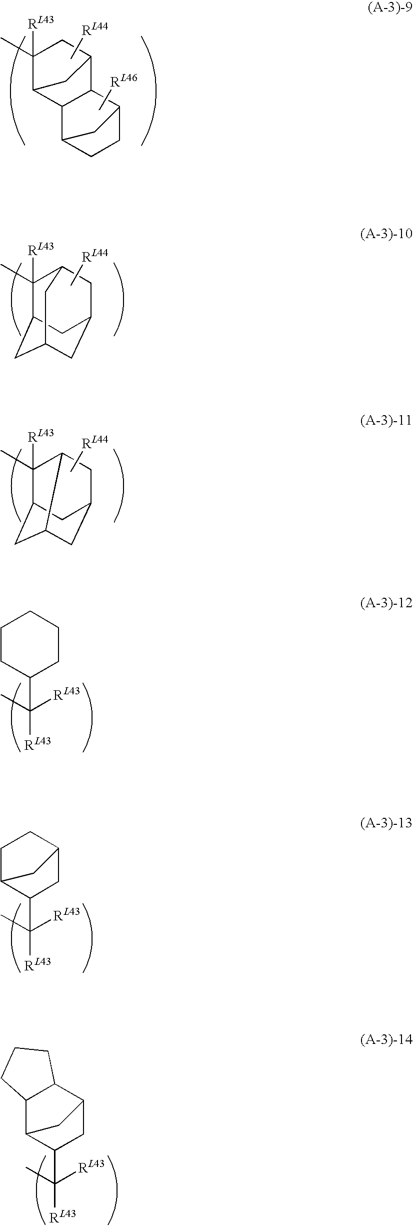

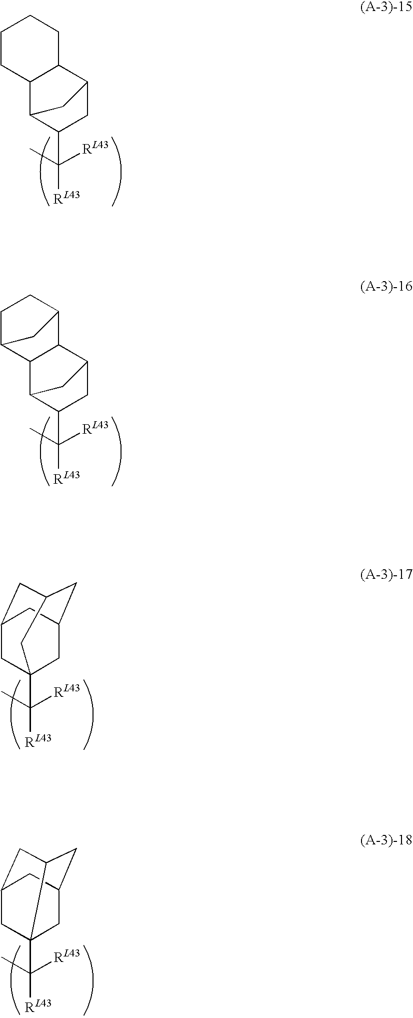

Herein R^{L43} is each independently a straight, branched or cyclic C₁-C₈ alkyl group or C₆-C₂₀ aryl group, typically phenyl, R^{L44} and R^{L46} each are hydrogen or a straight, branched or cyclic C₁-C₂₀ alkyl group, and R^{L45} is a C₆-C₂₀ aryl group, typically phenyl.

The polymer may be crosslinked within the molecule or between molecules with groups having R^{L47} which is a di- or multi-valent alkylene or arylene group, as shown by the following formulae (A-3)-19 and (A-3)-20.

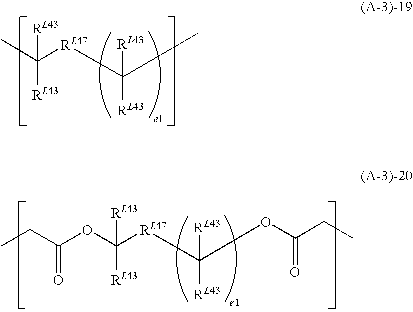

Herein R^{L43} is as defined above, R^{L47} is a straight, branched or cyclic C₁-C₂₀ alkylene group or arylene group, typically phenylene, which may contain a heteroatom such as oxygen, sulfur or nitrogen, and e1 is an integer of 1 to 3.

In formulae (A-1), (A-2), and (A-3), R^{L30}, R^{L33}, and R^{L36} also stand for substituted or unsubstituted aryl groups such as phenyl, p-methylphenyl, p-ethylphenyl and alkoxy-substituted phenyl, typically p-methoxyphenyl, and aralkyl groups such as benzyl and phenethyl, which may contain an oxygen atom, or in which hydrogen atoms attached to carbon atoms are replaced by hydroxyl groups, or in which two hydrogen atoms are replaced by an oxygen atom to form a carbonyl group, as exemplified by alkyl groups and oxoalkyl groups of the following formulae.

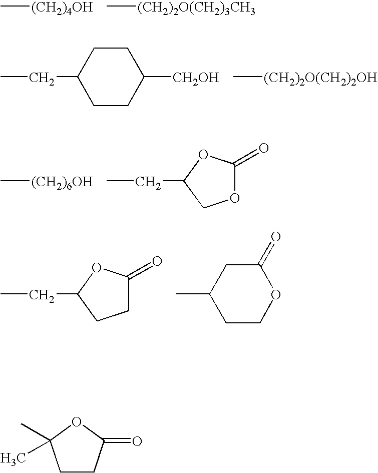

Of recurring units having acid labile groups of formula (A-3), recurring units of (meth)acrylate having an exo-form structure represented by the formula (A-3)-21 are preferred.

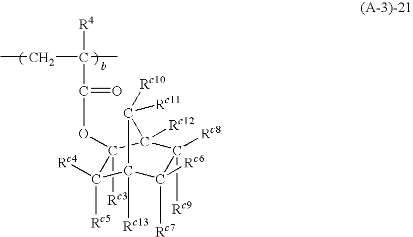

Herein, R⁴ and b are as defined above; R^{c3} is a straight, branched or cyclic C₁-C₈ alkyl group or an optionally substituted C₆-C₂₀ aryl group; R^{c4} to R^{c9}, R^{c12} and R^{c13} are each independently hydrogen or a monovalent C₁-C₁₅ hydrocarbon group which may contain a heteroatom; and R^{c10} and R^{c11} are hydrogen. Alternatively, a pair of R^{c4} and R^{c5}, R^{c6} and R^{c8}, R^{c6} and R^{c9}, R^{c7} and R^{c9}, R^{c7} and R^{c13}, R^{c8} and R^{c12}, R^{c10} and R^{c11}, or R^{c11} and R^{c12}, taken together, may form a ring, and in this case, each ring-forming R is a divalent C₁-C₁₅ hydrocarbon group which may contain a heteroatom. Also, a pair of R^{c4} and R^{c13}, R^{c10} and R^{c13}, or R^{c6} and R^{c8} which are attached to vicinal carbon atoms may bond together directly to form a double bond. R^{c14} is hydrogen or a straight, branched or cyclic C₁-C₁₅ alkyl group. The formula also represents an enantiomer.

The ester form monomers from which recurring units having an exo-form structure represented by formula (A-3)-21 are derived are described in U.S. Pat. No. 6,448,420 (JP-A 2000-327633). Illustrative non-limiting examples of suitable monomers are given below.

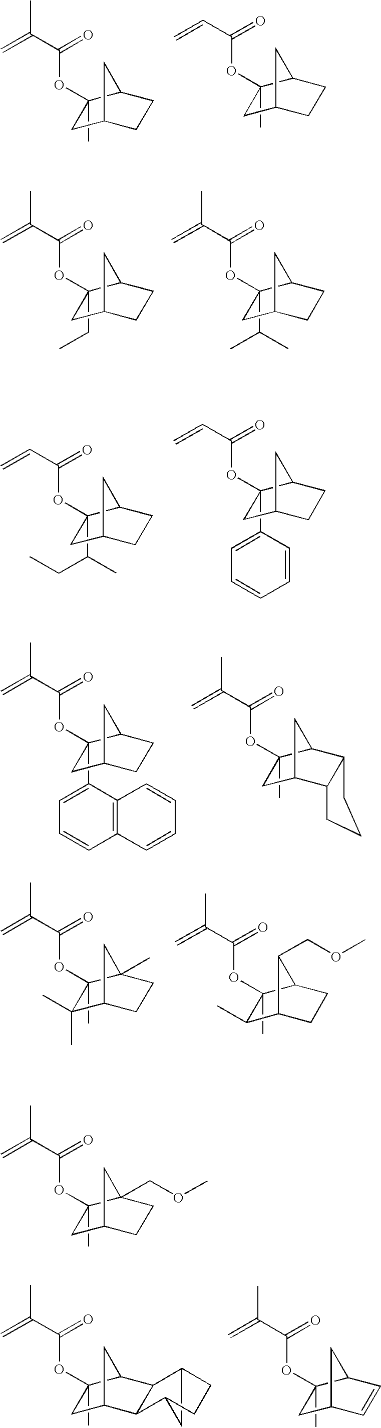

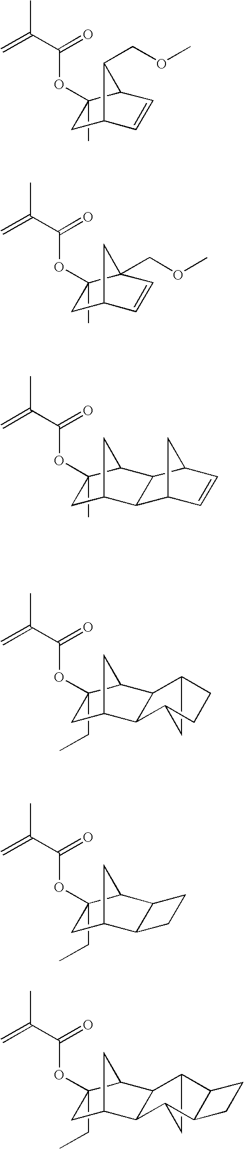

Also included in the acid labile groups of formula (A-3) are acid labile groups of (meth)acrylate having furandiyl, tetrahydrofurandiyl or oxanorbornanediyl as represented by the following formula (A-3)-22.

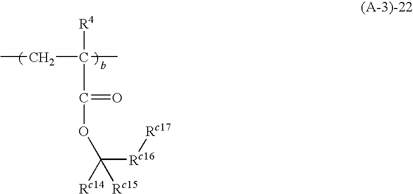

Herein, R⁴ and b are as defined above; R^{c14} and R^{c15} are each independently a monovalent, straight, branched or cyclic C₁-C₁₀ hydrocarbon group, or R^{c14} and R^{c15}, taken together, may form an aliphatic hydrocarbon ring with the carbon atom to which they are attached. R^{c16} is a divalent group selected from furandiyl, tetrahydrofurandiyl and oxanorbornanediyl. R^{c17} is hydrogen or a monovalent, straight, branched or cyclic C₁-C₁₀ hydrocarbon group which may contain a heteroatom.

Examples of the monomers from which the recurring units substituted with acid labile groups having furandiyl, tetrahydrofurandiyl and oxanorbornanediyl are derived are shown below. Note that Me is methyl and Ac is acetyl.

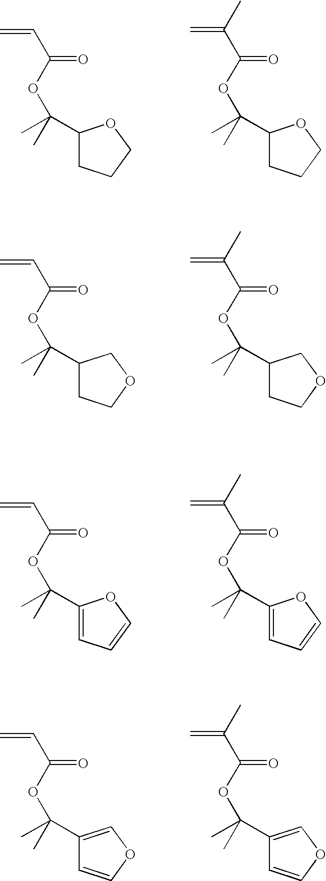

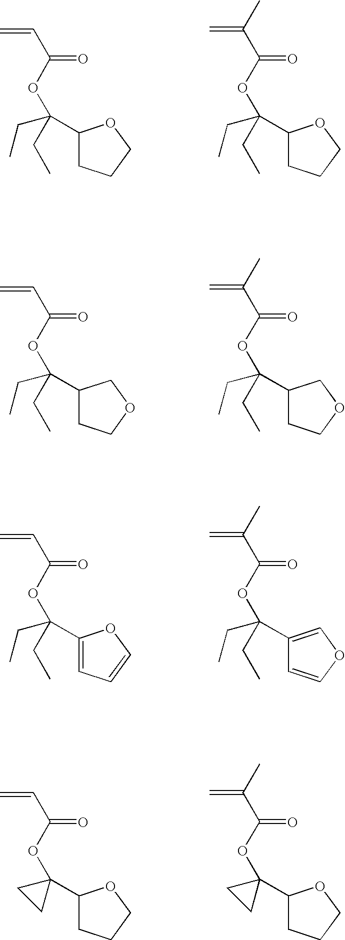

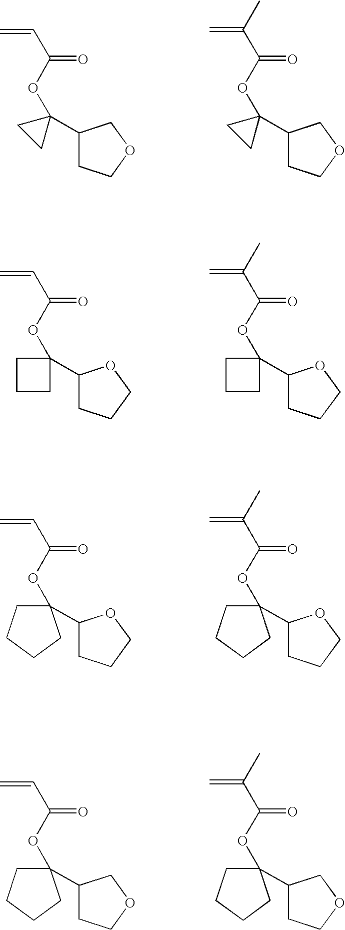

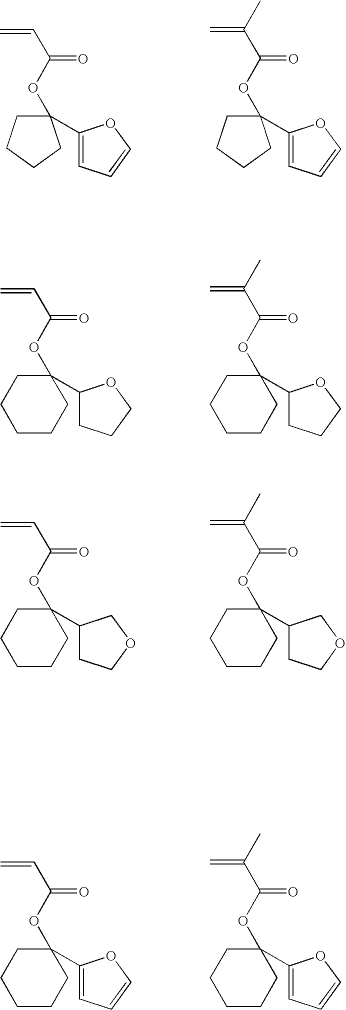

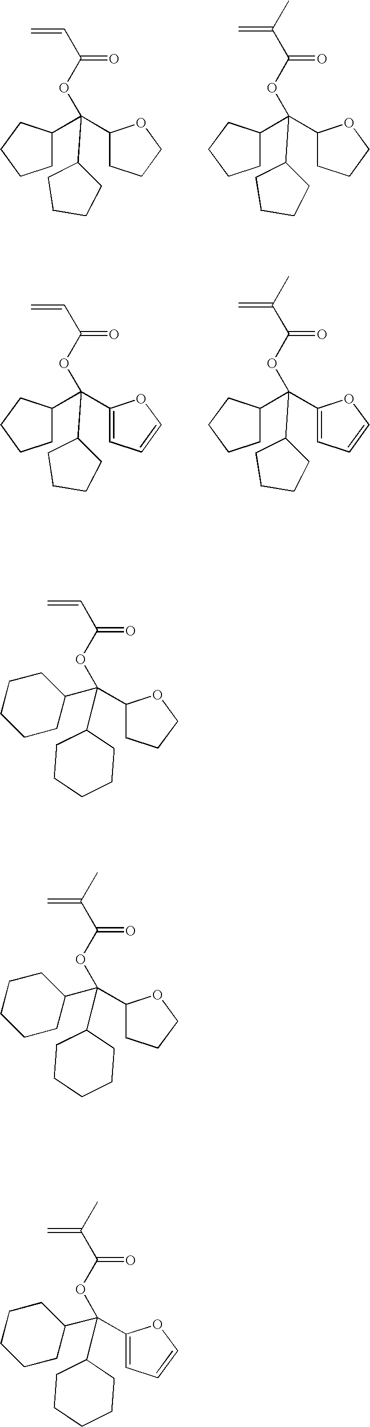

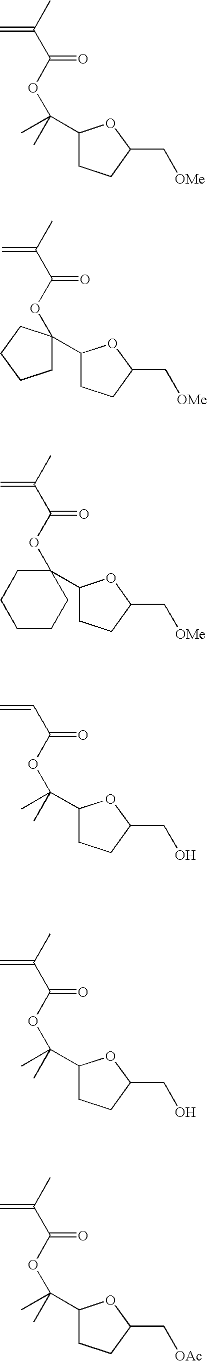

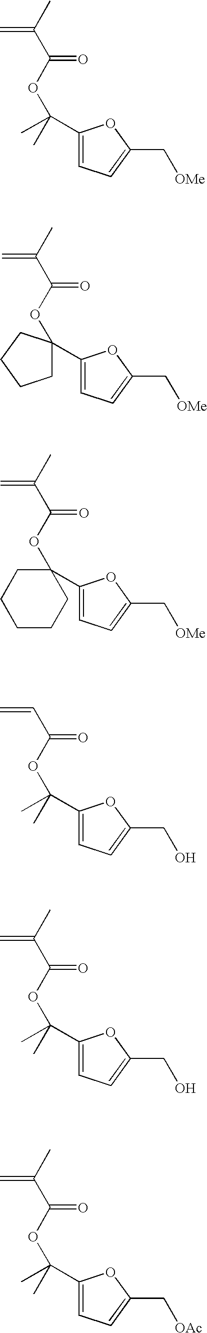

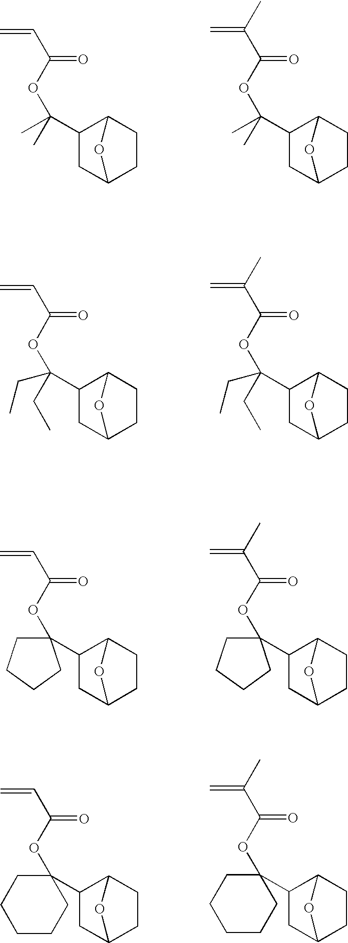

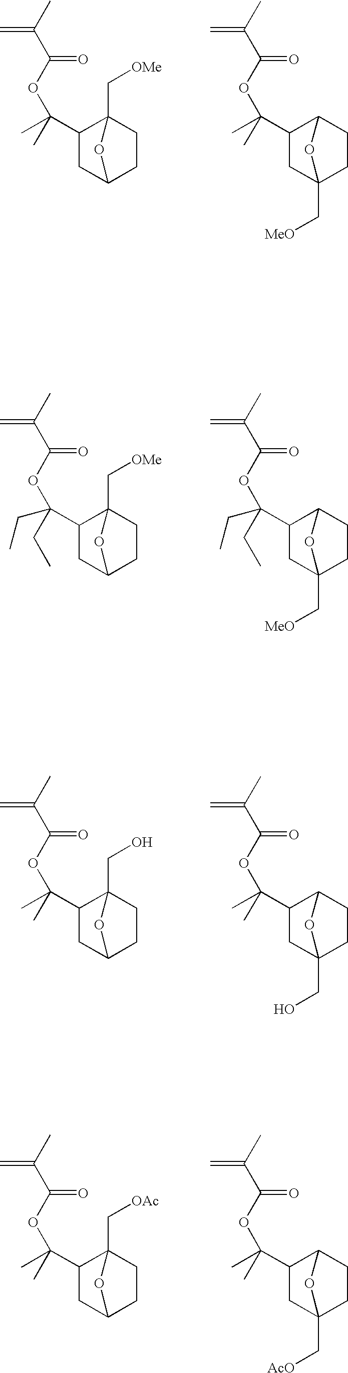

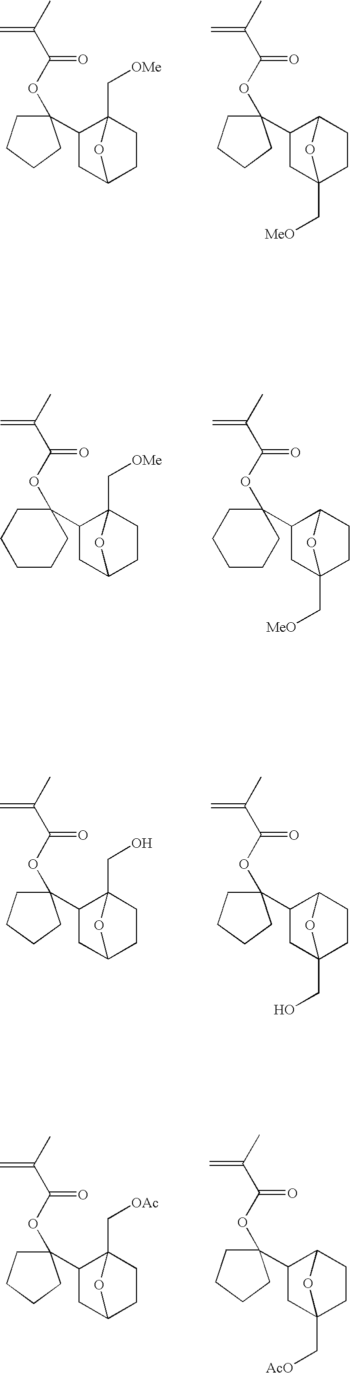

While the polymer used in the second resist composition preferably includes recurring units (a), (b), (c−1), and (c−2) as shown in formula (3), it may have copolymerized therein recurring units (d) derived from a monomer having a hydroxy, lactone ring, carbonate, cyano, ether or ester group. Examples of monomers from which recurring units (d) are derived are given below.

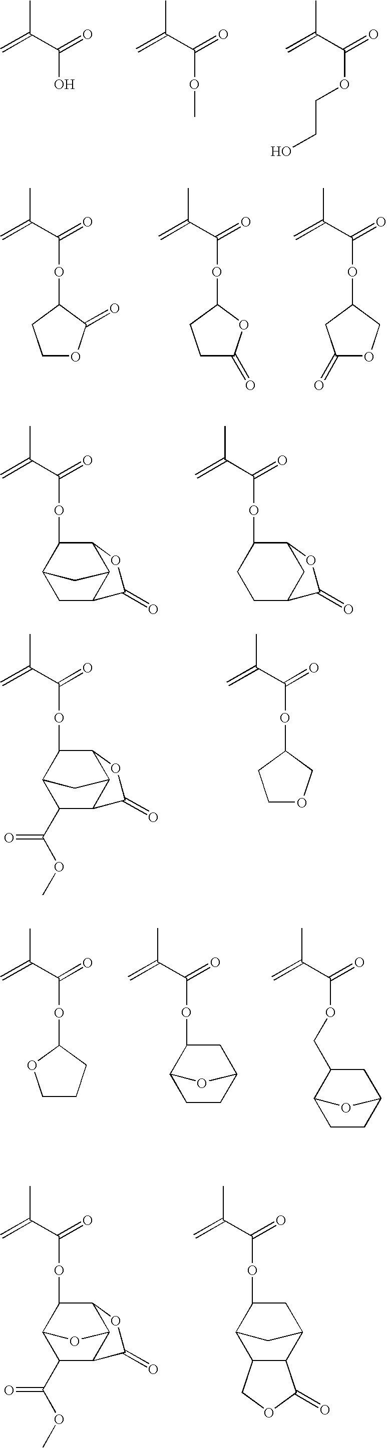

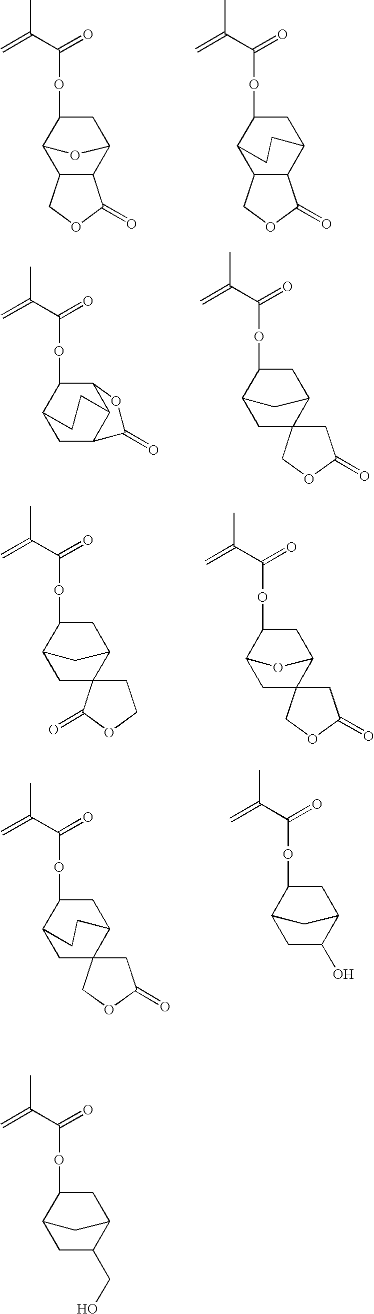

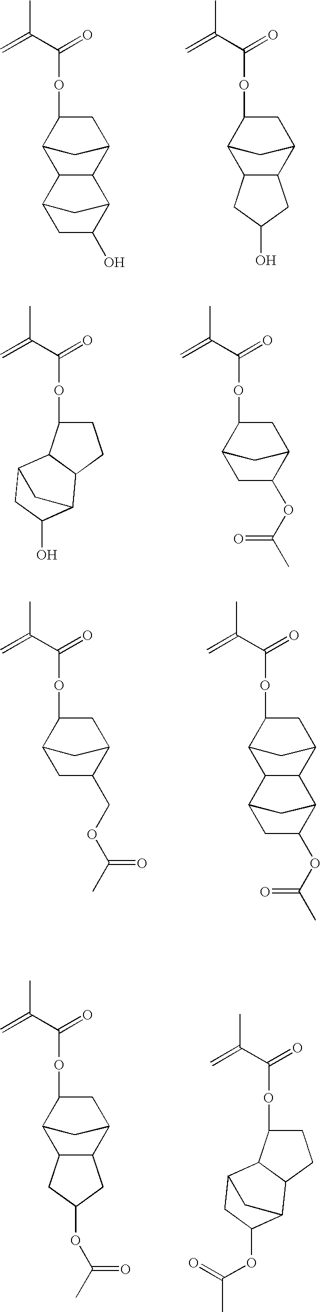

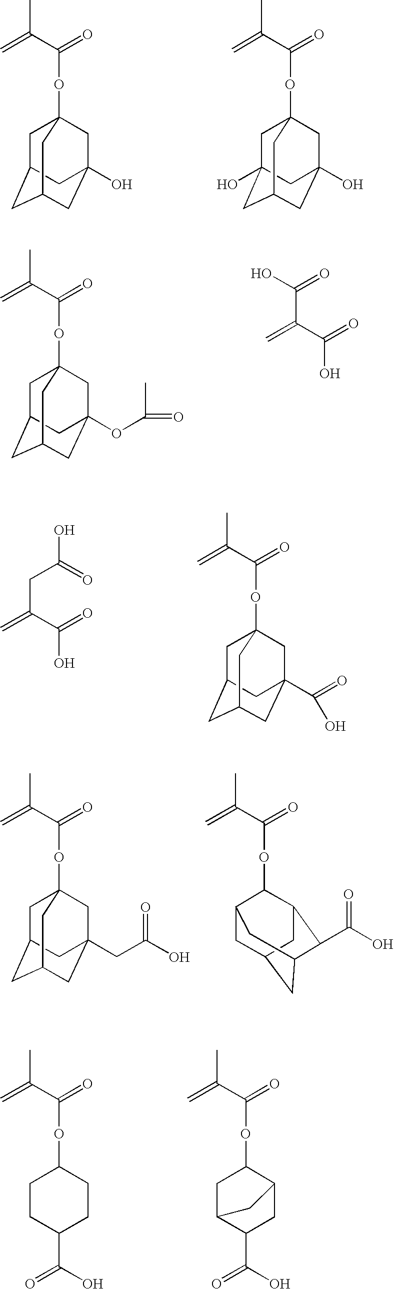

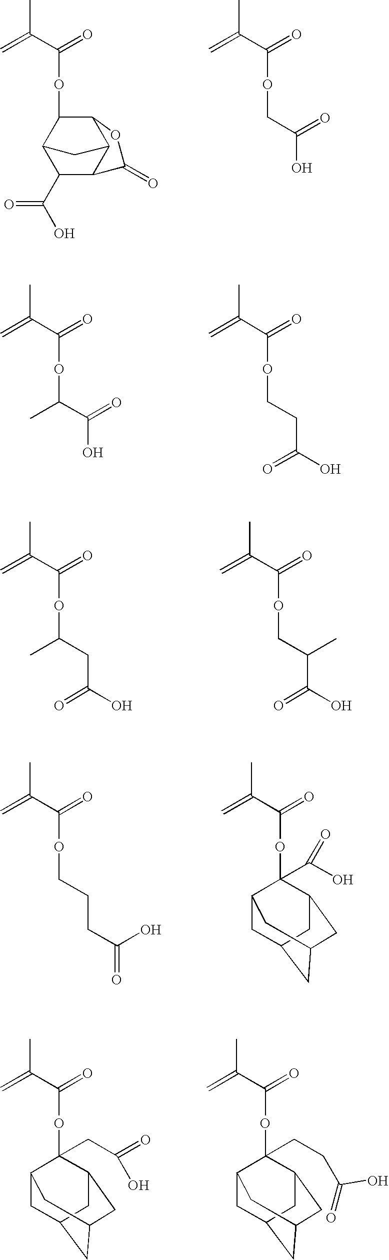

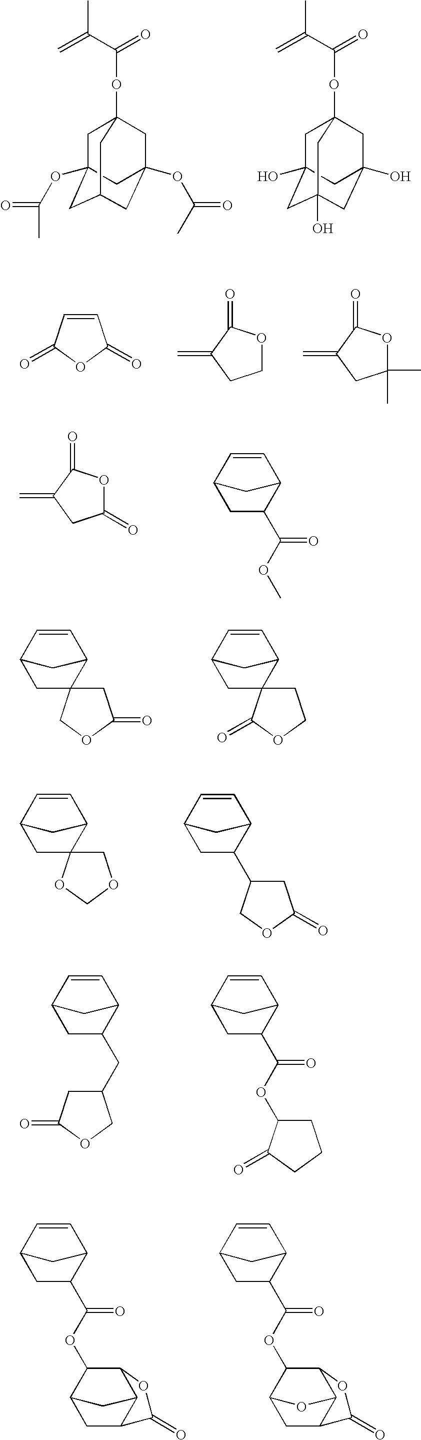

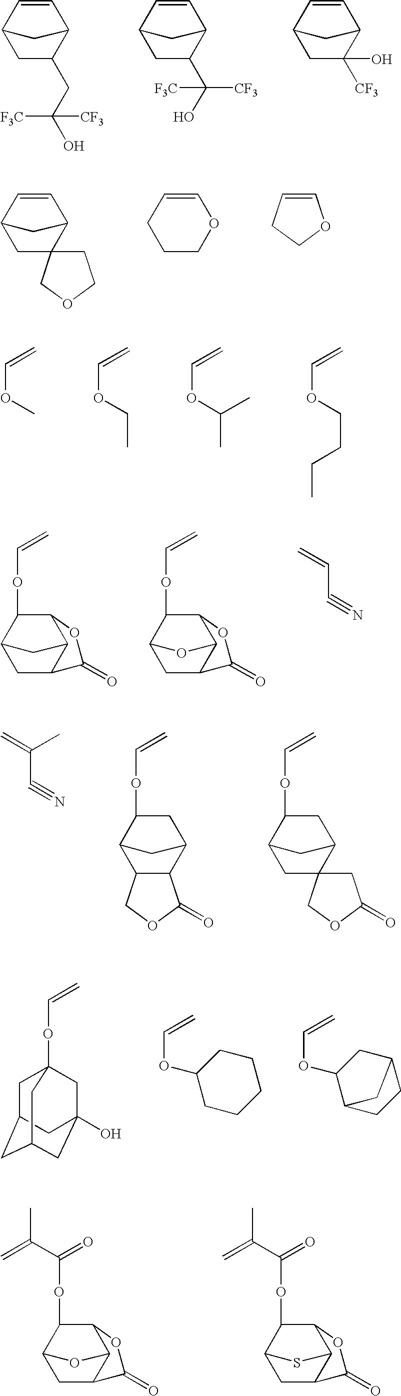

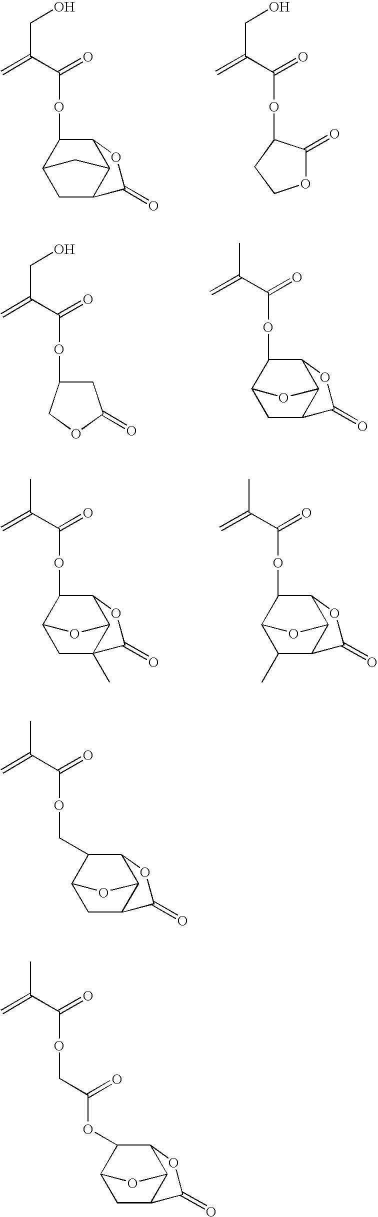

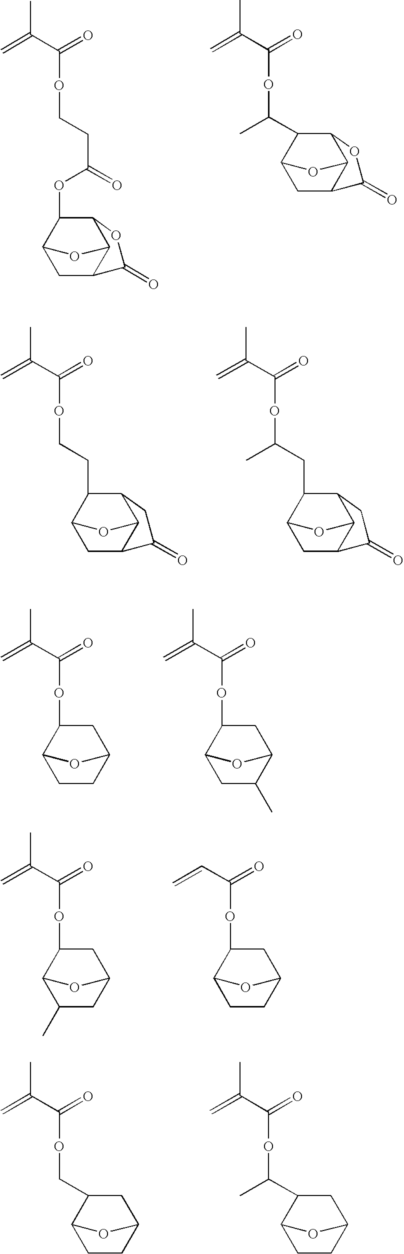

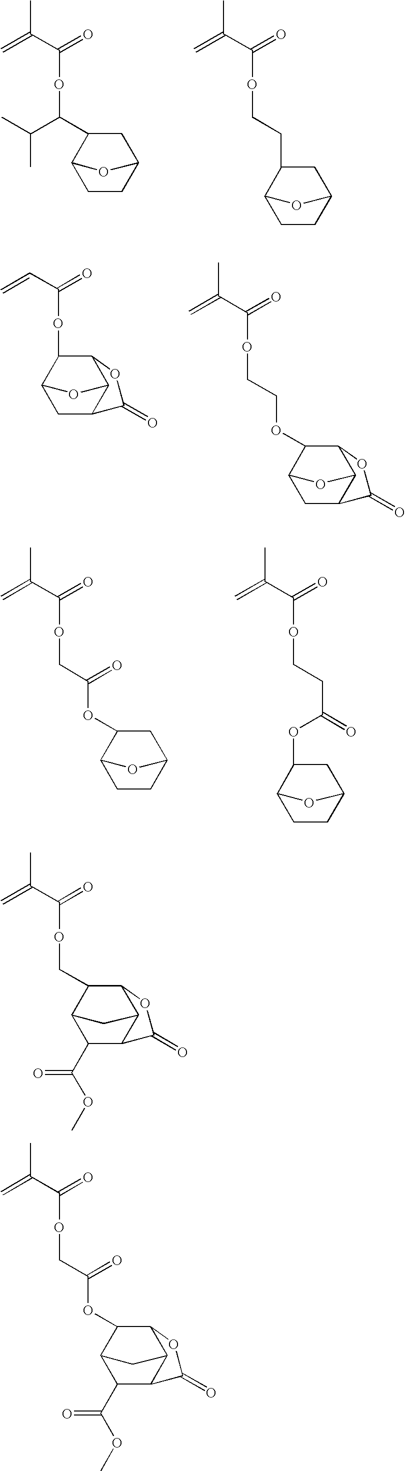

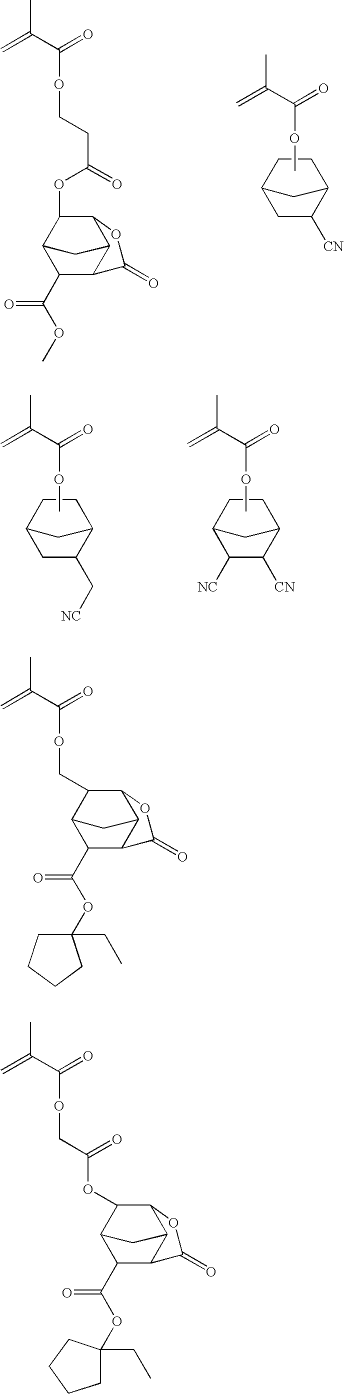

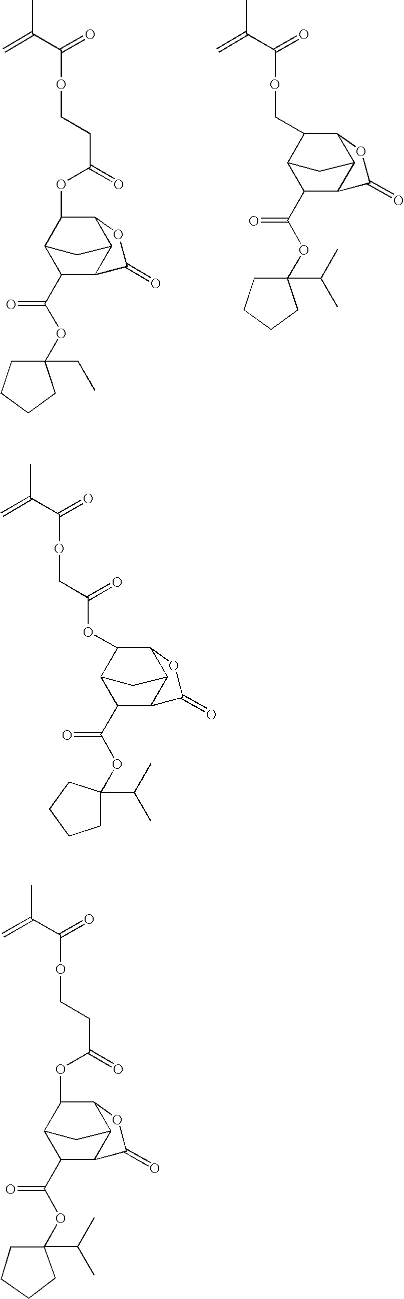

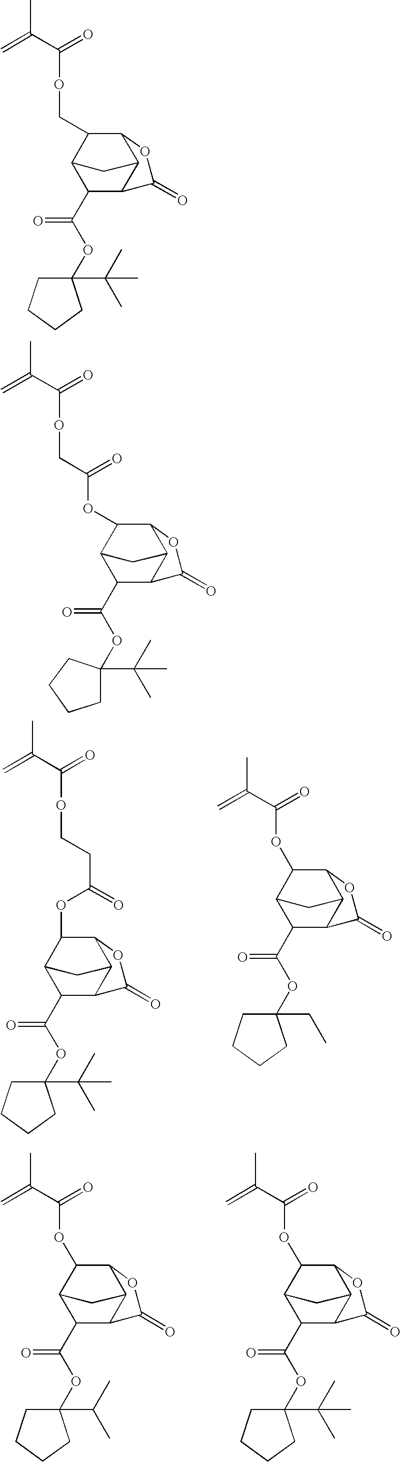

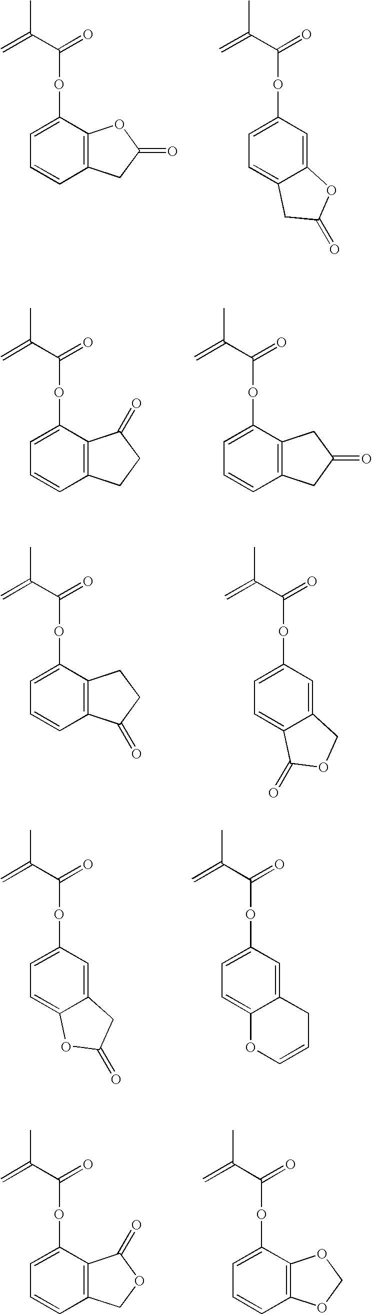

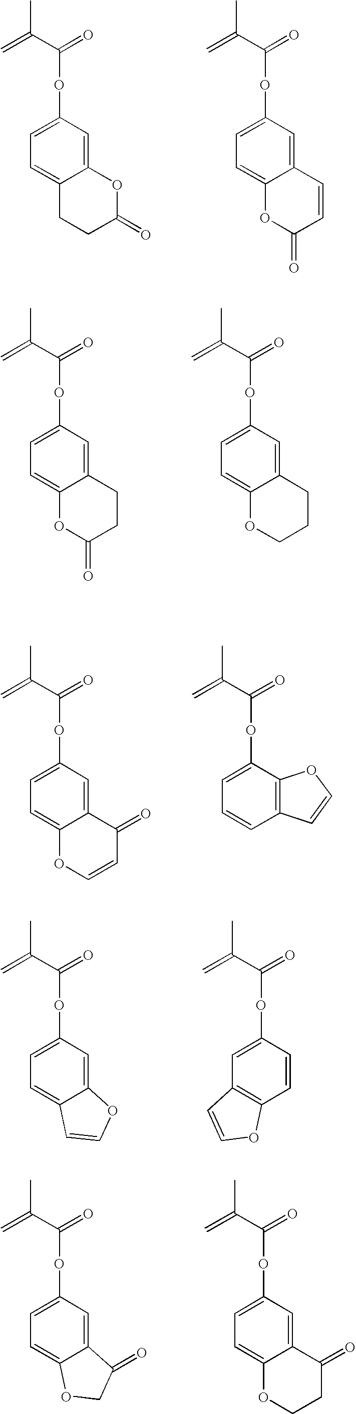

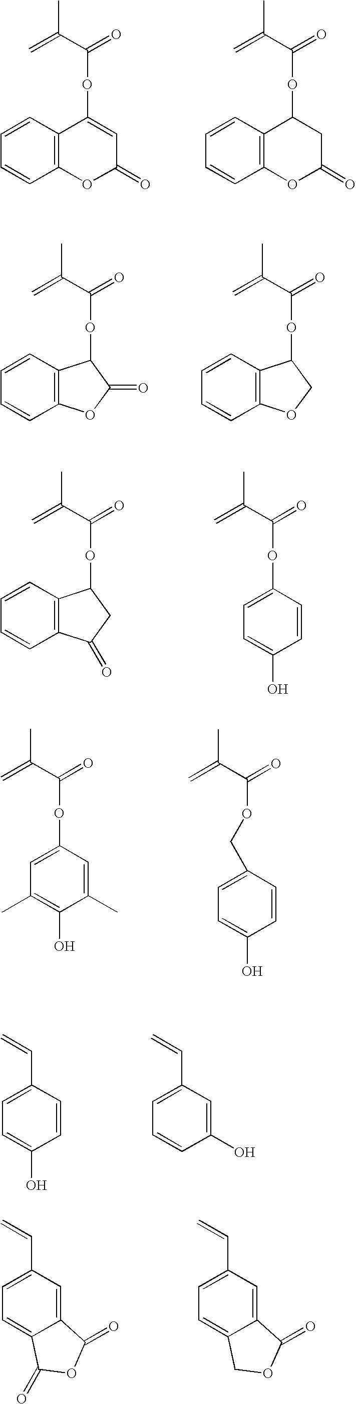

Further, any of recurring units (g1), (g2), and (g3) having a sulfonium salt as represented by the general formula (10) may be copolymerized.

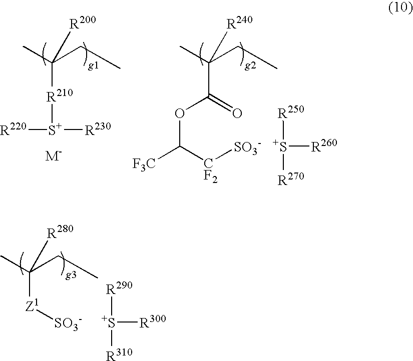

Herein R²⁰⁰, R²⁴⁰, and R²⁸⁰ each are hydrogen or methyl. R²¹⁰ is a single bond, phenylene, —O—R— or —C(═O)—Y¹—R— wherein Y¹ is an oxygen atom or NH, and R is a straight, branched or cyclic C₁-C₆ alkylene group, phenylene group or alkenylene group, which may contain a carbonyl (—CO—), ester (—COO—), ether (—O—) or hydroxy radical. R²²⁰, R²³⁰, R²⁵⁰, R²⁶⁰, R²⁷⁰, R²⁹⁰, R³⁰⁰, and R³¹⁰ are each independently a straight, branched or cyclic C₁-C₁₂ alkyl group which may contain a carbonyl, ester or ether radical, or a C₆-C₁₂ aryl group, C₇-C₂₀ aralkyl group or thiophenyl group. Z¹ is a single bond, methylene, ethylene, phenylene, fluorinated phenylene, —O—R³²⁰—, or —C(═O)-Z²-R³²⁰— wherein Z² is an oxygen atom or NH, and R³²⁰ is a straight, branched or cyclic C₁-C₆ alkylene group, phenylene group or alkenylene group, which may contain a carbonyl, ester, ether or hydroxy radical. M⁻ is a non-nucleophilic counter ion. The subscripts g1, g2 and g3 are numbers in the range: 0≦g1 ≦0.3, 0≦g2≦0.3, 0g3 0.3, and 0≦g1+g2+g≦0.3.

Examples of the non-nucleophilic counter ion represented by M⁻ include halide ions such as chloride and bromide ions; fluoroalkylsulfonate ions such as triflate, 1,1,1-trifluoroethanesulfonate, and nonafluorobutanesulfonate; arylsulfonate ions such as tosylate, benzenesulfonate, 4-fluorobenzenesulfonate, 1,2,3,4,5-pentafluorobenzenesulfonate; alkylsulfonate ions such as mesylate and butanesulfonate; imidates such as bis(trifluoromethylsulfonyl)imide, bis(perfluoroethylsulfonyl)imide, and bis(perfluorobutylsulfonyl)imide; and methidates such as tris(trifluoromethylsulfonyl)methide and tris(perfluoroethylsulfonyl)methide.

Other non-nucleophilic counter ions include sulfonates having fluorine substituted at α-position as represented by the general formula (K-1) and sulfonates having fluorine substituted at α- and β-positions as represented by the general formula (K-2).

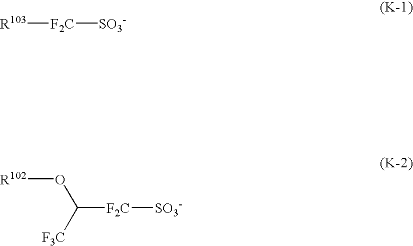

In formula (K-1), R¹⁰² is hydrogen, or a straight, branched or cyclic C₁-C₃₀ alkyl or acyl group, C₂-C₂₀ alkenyl group, or C₆-C₂₀ aryl or aryloxy group, which may have an ether, ester, carbonyl radical or lactone ring. In formula (K-2), R¹⁰² is hydrogen, or a straight, branched or cyclic C₁-C₂₀ alkyl group, C₂-C₂₀ alkenyl group, or C₆-C₂₀ aryl group, which may have an ether, ester, carbonyl radical or lactone ring.

As described above, the base polymer in the first resist composition used in the first patterning stage should be insoluble in the solvent consisting of a C₃-C₈ alcohol and an optional C₆-C₁₂ ether. The polymer should contain lactone-containing adhesive groups in order that the polymer be insoluble in the solvent. On the other hand, since recurring units (a), (c−1), and (c−2) facilitate dissolution in the C₃-C₈ alcohol and C₆-C₁₂ ether, these units should not be incorporated into the base polymer of the first resist composition, or if incorporated, should desirably be limited to a copolymerization proportion of up to 20 mol %.

Specifically, the base polymer in the first resist composition used in the first patterning stage should comprise recurring units (b) having an acid labile group and recurring units (a⁰) having lactone, and may have further copolymerized therein recurring units (d) having a hydroxy, carbonate, cyano, ether or ester group.

Preferably the base polymer in the first resist composition used in the first patterning stage may have incorporated therein acidic recurring units (j) capable of promoting adsorption of amine or oxazoline for achieving more effective inactivation. Examples of the acidic recurring units include the aforementioned units containing fluoroalcohol, sulfonamide, carboxyl group, sulfo group, phenol group, and naphthol group.

The base polymer in the first resist composition used in the first patterning stage comprises recurring units (a⁰), (b), and (d) in a copolymerization proportion: 0<a⁰<1.0, 0<b<1.0, 0≦d<1.0, and 0<b+d≦1.0; preferably 0.1≦a⁰≦0.9, 0.1≦b≦0.8, 0.05≦d≦0.9, and 0.15≦b+d≦1.0; more preferably 0.2≦a⁰≦0.8, 0.15≦b≦0.7, 0.1≦d≦0.85, and 0.2≦b+d≦1.0. Acidic recurring units (j) are incorporated in a proportion: 0≦j≦0.5, based on the entire recurring units.

The base polymer in the second resist composition used in the second patterning stage comprises recurring units (a), (b), (c−1), and (c−2) in a copolymerization proportion: 0<a<1.0, 0<b<1.0, 0≦(c−1)<1.0, 0≦(c−2)<1.0, 0<a+b+(c−1)+(c−2)≦1.0, and 0.1≦a+(c−1)+(c−2) 0.9; preferably 0.1≦a≦0.9, 0.1≦b≦0.8, 0≦(c−1)+(c−2)≦0.5, 0.3≦a+b+(c−1)+(c−2)≦1.0, and 0.15≦a+(c−1)+(c−2)≦0.85; more preferably 0.2≦a≦0.8, 0.15≦b≦0.7, 0≦(c−1)≦0.4, 0≦(c−2)≦0.4, 0.4a+b+(c−1)+(c−2)≦1.0, and 0.2≦a+(c−1)+(c−2)≦0.8. Also preferably (c−1) and (c−2) are not equal to 0 at the same time.

It is noted that a+b+(c−1)+(c−2)+d≦1.0. The meaning of a+b+(c−1)+(c−2)+d=1 is that in a polymer comprising recurring units (a), (b), (c−1), (c−2), and (d), the sum of recurring units (a), (b), (c−1), (c−2), and (d) is 100 mol % based on the total amount of entire recurring units. The meaning of a+b+(c−1)+(c−2)+d<1 is that the sum of recurring units (a), (b), (c−1), (c−2), and (d) is less than 100 mol % based on the total amount of entire recurring units, indicating the inclusion of other recurring units, for example, units (g1), (g2) or (g3). Where recurring units (g1), (g2) or (g3) are incorporated, their proportion is preferably 0≦g1+g2+g3≦0.2.

The following description applies to both the first and second resist compositions.

The polymer serving as the base resin in the resist material used in the pattern forming process of the invention should preferably have a weight average molecular weight (Mw) in the range of 1,000 to 500,000, and more preferably 2,000 to 30,000, as measured by gel permeation chromatography (GPC) using polystyrene standards. With too low a Mw, the efficiency of thermal crosslinking in the resist material after development may become low. A polymer with too high a Mw may lose alkali solubility and give rise to a footing phenomenon after pattern formation.

If a polymer has a wide molecular weight distribution or dispersity (Mw/Mn), which indicates the presence of lower and higher molecular weight polymer fractions, there is a possibility that foreign matter is left on the pattern or the pattern profile is degraded. The influences of molecular weight and dispersity become stronger as the pattern rule becomes finer. Therefore, the multi-component copolymer should preferably have a narrow dispersity (Mw/Mn) of 1.0 to 2.0, especially 1.0 to 1.5, in order to provide a resist composition suitable for micropatterning to a small feature size.

It is understood that a blend of two or more polymers which differ in compositional ratio, molecular weight or dispersity is acceptable.

The polymer used herein may be synthesized by any desired method, for example, by dissolving unsaturated bond-containing monomers corresponding to the respective units in an organic solvent, adding a radical initiator thereto, and effecting heat polymerization. Examples of the organic solvent which can be used for polymerization include toluene, benzene, tetrahydrofuran, diethyl ether and dioxane. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. Preferably the system is heated at 50 to 80° C. for polymerization to take place. The reaction time is 2 to 100 hours, preferably 5 to 20 hours. The acid labile group that has been incorporated in the monomer may be kept as such, or the acid labile group may be once removed with an acid catalyst and thereafter protected or partially protected.

The polymer is not limited to one type and a mixture of two or more polymers may be added. The use of plural polymers allows for adjustment of resist properties.

The first or second positive resist composition used herein may include an acid generator in order for the composition to function as a chemically amplified positive resist composition. Typical of the acid generator used herein is a photoacid generator (PAG) capable of generating an acid in response to actinic light or radiation. It is any compound capable of generating an acid upon exposure to high-energy radiation. Suitable photoacid generators include sulfonium salts, iodonium salts, sulfonyldiazomethane, N-sulfonyloxyimide, and oxime-O-sulfonate acid generators. The acid generators may be used alone or in admixture of two or more. Exemplary acid generators are described in U.S. Pat. No. 7,537,880 (JP-A 2008-111103, paragraphs [0122] to [0142]). The acid generator is typically used in an amount of 0.1 to 30 parts, and preferably 1 to 20 parts by weight per 100 parts by weight of the base polymer.

The resist composition may further comprise an organic solvent, basic compound, dissolution regulator, surfactant, and acetylene alcohol, alone or in combination.

Examples of the organic solvent added to the first resist composition are described in U.S. Pat. No. 7,537,880 (JP-A 2008-111103, paragraphs [0144] to [0145]. The organic solvent used in the first resist composition may be any organic solvent in which the base resin, acid generator, and other components are soluble. Illustrative, non-limiting, examples of the organic solvent include ketones such as cyclohexanone and methyl n-amyl ketone; alcohols such as 3-methoxybutanol, 3-methyl-3-methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone. These solvents may be used alone or in combinations of two or more thereof. Of the above organic solvents, it is recommended to use diethylene glycol dimethyl ether, 1-ethoxy-2-propanol, PGMEA, and mixtures thereof because the acid generator is most soluble therein. An appropriate amount of the organic solvent used is 200 to 3,000 parts, especially 400 to 2,500 parts by weight per 100 parts by weight of the base polymer.

In the second resist composition, the organic solvent comprises a C₃-C₈ alcohol and optionally a C₆-C₁₂ ether. Examples of C₃-C₈ alcohol include n-propanol, isopropyl alcohol, 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2,2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, 1-heptanol, cyclohexanol, and octanol.

Examples of C₆-C₁₂ ether include methyl cyclopentyl ether, methyl cyclohexyl ether, diisopropyl ether, diisobutyl ether, diisopentyl ether, di-n-pentyl ether, methyl cyclopentyl ether, methyl cyclohexyl ether, di-n-butyl ether, di-sec-butyl ether, di-sec-pentyl ether, di-tert-amyl ether, di-n-hexyl ether, anisole, 2-methylanisole, 3-methylanisole, 4-methylanisole, 2,3-dimethylanisole, 2,4-dimethylanisole, 3,4-dimethylanisole, 2,5-dimethylanisole, 2,6-dimethylanisole, 3,5-dimethylanisole, 3,6-dimethylanisole, 2,3,4-trimethylanisole, 2,3,6-trimethylanisole, 2,4,6-trimethylanisole, 2,4,5,6-tetramethylanisole, 2-ethylanisole, 3-ethylanisole, 4-ethylanisole, 2-isopropylanisole, 3-isopropylanisole, 4-isopropylanisole, 4-propylanisole, 2-butylanisole, 3-butylanisole, 4-butylanisole, 2-tert-butylanisole, 3-tert-butylanisole, 4-tert-butylanisole, pentamethylanisole, 2-vinylanisole, 3-vinylanisole, 4-methoxystyrene, ethyl phenyl ether, propyl phenyl ether, butyl phenyl ether, ethyl 3,5-xylyl ether, ethyl 2,6-xylyl ether, ethyl 2,4-xylyl ether, ethyl 3,4-xylyl ether, ethyl 2,5-xylyl ether, methyl benzyl ether, ethyl benzyl ether, isopropyl benzyl ether, propyl benzyl ether, methyl phenethyl ether, ethyl phenethyl ether, isopropyl phenethyl ether, propyl phenethyl ether, butyl phenethyl ether, vinyl phenyl ether, allyl phenyl ether, vinyl benzyl ether, allyl benzyl ether, vinyl phenethyl ether, allyl phenethyl ether, 4-ethylphenetole, and tert-butyl phenyl ether.

Of the alcohol solvents, primary alcohols are preferred because of a high solubility of the polymer therein, and 2-methyl-1-butanol and 3-methyl-1-butanol are most preferred. However, if 2-methyl-1-butanol or 3-methyl-1-butanol is used alone as the solvent, there arises a problem that a resist film resulting from spin coating and baking has poor water slip on its surface. Water slip on a resist film is facilitated as the receding contact angle of the film (i.e., the angle at which a water droplet on a resist film rolls down when the wafer is increasingly inclined) becomes greater. A resist film having a smaller receding contact angle is detrimental in the immersion lithography in that upon high-speed scanning, water spills out of the wafer stage or water droplets are left backward of scanning, causing defects. The boiling point of 2-methyl-1-butanol and 3-methyl-1-butanol is around 130° C. and lower than the boiling point (145° C.) of PGMEA commonly used in the art. A solvent having a lower boiling point tends to evaporate rapidly. With respect to the immersion lithography, it is known that a water slip improver to be described later is blended in a resist material and the water slip improver segregates toward the resist film surface during spin coating. If a low-boiling solvent is used in this resist material, the resist film begins solidifying before the segregation of the water slip improver toward the surface takes place, failing to provide satisfactory water slip. For retarding evaporation of the solvent, a blend of 2-methyl-1-butanol or 3-methyl-1-butanol with a high-boiling solvent is effective. The high-boiling solvent is preferably selected from 1-hexanol, 1-heptanol and 1-octanol.

While the second resist composition is desired to cause minimal damage to the first resist pattern during coating, a blend of the C₃-C₈ alcohol with the C₆-C₁₂ ether is advantageous as the solvent in the second resist composition. Although the polymer for the second resist composition cannot be dissolved in the C₆-C₁₂ ether used alone, a blend of the C₃-C₈ alcohol with the C₆-C₁₂ ether allows the polymer to be dissolved and is effective for minimizing any damage to the first resist pattern.

For use in the first and second resist compositions, exemplary basic compounds are described in JP-A 2008-111103 (U.S. Pat. No. 7,537,880), paragraphs [0146] to [0164], and exemplary surfactants in paragraphs [0165] to [0166]. Exemplary dissolution regulators are described in JP-A 2008-122932 (US 2008090172), paragraphs [0155] to [0178], and exemplary acetylene alcohols in paragraphs [0179] to [0182]. These components may be blended in standard amounts. For example, the basic compound may be preferably blended in an amount of 0.001 to 10 parts, the dissolution regulator in an amount of 0.1 to 50 parts, and the surfactant in an amount of 0.00001 to 5 parts by weight per 100 parts by weight of the base polymer.

### Process

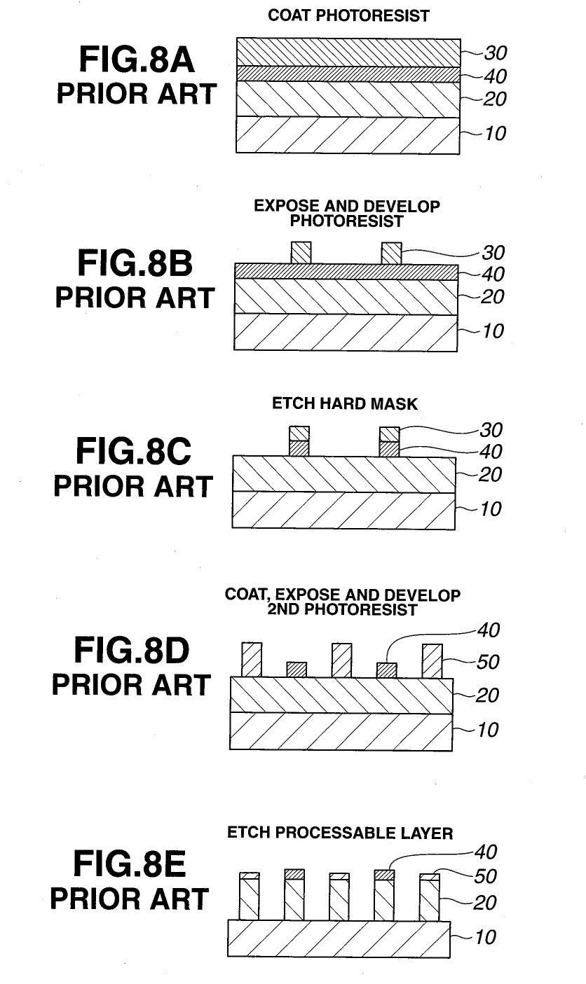

Now, the double patterning process is described. FIGS. 8 to 10 illustrate prior art double patterning processes.

Referring to FIG. 8, one exemplary double patterning process I is illustrated. A photoresist film 30 is coated and formed on a processable layer 20 on a substrate 10. To prevent the photoresist pattern from collapsing, the technology intends to reduce the thickness of photoresist film. One approach taken to compensate for a lowering of etch resistance of thinner film is to process the processable layer using a hard mask. The double patterning process illustrated in FIG. 8 uses a multilayer coating in which a hard mask 40 is laid between the photoresist film 30 and the processable layer 20 as shown in FIG. 8A. In the double patterning process, the hard mask is not always necessary, and an underlayer film in the form of a carbon film and a silicon-containing intermediate film may be laid instead of the hard mask, or an organic antireflective coating may be laid between the hard mask and the photoresist film. The hard mask used herein may be of SiO₂, SiN, SiON, p-Si or TiN, for example. The resist material used in double patterning process I is a positive resist composition. In the process, the resist film 30 is exposed and developed (FIG. 8B), the hard mask 40 is then dry etched (FIG. 8C), the photoresist film is stripped, and a second photoresist film 50 is coated, formed, exposed, and developed (FIG. 8D). Then the processable layer 20 is dry etched (FIG. 8E). Since this etching is performed using the hard mask pattern and the second photoresist pattern as a mask, variations occur in the pattern size after etching of the processable layer due to a difference in etch resistance between hard mask 40 and photoresist film 50.

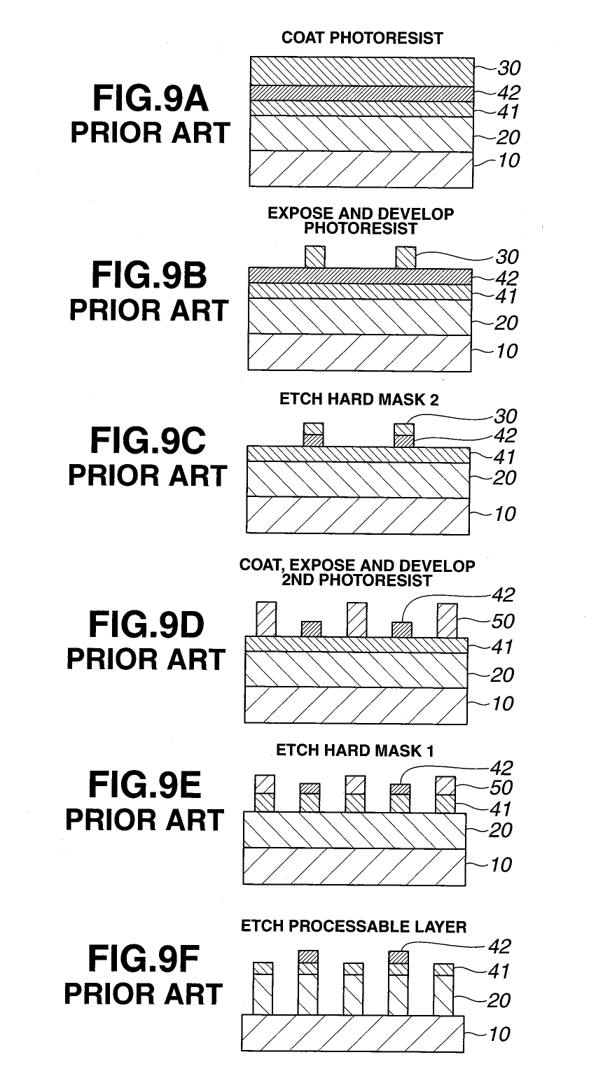

To solve the above problem, a double patterning process II illustrated in FIG. 9 involves laying two layers of hard mask 41 and 42. The upper layer of hard mask 42 is processed using a first resist pattern, the lower layer of hard mask 41 is processed using a second resist pattern, and the processable layer is dry etched using the two hard mask patterns. It is essential to establish a high etching selectivity between first hard mask 41 and second hard mask 42. Thus the process is rather complex.

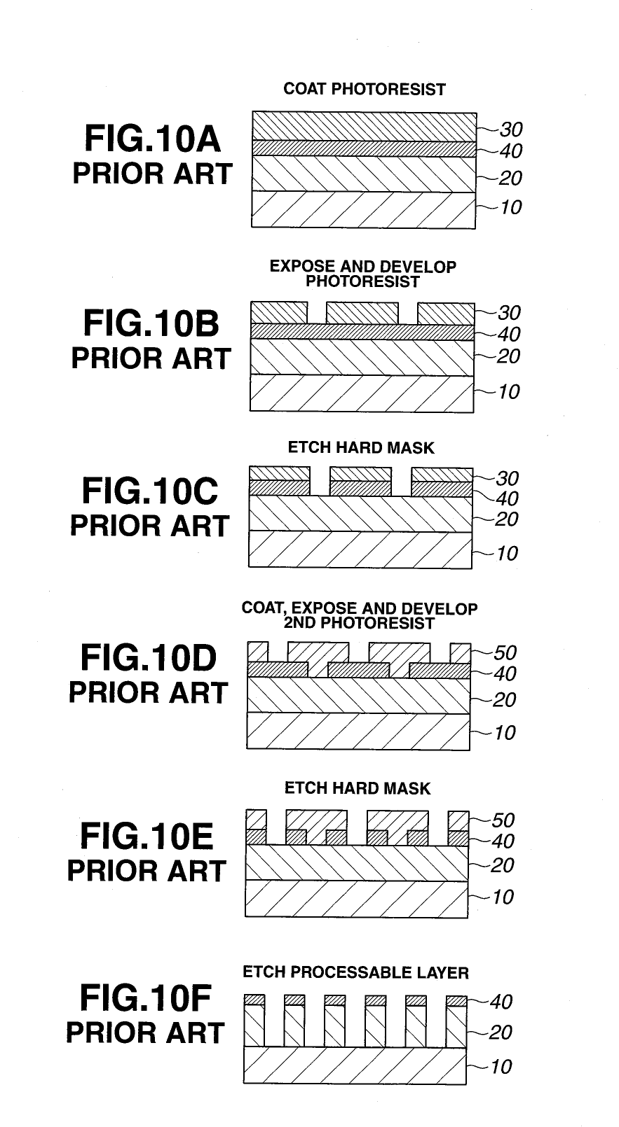

FIG. 10 illustrates a double patterning process III using a trench pattern. This process requires only one layer of hard mask. However, since the trench pattern is lower in optical contrast than the line pattern, the process has the drawbacks of difficult resolution of the pattern after development and a narrow margin. It is possible to form a wide trench pattern and induce shrinkage by the thermal flow or RELACS method, but this process is more intricate. Using negative resist materials enables exposure at a high optical contrast, but the negative resist materials generally have the drawbacks of low contrast and low resolution capability as compared with positive resist materials. The trench process requires a very high accuracy of alignment because any misalignment between the first and second trenches leads to a variation in the width of the finally remaining lines.

The double patterning processes I to III described above have the drawback that two hard mask etchings are involved.

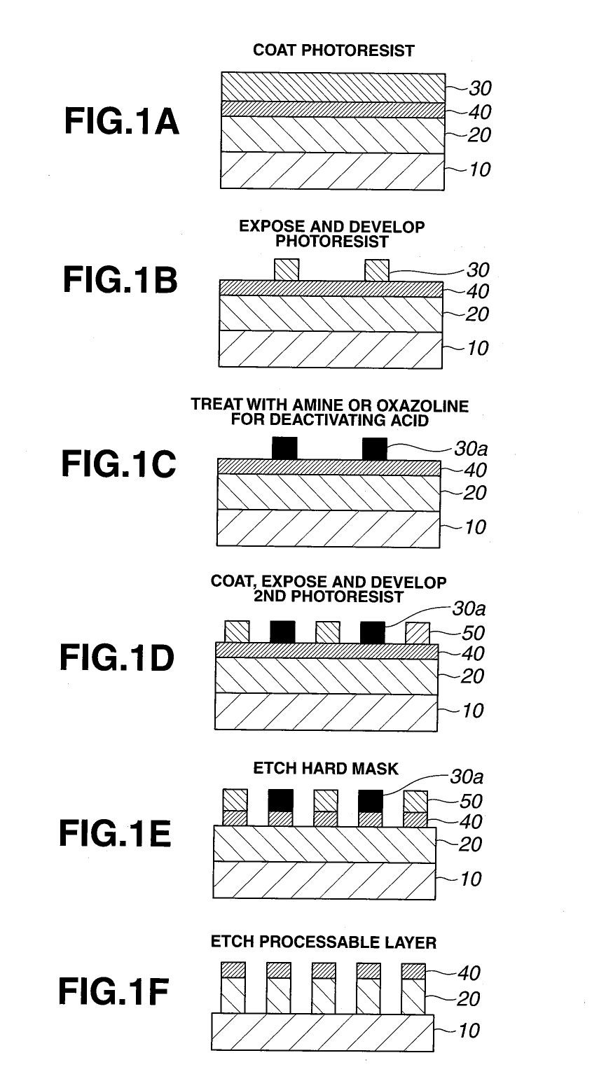

FIG. 1 illustrates the double patterning process of the invention. FIG. 1A shows a structure wherein a first resist film 30 of the first resist composition is formed on a processable layer 20 on a substrate 10 via a hard mask 40 as in FIG. 8A. The first resist film 30 is exposed patternwise and developed to form a first resist pattern (FIG. 1B). Then an amine or oxazoline compound is applied to the first resist pattern-bearing substrate for deactivating the first resist film 30 to acid, yielding a deactivated resist pattern 30a (FIG. 10). The application of an amine or oxazoline compound may be implemented either by vapor priming or by spin coating. The unnecessary portion of amine or oxazoline compound may be evaporated off by baking or stripped off using a suitable solvent, water or alkaline developer. Application may be followed by baking in order to cause the amine or oxazoline compound to penetrate into the pattern. The preferred baking is at 50 to 170° C. for 5 to 600 seconds. A temperature higher than 170° C. is undesired because the resist pattern may be deformed due to thermal flow or shrunk as a result of deprotection of acid labile groups. The baking temperature is preferably up to 150° C., more preferably up to 140° C., and even more preferably up to 130° C. The pattern is little deformed if baking is at or below 130° C.

Next, the second resist composition is coated on the substrate to form a second resist film. Through patternwise exposure and development of the second resist film, a second resist pattern 50 is formed in an area where features of the inactivated first resist pattern 30a have not been formed (FIG. 1D). Thereafter, the hard mask 40 is etched (FIG. 1E). The processable layer 20 is dry etched, and finally, the inactivated first resist pattern 30a and second resist pattern 50 are removed (FIG. 1F).

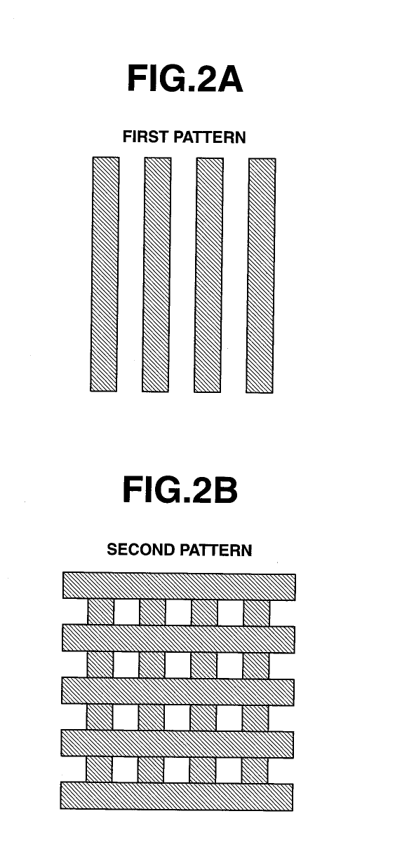

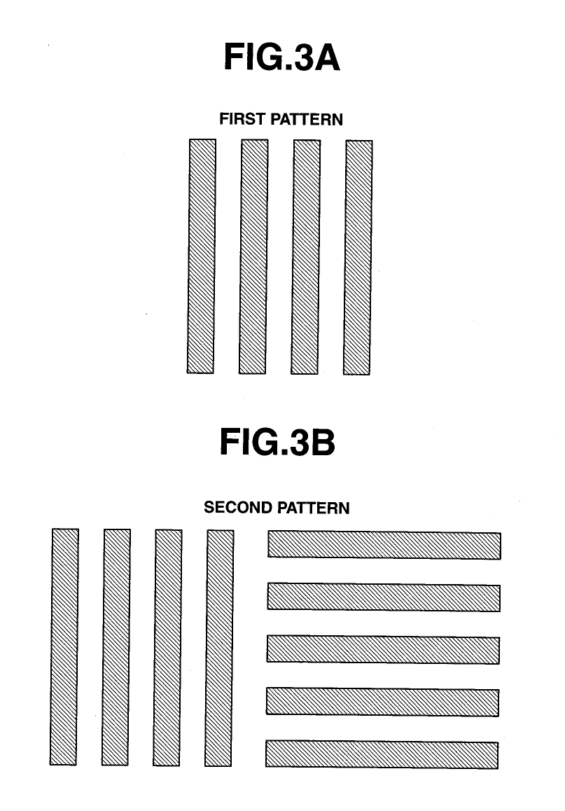

Although the process illustrated in FIG. 1 forms the second pattern between lines of the first pattern, it is also acceptable to form the second pattern so as to cross the first pattern orthogonally as shown in FIG. 2. Although such a pattern may be formed through a single exposure step, an orthogonal line pattern may be formed at a very high contrast by a combination of dipolar illumination with polarized illumination. Specifically, pattern lines in Y-direction are formed as shown in FIG. 2A and then insolubilized by the process of the invention. Thereafter, a second resist is coated and processed to form pattern lines in X-direction as shown in FIG. 2B. Combining X and Y lines defines a grid pattern while empty areas become holes. The pattern that can be formed by such a process is not limited to the orthogonal pattern, and may include a T-shaped pattern (not shown) or a separated pattern as shown in FIG. 3B.

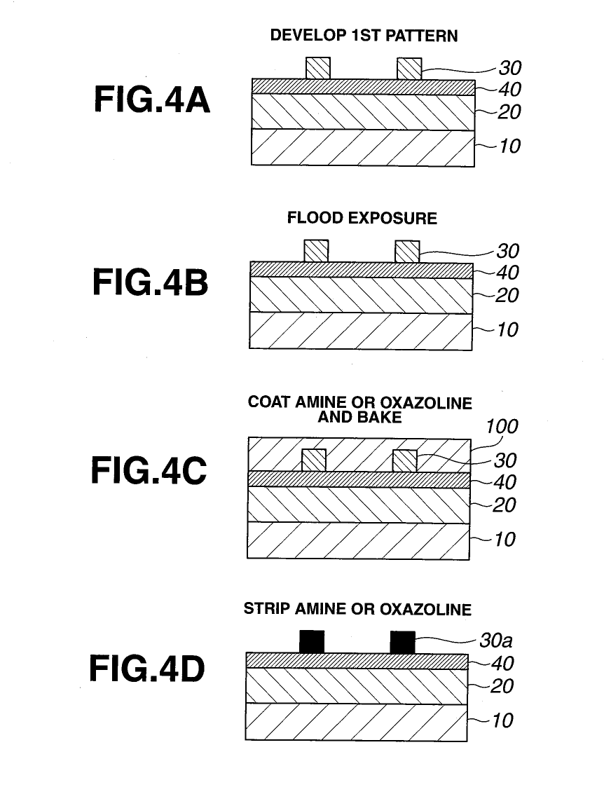

FIGS. 4 to 7 schematically illustrates the process of inactivating the first resist pattern. Illustrated in FIGS. 4 to 7 are the substrate 10, processable layer 20, first resist film or pattern 30, inactivated first resist pattern 30a, hard mask 40, and a deposit 100 resulting from application of the amine or oxazoline compound.

In FIG. 4, the first resist pattern as developed is irradiated with light before it is coated with the amine or oxazoline compound. The coating may be followed by baking for facilitating inactivation. Since the amine or oxazoline compound is supplied as a mixture with a base polymer and a solvent, the deposit 100 must be stripped later.

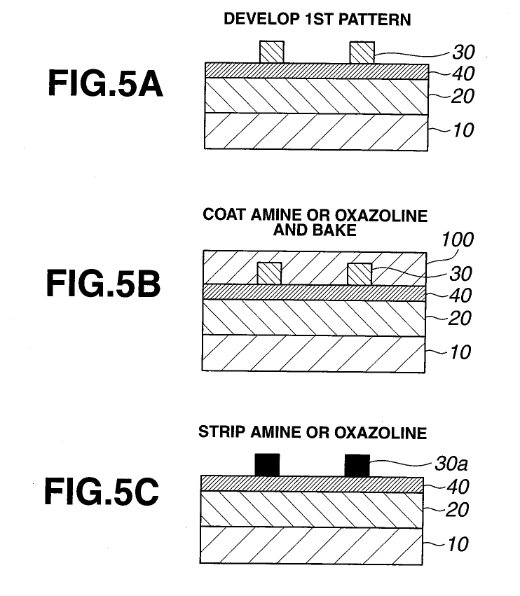

FIG. 5 illustrates an inactivating process similar to FIG. 4 while omitting light irradiation. Since the acid generator is left as such in the resist film, the efficiency of inactivation is lower than in FIG. 4. Advantageously the process is shorter.

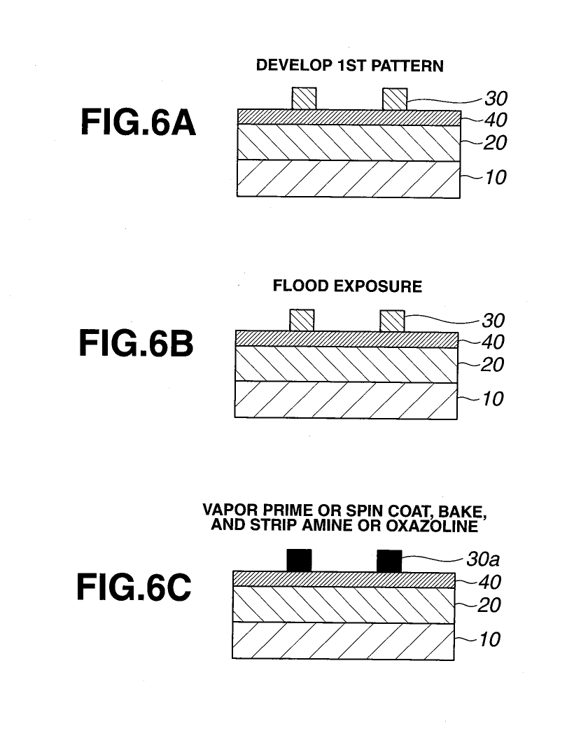

In the inactivating process of FIG. 6, the first resist pattern as developed is irradiated with light before the amine or oxazoline compound is vapor primed or spin coated. The inactivating agent used herein contains the amine or oxazoline compound, but not the base polymer. Since an excess of the amine or oxazoline compound may be evaporated off by baking, the process eliminates the stripping step.

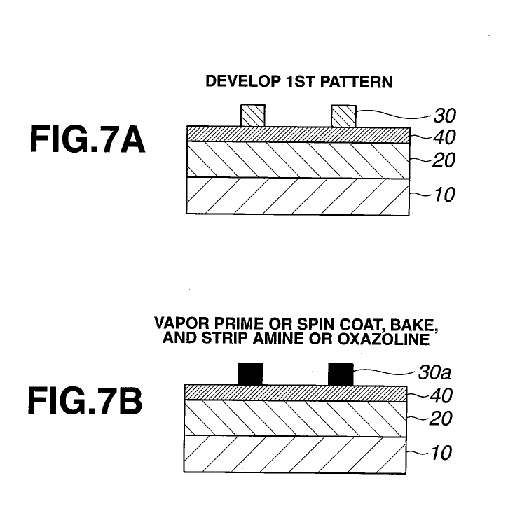

FIG. 7 illustrates an inactivating process similar to FIG. 6 while omitting light irradiation. This process is the shortest in that inactivation is achieved only by vapor priming or spin coating of the amine or oxazoline compound. Although the inactivating ability becomes lower due to such simplification, a satisfactory inactivating ability may be provided by taking a suitable measure, for example, using a polymer having copolymerized therein acidic units capable of facilitating adsorption of the amine or oxazoline compound to the first resist pattern.

The substrate 10 used herein is generally a silicon substrate. The processable layer 20 used herein includes SiO₂, SiN, SiON, SiOC, p-Si, α-Si, TiN, WSi, BPSG, SOG, Cr, CrO, CrON, MoSi, low dielectric film, and etch stopper film. The hard mask 40 is as described above. Understandably, an undercoat film in the form of a carbon film and an intermediate intervening layer in the form of a silicon-containing intermediate film or organic antireflective coating may be formed instead of the hard mask.

In the process of the invention, a first resist film of a first positive resist composition is formed on the processable layer directly or via an intermediate intervening layer such as the hard mask. The first resist film preferably has a thickness of 10 to 1,000 nm, and more preferably 20 to 500 nm. The first resist film is heated or pre-baked prior to exposure, with the preferred pre-baking conditions including a temperature of 60 to 180° C., especially 70 to 150° C. and a time of 10 to 300 seconds, especially 15 to 200 seconds.

This is followed by patternwise exposure. For the exposure, preference is given to high-energy radiation having a wavelength of 140 to 250 nm, and especially ArF excimer laser radiation of 193 nm. The exposure may be done either in air or in a dry atmosphere with a nitrogen stream, or by immersion lithography in water. The ArF immersion lithography uses deionized water or liquids having a refractive index of at least 1 and highly transparent to the exposure wavelength such as alkanes as the immersion solvent. The immersion lithography involves prebaking a resist film and exposing the resist film to light through a projection lens, with water introduced between the resist film and the projection lens. Since this allows lenses to be designed to a NA of 1.0 or higher, formation of finer feature size patterns is possible. The immersion lithography is important for the ArF lithography to survive to the 45-nm node. In the case of immersion lithography, deionized water rinsing (or post-soaking) may be carried out after exposure for removing water droplets left on the resist film, or a protective coating may be applied onto the resist film after pre-baking for preventing any leach-outs from the resist film and improving water slip on the film surface. The resist protective coating used in the immersion lithography is preferably formed from a solution of a polymer having 1,1,1,3,3,3-hexafluoro-2-propanol residues which is insoluble in water, but soluble in an alkaline developer liquid, in a solvent selected from alcohols of at least 4 carbon atoms, ethers of 8 to 12 carbon atoms, and mixtures thereof. After formation of the photoresist film, deionized water rinsing (or post-soaking) may be carried out for extracting the acid generator and the like from the film surface or washing away particles, or after exposure, rinsing (or post-soaking) may be carried out for removing water droplets left on the resist film.

To the first resist composition, an additive for rendering the resist surface water repellent may be added. A typical additive is a polymer having a fluoroalcohol group. After spin coating, the polymer segregates toward the resist surface to reduce the surface energy, thereby improving water slip. Such additives are described in JP-A 2007-297590 and JP-A 2008-122932.

Exposure is preferably carried out so as to provide an exposure dose of about 1 to 200 mJ/cm², more preferably about 10 to 100 mJ/cm². This is followed by baking on a hot plate at 60 to 150° C. for 1 to 5 minutes, preferably at 80 to 120° C. for 1 to 3 minutes (post-exposure baking=PEB).

Thereafter the resist film is developed with a developer in the form of an aqueous alkaline solution, for example, an aqueous solution of 0.1 to 5 wt %, preferably 2 to 3 wt % tetramethylammonium hydroxide (TMAH) for 0.1 to 3 minutes, preferably 0.5 to 2 minutes by conventional techniques such as dip, puddle or spray techniques. In this way, a desired resist pattern is formed on the substrate.

With respect to the second resist pattern, the second resist composition is coated, exposed and developed in a standard way. In one preferred embodiment, the second resist pattern is formed in an area where features of the first resist pattern are not formed, thereby reducing the distance between pattern features to one half. The conditions of exposure and development and the thickness of the second resist film may be the same as described above.

Next, using the inactivated first resist film and the second resist film as a mask, the intermediate intervening layer of hard mask or the like is etched, and the processable layer further etched. For etching of the intermediate intervening layer of hard mask or the like, dry etching with fluorocarbon or halogen gases may be used. For etching of the processable layer, the etching gas and conditions may be properly chosen so as to establish an etching selectivity relative to the hard mask, and specifically, dry etching with fluorocarbon, halogen, oxygen, hydrogen or similar gases may be used. Thereafter, the first and second resist films are removed. Removal of these films may be carried out after etching of the intermediate intervening layer of hard mask or the like. It is noted that removal of the crosslinked resist film may be achieved by dry etching with oxygen or radicals and removal of the second resist film may be achieved as previously described, or using strippers such as amines, sulfuric acid/aqueous hydrogen peroxide or organic solvents.

### EXAMPLE

Examples of the invention are given below by way of illustration and not by way of limitation. The abbreviations used herein are GPC for gel permeation chromatography, Mw for weight average molecular weight, Mn for number average molecular weight, Mw/Mn for molecular weight distribution or dispersity, NMR for nuclear magnetic resonance, PGMEA for propylene glycol monomethyl ether acetate, and TMAH for tetramethylammonium hydroxide. For all polymers, Mw and Mn are determined by GPC versus polystyrene standards.

### Synthesis Examples

Polymers to be used in resist compositions were prepared by combining various monomers, effecting copolymerization reaction in tetrahydrofuran medium, crystallization in methanol, repeatedly washing with hexane, isolation, and drying. The resulting polymers (Polymers 1 to 22) had the composition shown below. The composition of each polymer was analyzed by ¹H-NMR, and the Mw and Mw/Mn determined by GPC.

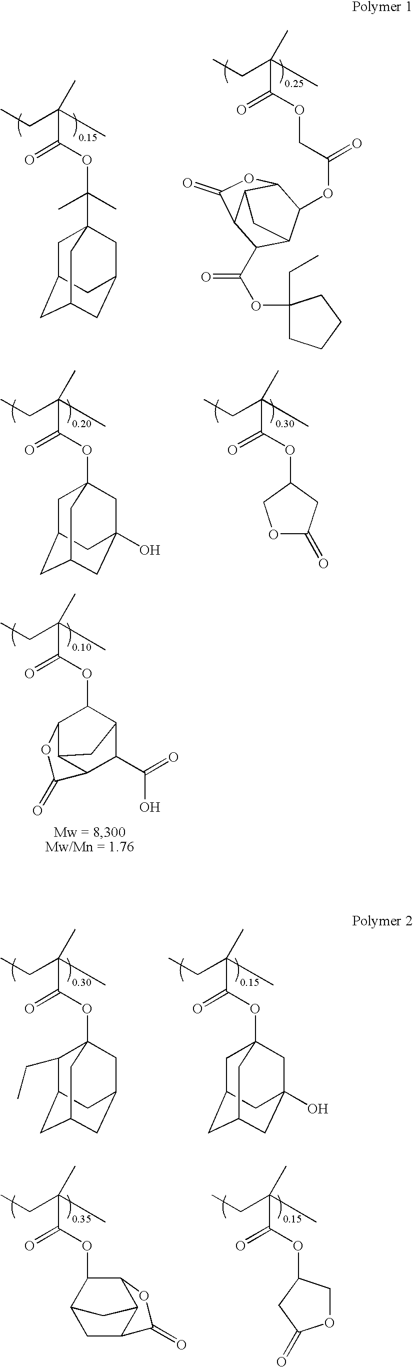

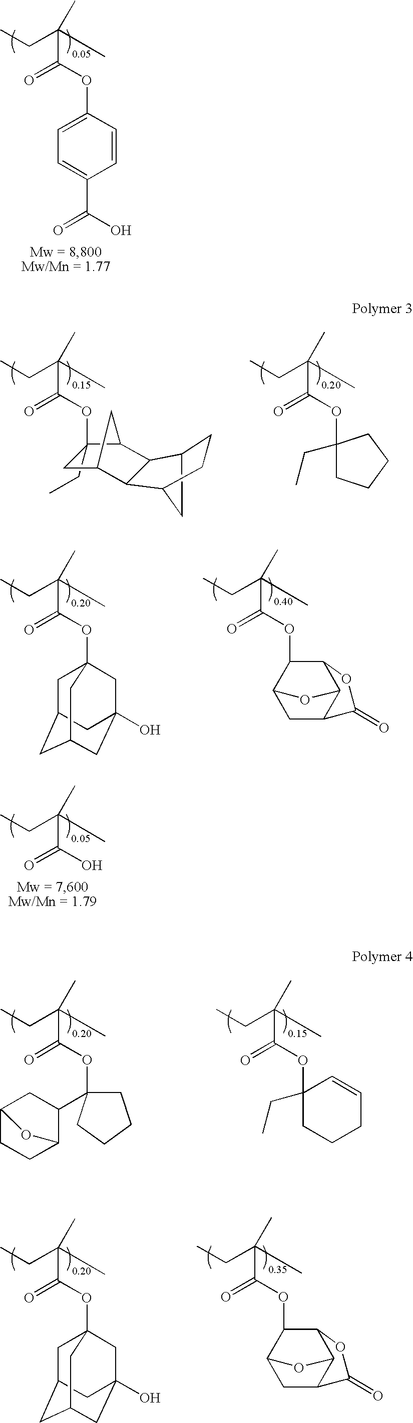

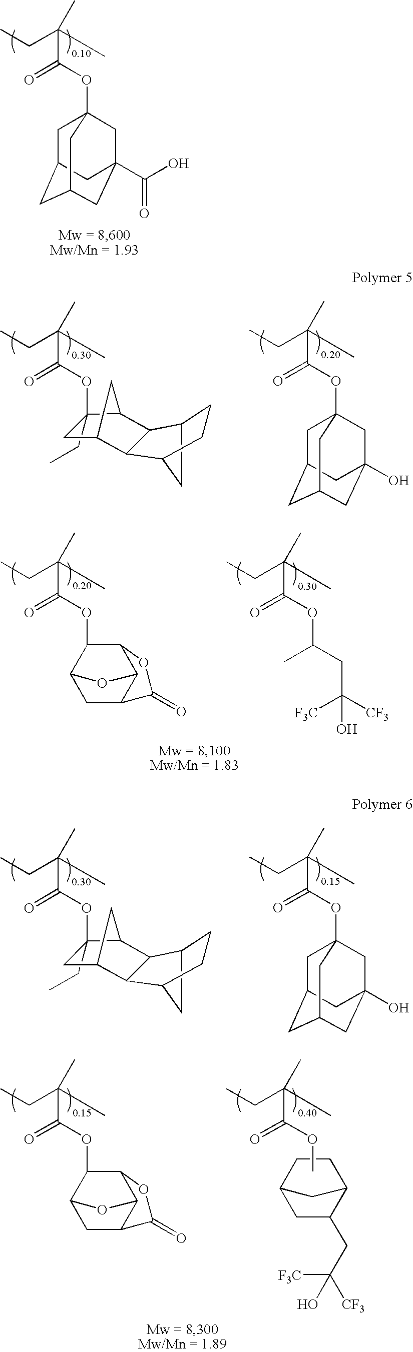

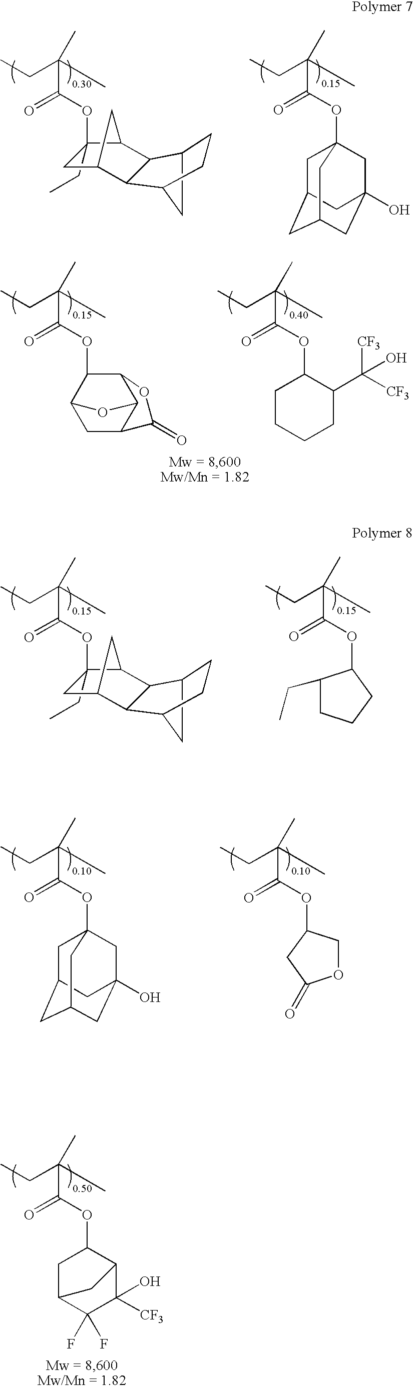

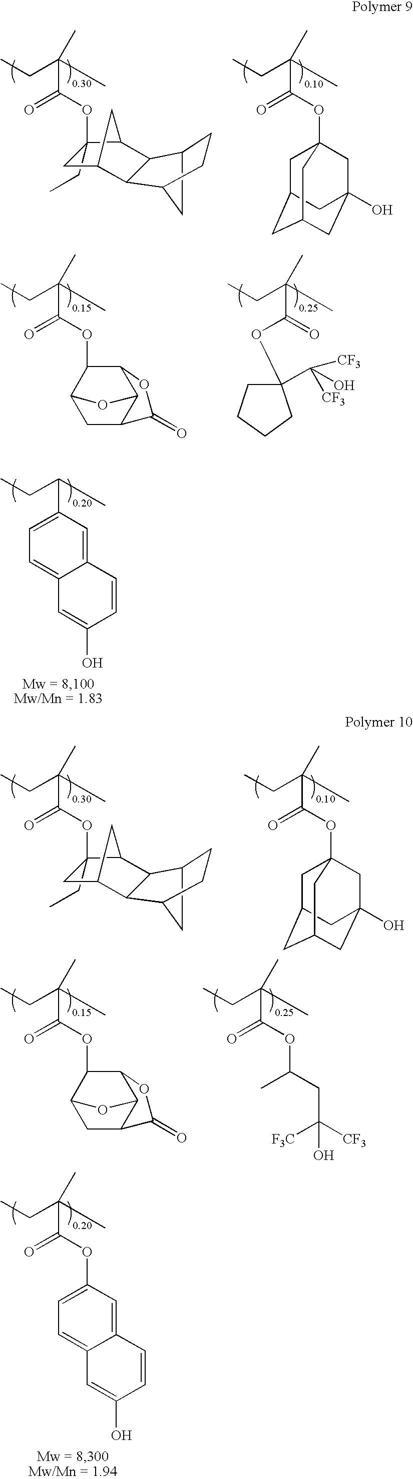

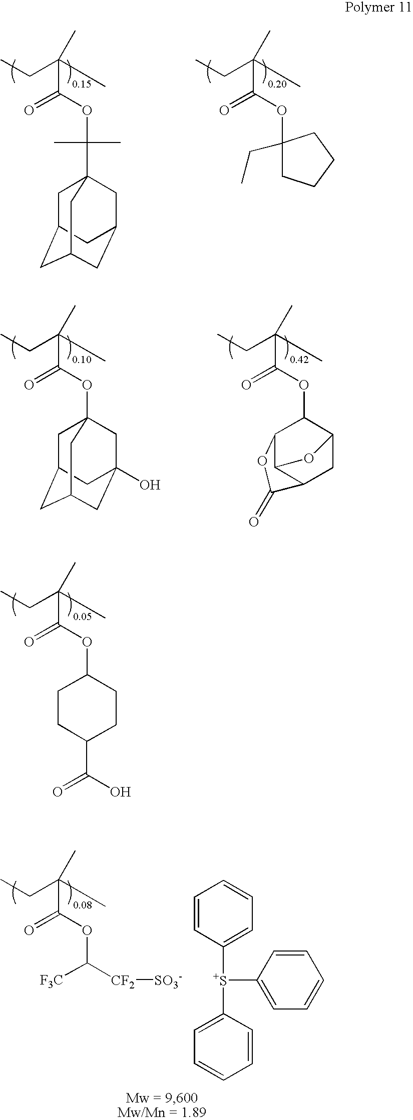

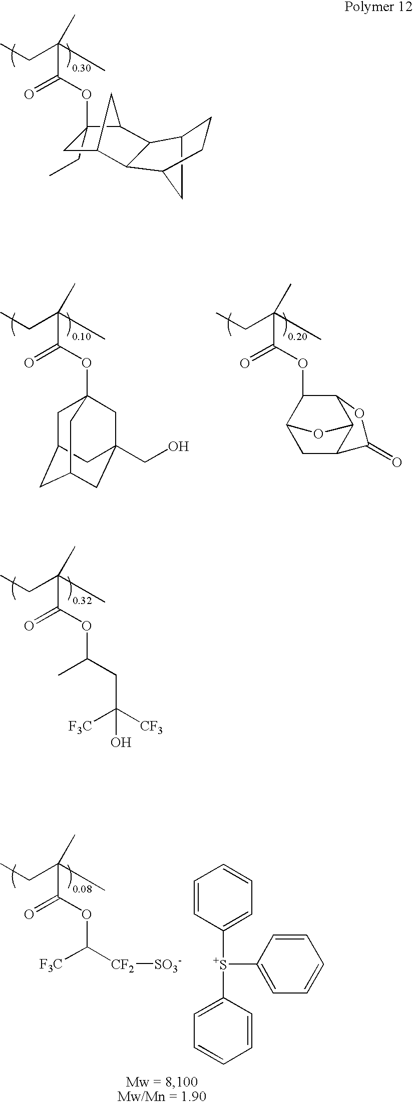

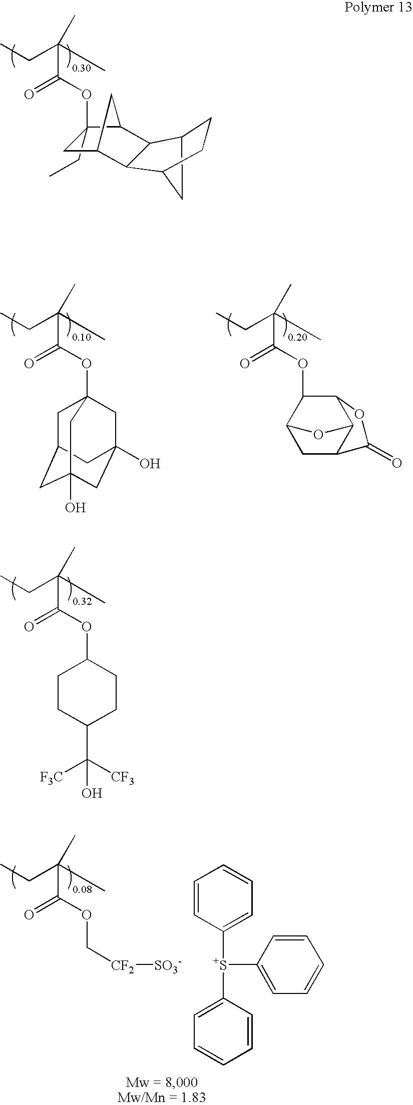

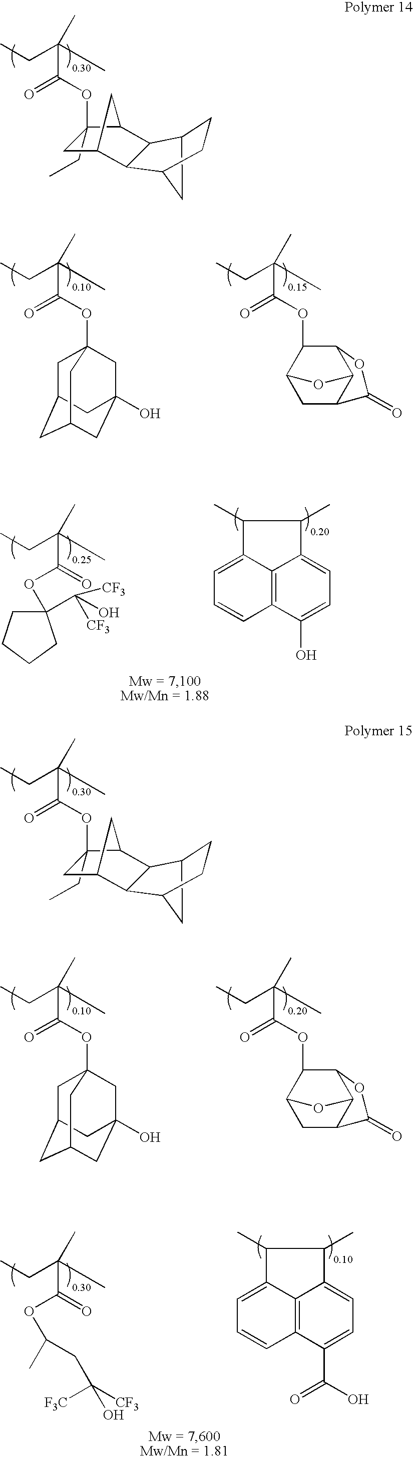

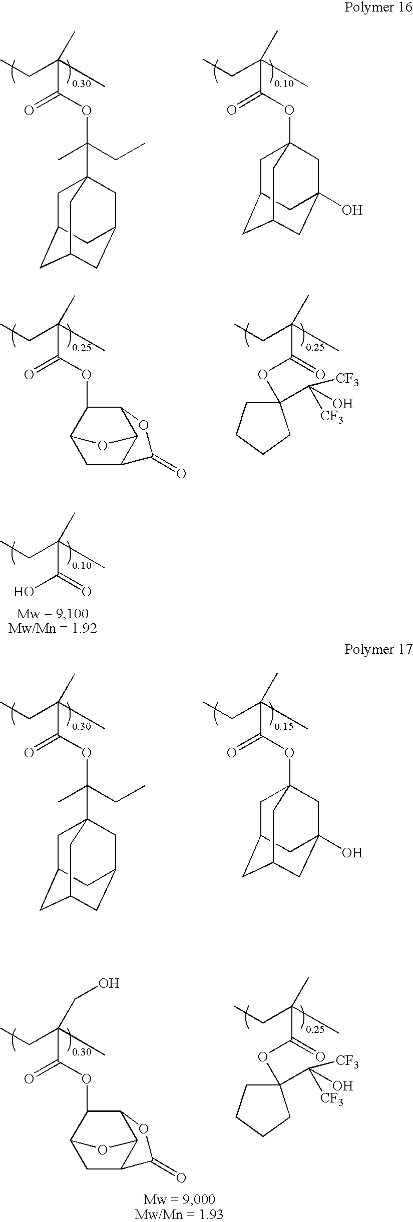

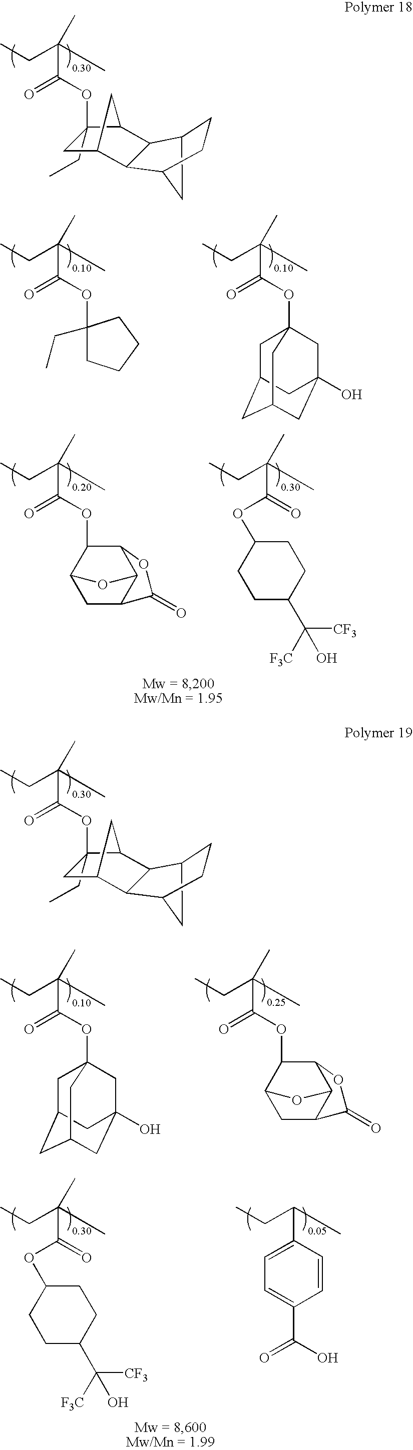

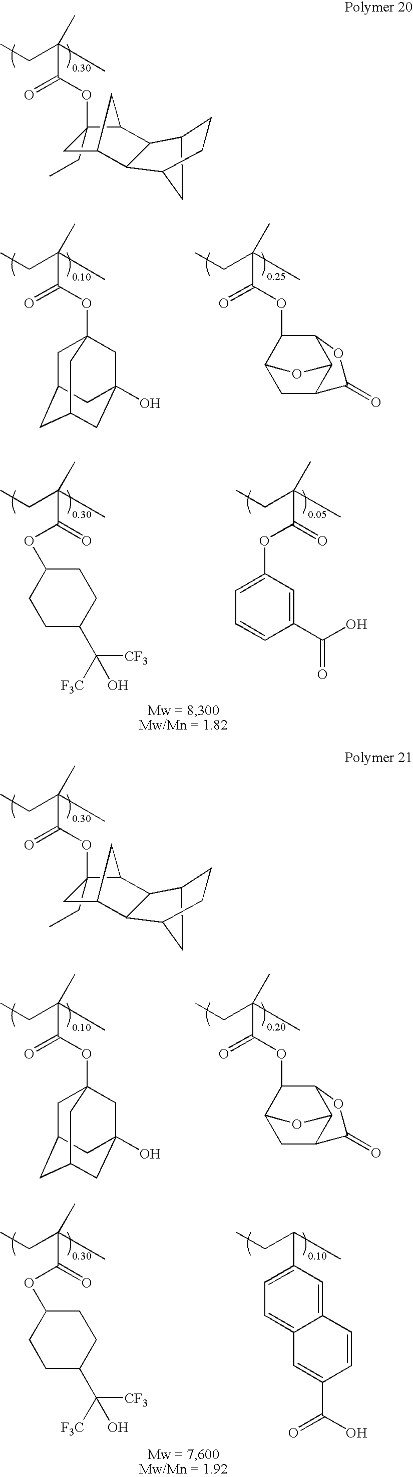

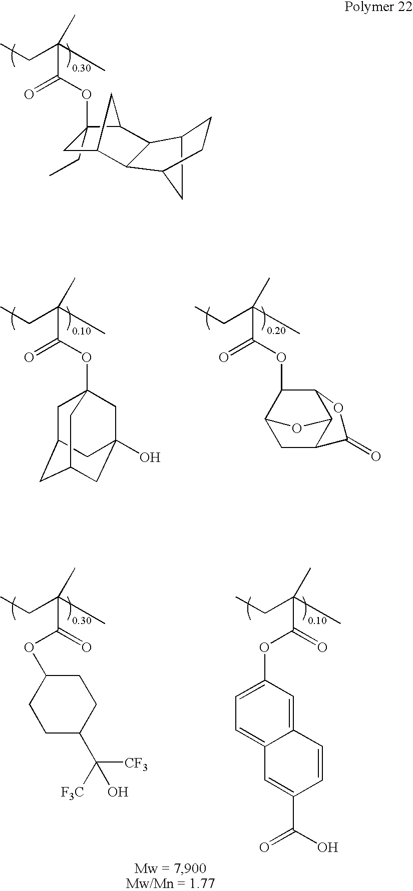

### Preparation of First Resist Composition

A resist solution was prepared by dissolving each polymer (Polymers 1 to 4, 11), an acid generator, a basic compound (or amine quencher), and a repellent (for rendering the resist film surface water repellent) in a solvent in accordance with the recipe shown in Table 1, and filtering through a Teflon® filter with a pore size of 0.2 μm. The solvent contained 50 ppm of surfactant FC-4430 (3M-Sumitomo Co., Ltd.).

The components in Table 1 are identified below.
Acid generator: PAG1 of the following structural formula

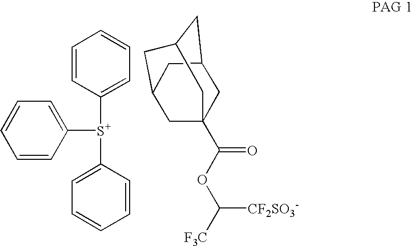

Basic compound: Quencher 1 of the following structural formula

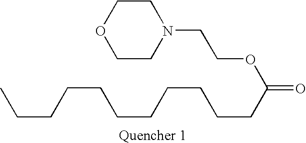

Repellent: Repellent Polymers 1 and 2 of the following formulae

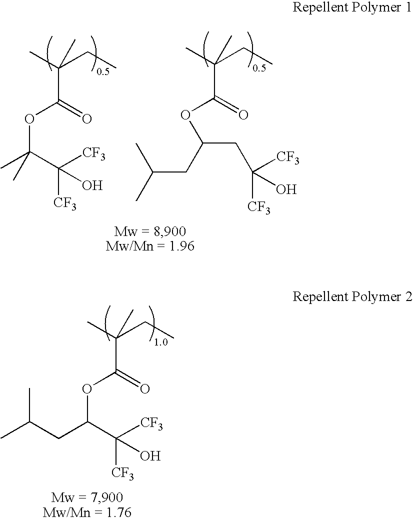

Organic solvent: PGMEA and cyclohexanone (CyH)

TABLE 1

| | | | Acid | Basic | | Organic |
|---|---|---|---|---|---|---|
| | | Polymer | generator | compound | Repellent | solvent |
| | | (pbw) | (pbw) | (pbw) | (pbw) | (pbw) |
| Resist | 1-1 | Polymer 1 | PAG1 | Quencher 1 | Repellent | PGMEA(1,500) |
| | | (100) | (14.0) | (1.60) | Polymer 1 | CyH(500) |
| | | | | | (3.0) | |
| | 1-2 | Polymer 2 | PAG1 | Quencher 1 | Repellent | PGMEA(1,500) |
| | | (100) | (14.0) | (1.60) | Polymer 1 | CyH(500) |
| | | | | | (3.0) | |
| | 1-3 | Polymer 3 | PAG1 | Quencher 1 | Repellent | PGMEA(1,500) |
| | | (100) | (14.0) | (1.60) | Polymer 2 | CyH(500) |
| | | | | | (3.0) | |
| | 1-4 | Polymer 4 | PAG1 | Quencher 1 | Repellent | PGMEA(1,500) |
| | | (100) | (14.0) | (1.60) | Polymer 1 | CyH(500) |
| | | | | | (3.0) | |
| | 1-5 | Polymer 11 | — | Quencher 1 | Repellent | PGMEA(1,500) |
| | | (100) | | (1.60) | Polymer 1 | CyH(500) |
| | | | | | (3.0) | |

### Preparation of Second Resist Composition

A resist solution was prepared by dissolving each polymer (Polymers 5 to 10, 12 to 22), an acid generator, a basic compound, and a repellent (for rendering the resist film surface water repellent) in a solvent in accordance with the recipe shown in Table 2, and filtering through a Teflon® filter with a pore size of 0.2 μm. The solvent contained 50 ppm of surfactant FC-4430 (3M-Sumitomo Co., Ltd.).

TABLE 2

| | | | Acid | Basic | | |
|---|---|---|---|---|---|---|
| | | Polymer | generator | compound | Repellent | Organic solvent |
| | | (pbw) | (pbw) | (pbw) | (pbw) | (pbw) |
| Resist | 2-1 | Polymer 5 | PAG1 | Quencher 1 | Repellent | 4-methyl-2-pentanol (2,100) |
| | | (100) | (14.0) | (1.60) | Polymer 1 | |
| | | | | | (3.0) | |
| | 2-2 | Polymer 6 | PAG1 | Quencher 1 | Repellent | 3-methyl-1-butanol (2,100) |
| | | (100) | (14.0) | (1.60) | Polymer 1 | |
| | | | | | (3.0) | |
| | 2-3 | Polymer 7 | PAG1 | Quencher 1 | Repellent | 2-methyl-1-butanol (1,500) |
| | | (100) | (14.0) | (1.60) | Polymer 1 | diisoamyl ether (800) |
| | | | | | (3.0) | |
| | 2-4 | Polymer 8 | PAG1 | Quencher 1 | Repellent | isobutyl alcohol (800) |
| | | (100) | (14.0) | (1.60) | Polymer 1 | 4-methyl-2-pentanol (1,300) |
| | | | | | (3.0) | |
| | 2-5 | Polymer 9 | PAG1 | Quencher 1 | Repellent | 3-methyl-3-pentanol (1,800) |
| | | (100) | (14.0) | (1.60) | Polymer 1 | diisoamyl ether (400) |
| | | | | | (3.0) | |
| | 2-6 | Polymer 10 | PAG1 | Quencher 1 | Repellent | 2-methyl-1-butanol (2,100) |
| | | (100) | (14.0) | (1.60) | Polymer 1 | |
| | | | | | (3.0) | |
| | 2-7 | Polymer 10 | PAG1 | Quencher 1 | Repellent | 2-methyl-1-butanol (1,900) |
| | | (100) | (14.0) | (1.60) | Polymer 1 | 1-hexanol (200) |
| | | | | | (3.0) | |
| | 2-8 | Polymer 10 | PAG1 | Quencher 1 | Repellent | 2-methyl-1-butanol (1,900) |
| | | (100) | (14.0) | (1.60) | Polymer 1 | 1-heptanol (200) |
| | | | | | (3.0) | |
| | 2-9 | Polymer 10 | PAG1 | Quencher 1 | Repellent | 2-methyl-1-butanol (2,000) |
| | | (100) | (14.0) | (1.60) | Polymer 1 | 1-octanol (100) |
| | | | | | (3.0) | |
| | 2-10 | Polymer 10 | PAG1 | Quencher 1 | Repellent | 2-methyl-1-butanol (1,700) |
| | | (100) | (14.0) | (1.60) | Polymer 1 | 2,6-dimethylanisole (400) |
| | | | | | (3.0) | |
| | 2-11 | Polymer 12 | — | Quencher 1 | Repellent | 2-methyl-1-butanol (1,700) |
| | | (100) | | (1.60) | Polymer 1 | 3,5-dimethylanisole (400) |
| | | | | | (3.0) | |
| | 2-12 | Polymer 13 | — | Quencher 1 | Repellent | 2-methyl-1-butanol (1,700) |
| | | (100) | | (1.60) | Polymer 1 | 2,4-dimethylanisole (400) |
| | | | | | (3.0) | |
| | 2-13 | Polymer 14 | PAG1 | Quencher 1 | Repellent | 2-methyl-1-butanol (1,700) |
| | | (100) | (14.0) | (1.60) | Polymer 1 | 4-ethylanisole (400) |
| | | | | | (3.0) | |
| | 2-14 | Polymer 15 | PAG1 | Quencher 1 | Repellent | 2-methyl-1-butanol (2,100) |
| | | (100) | (14.0) | (1.60) | Polymer 1 | |
| | | | | | (3.0) | |
| | 2-15 | Polymer 16 | PAG1 | Quencher 1 | Repellent | 2-methyl-1-butanol (2,100) |
| | | (100) | (14.0) | (1.60) | Polymer 1 | |
| | | | | | (3.0) | |
| | 2-16 | Polymer 17 | PAG1 | Quencher 1 | Repellent | 2-methyl-1-butanol (2,100) |
| | | (100) | (14.0) | (1.60) | Polymer 1 | |
| | | | | | (3.0) | |
| | 2-17 | Polymer 18 | PAG1 | Quencher 1 | Repellent | 2-methyl-1-butanol (2,100) |
| | | (100) | (14.0) | (1.60) | Polymer 1 | |
| | | | | | (3.0) | |
| | 2-18 | Polymer 19 | PAG1 | Quencher 1 | Repellent | 2-methyl-1-butanol (2,100) |
| | | (100) | (14.0) | (1.60) | Polymer 1 | |
| | | | | | (3.0) | |
| | 2-19 | Polymer 20 | PAG1 | Quencher 1 | Repellent | 2-methyl-1-butanol (1,700) |
| | | (100) | (14.0) | (1.60) | Polymer 1 | 1-heptanol (200) |
| | | | | | (3.0) | isobutyl alcohol (200) |
| | 2-20 | Polymer 21 | PAG1 | Quencher 1 | Repellent | 2-methyl-1-butanol (1,700) |
| | | (100) | (14.0) | (1.60) | Polymer 1 | 1-heptanol (200) |
| | | | | | (3.0) | isobutyl alcohol (200) |
| | 2-21 | Polymer 22 | PAG1 | Quencher 1 | Repellent | 2-methyl-1-butanol (1,700) |
| | | (100) | (14.0) | (1.60) | Polymer 1 | 1-heptanol (200) |
| | | | | | (3.0) | isobutyl alcohol (200) |

### Preparation of Pattern Overcoat Material

A coating solution was prepared by dissolving a polymer (Overcoat Polymers 1 to 4) and an amine or oxazoline in a solvent in accordance with the formulation of Table 3 and filtering through a Teflon® filter having a pore size of 0.2

Polyvinyl pyrrolidone with Mw=10,000 is available from Aldrich.

Overcoat Polymers were prepared by combining various monomers, effecting copolymerization reaction in tetrahydrofuran medium, crystallization in methanol, repeatedly washing with hexane, isolation, and drying. The resulting polymers (Overcoat Polymers 1 to 30) had the composition shown below. The composition of each polymer was analyzed by ¹H-NMR, and the Mw and Mw/Mn determined by GPC.

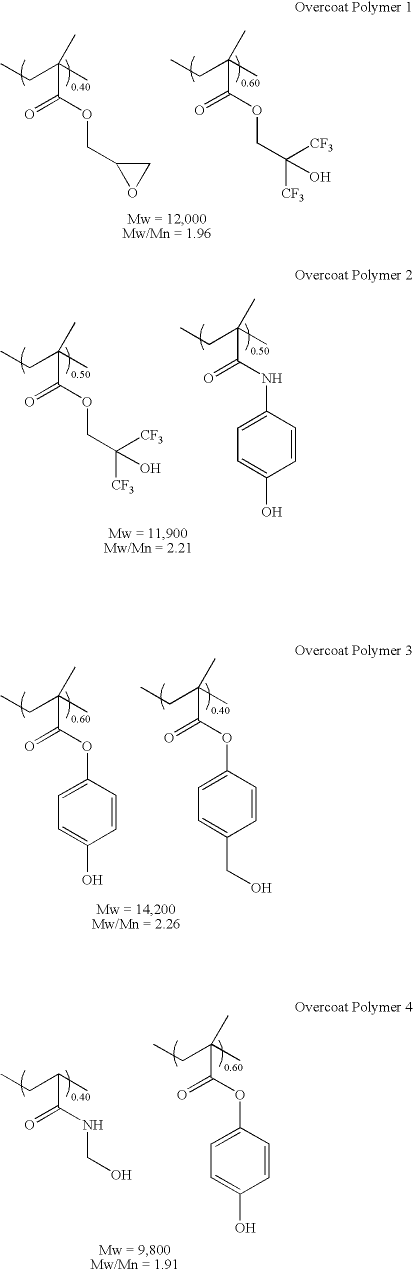

TABLE 3

| Overcoat | | Polymer | Basic compound | Organic solvent |
|---|---|---|---|---|
| material | | (pbw) | (pbw) | (pbw) |
| Overcoat | 1 | polyvinyl pyrrolidone | 1,3-bis(4,5-dihydro-2-oxazolyl)- | isobutyl alcohol (3,000) |
| | | (100) | benzene (15) | |
| | 2 | Overcoat Polymer 1 | 1,4-bis(4,5-dihydro-2-oxazolyl)- | isobutyl alcohol (3,000) |
| | | (100) | benzene (15) | |
| | 3 | Overcoat Polymer 2 | 2,2′-bis(2-oxazoline) (15) | isobutyl alcohol (3,000) |
| | | (100) | | |
| | 4 | Overcoat Polymer 3 | 1,4-bis(4,5-dihydro-2-oxazolyl)- | isobutyl alcohol (3,000) |
| | | (100) | benzene (15) | |
| | 5 | Overcoat Polymer 4 | 1,4-bis(4,5-dihydro-2-oxazolyl)- | isobutyl alcohol (3,000) |
| | | (100) | benzene (15) | |
| | 6 | — | 3-(2-aminoethylaminopropyl)- | isobutyl alcohol (1,000) |
| | | | triethoxysilane (10) | water (500) |
| | 7 | polyvinyl pyrrolidone | hexamethylenetetramine (10) | isobutyl alcohol (3,000) |
| | | (100) | | |
| | 8 | polyvinyl pyrrolidone | ethylenediamine (10) | isobutyl alcohol (3,000) |
| | | (100) | | |
| | 9 | polyvinyl pyrrolidone | triethanolamine (10) | isobutyl alcohol (3,000) |
| | | (100) | | water (300) |
| | 10 | polyvinyl pyrrolidone | DBU (10) | isobutyl alcohol (3,000) |
| | | (100) | | |
| | 11 | polyvinyl pyrrolidone | Amine 1 (10) | isobutyl alcohol (3,000) |
| | | (100) | | |
| | 12 | polyvinyl pyrrolidone | Amine 2 (10) | isobutyl alcohol (3,000) |
| | | (100) | | |
| | 13 | polyvinyl pyrrolidone | Amine 3 (10) | isobutyl alcohol (3,000) |
| | | (100) | | |
| | 14 | polyvinyl pyrrolidone | Amine 4 (10) | isobutyl alcohol (3,000) |
| | | (100) | | |
| | 15 | polyvinyl pyrrolidone | Amine 5 (10) | isobutyl alcohol (3,000) |
| | | (100) | | |
| | 16 | polyvinyl pyrrolidone | Amine 6 (10) | isobutyl alcohol (3,000) |
| | | (100) | | |
| | 17 | polyvinyl pyrrolidone | Amine 7 (10) | isobutyl alcohol (3,000) |
| | | (100) | | |
| | 18 | polyvinyl pyrrolidone | tris(3-aminopropyl)amine (10) | isobutyl alcohol (3,000) |
| | | (100) | | |
| | 19 | polyvinyl pyrrolidone | 4,9-dioxa-1,12-dodecanediamine (10) | isobutyl alcohol (3,000) |
| | | (100) | | |
| | 20 | — | 1,3-propanediamine (10) | isoamyl ether (2,000) |
| | 21 | — | ethylenediamine (10) | 4-methyl-2-pentanol (2,000) |
| | 22 | — | N,N′-dimethyl-1,3-propanediamine (10) | isoamyl ether (2,000) |
| | 23 | — | N,N-dimethyl-1,3-propanediamine (10) | isoamyl ether (2,000) |
| | 24 | — | ethylenediamine (10) | 4-methyl-2-pentanol (2,000) |
| | 25 | — | N,N′-dimethyl-1,3-propanediamine (10) | isoamyl ether (2,000) |
| | 26 | — | N,N-dimethyl-1,3-propanediamine (10) | isoamyl ether (2,000) |
| | 27 | — | N-methylethylenediamine (5) | isoamyl ether (2,000) |
| | 28 | — | N-methyl-1,3-diaminopropane (5) | isoamyl ether (2,000) |
| | 29 | — | N,N′-dimethylethylenediamine (5) | isoamyl ether (2,000) |
| | 30 | — | 2,2′-diaminoethylamine (5) | isoamyl ether (2,000) |
| | 31 | — | hydrazine (10) | isoamyl ether (700) |
| | | | | 2-methyl-1-butanol (300) |
| | 32 | — | hydrazine hydrate (10) | isoamyl ether (700) |
| | | | | 2-methyl-1-butanol (300) |
| | 33 | — | methylhydrazine (20) | isoamyl ether (700) |
| | | | | 2-methyl-1-butanol (300) |
| | 34 | — | hydrazine (5) | isoamyl ether (700) |
| | | | ethylenediamine (5) | 2-methyl-1-butanol (300) |

The components in Table 3 are identified below.

DBU: 1,8-diazabicyclo[5.4.0]-7-undecene

### Amines 1 to 7:

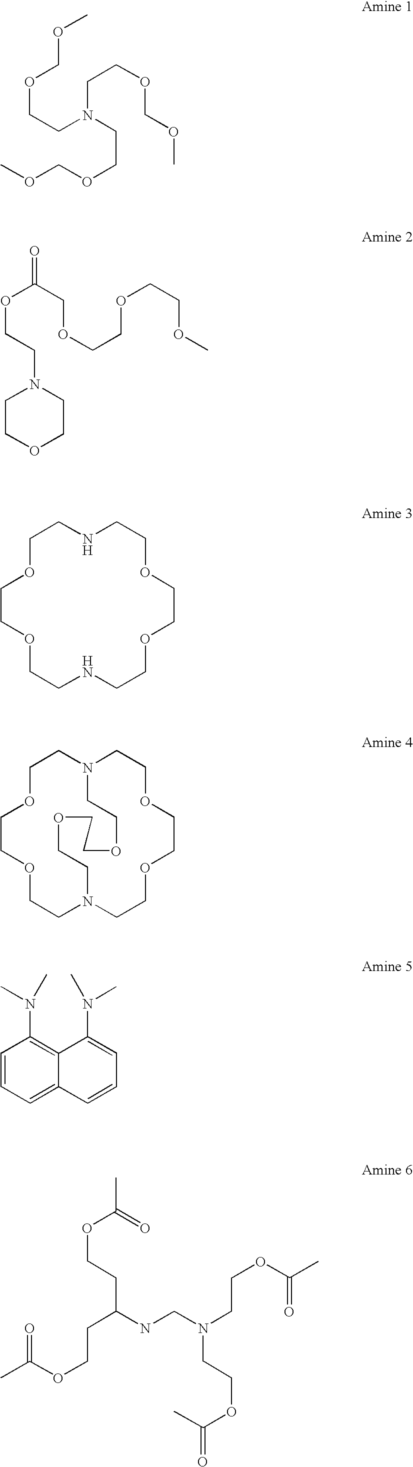

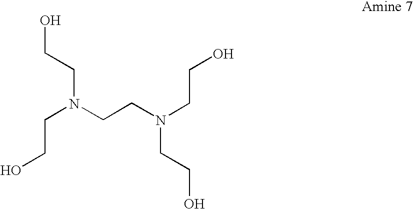

### Slimming of First Resist Film by Solvent

Each of the first resist compositions shown in Table 1 was coated on a silicon wafer and baked at 100° C. for 60 seconds to form a resist film of 100 nm thick. A solvent (shown in Table 4) was statically dispensed on the resist film for 20 seconds, followed by spin drying and baking at 100° C. for 60 seconds for evaporating off the solvent. The thickness of the resist film was measured for determining a film thickness reduction (slimming) before and after solvent dispensing. The results are shown in Table 4.

TABLE 4

| | | | Slimming |
|---|---|---|---|
| | | Solvent (weight ratio) | (nm) |
| Resist | 1-1 | 4-methyl-2-pentanol | 1.6 |
| | 1-1 | 3-methyl-1-butanol | 1.5 |
| | 1-1 | 2-methyl-1-butanol:diisoamyl ether = 8:2 | 0.6 |
| | 1-1 | isobutyl alcohol:4-methyl-2-pentanol = 4:6 | 1.4 |
| | 1-1 | 3-methyl-1-butanol:4-allylanisole = 9:1 | 0.5 |
| | 1-1 | 1-heptanol:2,3,5-trimethylanisole = 9:1 | 0.6 |
| | 1-1 | 2-methyl-1-butanol:2-pentanol:di-n-butyl | 0.7 |
| | | ether = 7:2:1 | |
| | 1-1 | 2-methyl-1-butanol:2-heptanol:4- | 0.6 |
| | | methoxytoluene = 7:2:1 | |
| | 1-1 | 2-methyl-1-butanol:2-hexanol:2- | 0.9 |
| | | ethylanisole = 6:2:2 | |
| | 1-1 | 1-heptanol:di-n-hexyl ether = 8:2 | 0.8 |
| | 1-1 | 2-methyl-1-butanol:n-butyl phenyl ether = 9:1 | 0.6 |
| | 1-1 | 2-methyl-1-butanol:isobutyl | 1.4 |
| | | alcohol:n-pentanol = 7:2:1 | |
| | 1-1 | 2-methyl-1-butanol:4-ethylanisole = 8:2 | 1.0 |
| | 1-1 | 2-methyl-1-butanol:4-ethylphenetole = 9:1 | 0.6 |
| | 1-1 | 2-methyl-1-butanol:3,5-dimethylanisole = 8:2 | 0.6 |
| | 1-1 | 2-methyl-1-butanol:2,6-dimethylanisole = 8:2 | 0.5 |
| | 1-1 | 2-methyl-1-butanol:2,4-dimethylanisole = 8:2 | 0.4 |
| | 1-1 | PGMEA | 100 |
| | 1-1 | cyclohexanone | 100 |
| | 1-1 | 2-methyl-1-butanol | 1.5 |
| | 1-2 | 2-methyl-1-butanol | 1.6 |
| | 1-3 | 2-methyl-1-butanol | 2.1 |
| | 1-4 | 2-methyl-1-butanol | 2.5 |
| | 1-5 | 2-methyl-1-butanol | 2.1 |

It was demonstrated that Resists 1-1 to 1-5 were insoluble in the alcohol solvents and alcohol/ether mixed solvents.

### Examples and Comparative Examples

### Double Patterning Test I

A coater/developer system (Clean Track Mark 8, Tokyo Electron Ltd.) has a tank which is usually charged with hexamethyldisilazane (HMDS) for improving adhesion to silicon substrates. The tank was charged with a vapor priming reagent in liquid or solution form as listed in Table 5. The system was designed such as to bubble nitrogen gas into the reagent liquid or solution, to fill the tank with the reagent vapor-containing gas, and to spray the gas over the wafer.

On a substrate (silicon wafer) having an antireflective coating (ARC-29A, Nissan Chemical Industries Ltd.) of 80 nm thick, each of the first resist compositions shown in Table 1 was spin coated, then baked on a hot plate at 100° C. for 60 seconds to form a resist film of 100 nm thick. Using an ArF excimer laser scanner model NSR-S610C (Nikon Corp., NA 1.30, σ 0.98/0.78, 35° cross-pole illumination, 6% halftone phase shift mask) with azimuthally polarized illumination, the coated substrate was exposed to a Y-direction 40-nm line/160-nm pitch pattern. Immediately after exposure, the resist film was baked (PEB) at 100° C. for 60 seconds and then developed for 30 seconds with a 2.38 wt % TMAH aqueous solution, obtaining a first line-and-space pattern having a line-to-space ratio of 1:3 and a line size of 40 nm.

In Examples 1-1 to 1-4 and Comparative Examples 1-1, 1-2, the first resist pattern-bearing substrate was irradiated with ArF excimer laser of 193 nm wavelength in a dose of 100 mJ/cm², after which the vapor obtained by bubbling nitrogen into the reagent solution shown in Tables 6 and 7 was sprayed over the substrate at 23° C. for 60 seconds. The excess amine compound was evaporated off by baking at 120° C. for 60 seconds. In Examples 1-5 to 1-12, the first pattern-bearing substrate was irradiated under a high-pressure mercury lamp at a power of 250 W for 30 seconds in Example 1-5; with KrCl excimer light of 222 nm wavelength in a dose of 100 mJ/cm² in Example 1-6; or under a metal halide lamp at a power of 250 W for 30 seconds in Examples 1-7 to 1-12. Thereafter, the vapor obtained by bubbling nitrogen into the reagent solution shown in Tables 6 and 7 was sprayed over the substrate at 23° C. for 90 seconds. The excess amine compound was evaporated off by baking at 130° C. for 60 seconds.

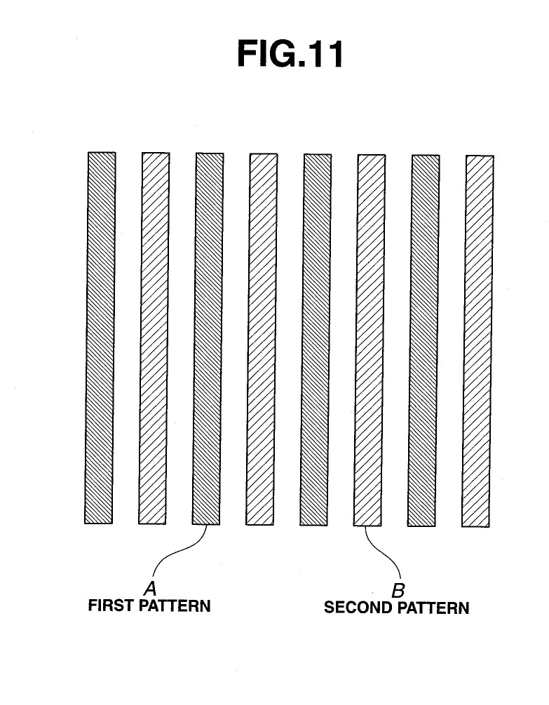

Next, each of the second resist compositions was coated onto the first resist pattern-bearing substrate and baked at 100° C. for 60 seconds. Using an ArF excimer laser scanner model NSR-S610C (Nikon Corp., NA 1.30, σ0.98/0.78, 35° cross-pole illumination, 6% halftone phase shift mask) with azimuthally polarized illumination, the coated substrate was exposed to a Y-direction 40-nm line/160-nm pitch pattern which was shifted 80 nm from the first pattern in X-direction. Immediately after exposure, the second resist film was baked (PEB) at 85° C. for 60 seconds and then developed for 30 seconds with a 2.38 wt % TMAH aqueous solution, obtaining a second line-and-space pattern having a line size of 40 nm. There were formed parallel extending first pattern lines A and second pattern lines B as illustrated in FIG. 11. The line width of the first and second patterns was measured by a measuring SEM (S-9380, Hitachi, Ltd.). The results are also shown in Table 5.

TABLE 5

| | | | | | | Size of | |
|---|---|---|---|---|---|---|---|
| | | | | | | 1st | |
| | | | | | | pattern | |
| | | | | | Size of | after | |
| | | | | | 1st | formation | |
| | | 1st | | 2nd | pattern | of | Size of |
| | | resist | | resist | as | 2nd | 2nd |
| | | composition | Vapor priming reagent | composition | developed | pattern | pattern |
| Example | 1-1 | Resist | n-butylamine | Resist | 41 nm | 30 nm | 40 nm |
| | | 1-1 | | 2-1 | | | |
| | 1-2 | Resist | ethylenediamine:isobutyl | Resist | 40 nm | 41 nm | 45 nm |
| | | 1-1 | alcohol = 2:8 | 2-1 | | | |
| | 1-3 | Resist | 2-isopropyl-2-oxazoline:isobutyl | Resist | 40 nm | 40 nm | 41 nm |
| | | 1-1 | alcohol = 2:8 | 2-1 | | | |
| | 1-4 | Resist | 1,3-propanediamine:dibutyl | Resist | 40 nm | 40 nm | 41 nm |
| | | 1-1 | ether = 2:8 | 2-1 | | | |
| | 1-5 | Resist | N,N′-dimethyl-1,3-propane- | Resist | 40 nm | 40 nm | 41 nm |
| | | 1-1 | diamine:toluene = 2:8 | 2-1 | | | |
| | 1-6 | Resist | N,N-dimethyl-1,3-propane- | Resist | 40 nm | 40 nm | 41 nm |
| | | 1-1 | diamine | 2-1 | | | |
| | 1-7 | Resist | N-methylethylenediamine | Resist | 40 nm | 40 nm | 41 nm |
| | | 1-1 | | 2-11 | | | |
| | 1-8 | Resist | N-methyl-1,3-diaminopropane | Resist | 40 nm | 40 nm | 41 nm |
| | | 1-1 | | 2-12 | | | |
| | 1-9 | Resist | N,N′-dimethylethylenediamine | Resist | 40 nm | 40 nm | 41 nm |
| | | 1-1 | | 2-13 | | | |
| | 1-10 | Resist | 2,2′-diaminoethylamine | Resist | 40 nm | 40 nm | 41 nm |
| | | 1-1 | | 2-14 | | | |
| | 1-11 | Resist | 10 wt % ammonia in isopropyl | Resist | 40 nm | 40 nm | 41 nm |
| | | 1-1 | alcohol | 2-15 | | | |
| | 1-12 | Resist | hexamethylsilazane | Resist | 40 nm | 30 nm | 41 nm |
| | | 1-1 | | 2-16 | | | |
| Comparative | 1-1 | Resist | — | Resist | 40 nm | pattern | 41 nm |
| Example | | 1-1 | | 2-1 | | vanished | |
| | 1-2 | Resist | n-butylamine | Resist | 40 nm | pattern | 41 nm |
| | | 1-1 | | 1-1 | | vanished | |

### Double Patterning Test II

On a substrate (silicon wafer) having an antireflective coating (ARC-29A) of 80 nm thick, each of the first resist compositions shown in Table 1 was spin coated, then baked on a hot plate at 100° C. for 60 seconds to form a resist film of 100 nm thick. Using an ArF excimer laser scanner model NSR-S610C (Nikon Corp., NA 1.30, σ0.98/0.78, 35° cross-pole illumination, azimuthally polarized illumination, 6% halftone phase shift mask), the coated substrate was exposed to a Y-direction 40-nm line/160-nm pitch pattern. Immediately after exposure, the resist film was baked (PEB) at 100° C. for 60 seconds and then developed for 30 seconds with a 2.38 wt % TMAH aqueous solution, obtaining a first line-and-space pattern having a line size of 40 nm.

Each of the overcoat materials (Overcoats 1 to 30) shown in Table 3 was coated onto the first resist pattern-bearing substrate and baked at 120° C. for 60 seconds. In Examples 2-1, 2-6 to 2-29, and Comparative Example 2-1, the overcoat was stripped with deionized water. In Examples 2-2 to 2-5, the overcoat was developed with a 2.38 wt % TMAH aqueous solution for 10 seconds and rinsed with deionized water. In Example 2-30, the excess amine component was evaporated off during the baking step at 120° C., and stripping was unnecessary. In Examples 2-31 to 2-40, the first resist pattern was irradiated with ArF excimer laser in a dose of 100 mJ/cm², after which the overcoat material was coated and baked at 120° C. for 60 seconds. In Example 2-41, the first pattern was irradiated under a high-pressure mercury lamp at a power of 250 W for 30 seconds, after which the overcoat material was coated and baked at 120° C. for 60 seconds. In Example 2-42, the first pattern was irradiated under a metal halide lamp at a power of 250 W for 30 seconds, after which the overcoat material was coated and baked at 120° C. for 60 seconds. In Comparative Example 2-2, the overcoat material was coated, baked at 160° C. for 60 seconds, and developed with a 2.38 wt % TMAH aqueous solution for 10 seconds, followed by rinsing with deionized water. In Comparative Example 2-3, the overcoat material was coated, baked at 120° C. for 60 seconds, stripped with deionized water, and baked at 140° C. for 60 seconds.

Next, each of the second resist compositions shown in Table 2 was coated onto the first resist pattern-bearing substrate and baked at 100° C. for 60 seconds. Using an ArF excimer laser scanner model NSR-S610C (Nikon Corp., NA 1.30, σ0.98/0.78, 35° cross-pole illumination, azimuthally polarized illumination, 6% halftone phase shift mask), the coated substrate was exposed to a Y-direction 40-nm line/160-nm pitch pattern which was shifted 80 nm from the first pattern in X-direction. Immediately after exposure, the second resist film was baked (PEB) at 85° C. for 60 seconds and then developed for 30 seconds with a 2.38 wt % TMAH aqueous solution, obtaining a second line-and-space pattern having a line size of 40 nm. There were formed parallel extending first pattern lines A and second pattern lines B as illustrated in FIG. 11. The line width of the first and second patterns was measured by a measuring SEM (S-9380, Hitachi, Ltd.). The results are shown in Tables 6 and 7.

TABLE 6

| | | | | | | Size of | |
|---|---|---|---|---|---|---|---|
| | | | | | | 1st | |
| | | | | | | pattern | |
| | | | | | Size of | after | |
| | | | | | 1st | formation | |
| | | 1st | | 2nd | pattern | of | Size of |
| | | resist | Overcoat | resist | as | 2nd | 2nd |
| | | composition | material | composition | developed | pattern | pattern |
| Example | 2-1 | Resist 1-1 | Overcoat 1 | Resist 2-1 | 41 nm | 42 nm | 40 nm |
| | 2-2 | Resist 1-1 | Overcoat 2 | Resist 2-1 | 40 nm | 41 nm | 40 nm |
| | 2-3 | Resist 1-1 | Overcoat 3 | Resist 2-1 | 40 nm | 40 nm | 41 nm |
| | 2-4 | Resist 1-1 | Overcoat 4 | Resist 2-1 | 40 nm | 40 nm | 41 nm |
| | 2-5 | Resist 1-1 | Overcoat 5 | Resist 2-1 | 40 nm | 40 nm | 41 nm |
| | 2-6 | Resist 1-1 | Overcoat 6 | Resist 2-1 | 40 nm | 42 nm | 41 nm |
| | 2-7 | Resist 1-1 | Overcoat 7 | Resist 2-1 | 40 nm | 43 nm | 41 nm |
| | 2-8 | Resist 1-1 | Overcoat 8 | Resist 2-1 | 40 nm | 41 nm | 41 nm |
| | 2-9 | Resist 1-1 | Overcoat 9 | Resist 2-1 | 40 nm | 40 nm | 40 nm |
| | 2-10 | Resist 1-1 | Overcoat 10 | Resist 2-1 | 40 nm | 40 nm | 40 nm |
| | 2-11 | Resist 1-1 | Overcoat 11 | Resist 2-1 | 40 nm | 41 nm | 41 nm |
| | 2-12 | Resist 1-1 | Overcoat 12 | Resist 2-1 | 40 nm | 40 nm | 41 nm |
| | 2-13 | Resist 1-1 | Overcoat 13 | Resist 2-1 | 40 nm | 41 nm | 41 nm |
| | 2-14 | Resist 1-1 | Overcoat 14 | Resist 2-1 | 40 nm | 40 nm | 41 nm |
| | 2-15 | Resist 1-1 | Overcoat 15 | Resist 2-1 | 40 nm | 43 nm | 41 nm |
| | 2-16 | Resist 1-1 | Overcoat 16 | Resist 2-1 | 40 nm | 40 nm | 42 nm |
| | 2-17 | Resist 1-1 | Overcoat 17 | Resist 2-1 | 40 nm | 42 nm | 41 nm |
| | 2-18 | Resist 1-1 | Overcoat 18 | Resist 2-1 | 40 nm | 40 nm | 40 nm |
| | 2-19 | Resist 1-2 | Overcoat 1 | Resist 2-1 | 40 nm | 41 nm | 40 nm |
| | 2-20 | Resist 1-3 | Overcoat 1 | Resist 2-2 | 40 nm | 41 nm | 40 nm |
| | 2-21 | Resist 1-4 | Overcoat 1 | Resist 2-3 | 40 nm | 40 nm | 39 nm |
| | 2-22 | Resist 1-5 | Overcoat 1 | Resist 2-4 | 40 nm | 42 nm | 39 nm |
| | 2-23 | Resist 1-1 | Overcoat 1 | Resist 2-5 | 40 nm | 41 nm | 39 nm |
| | 2-24 | Resist 1-1 | Overcoat 1 | Resist 2-6 | 40 nm | 40 nm | 41 nm |
| | 2-25 | Resist 1-1 | Overcoat 1 | Resist 2-7 | 40 nm | 40 nm | 41 nm |

TABLE 7

| | | | | | | Size of | |
|---|---|---|---|---|---|---|---|
| | | | | | | 1st | |
| | | | | | | pattern | |
| | | | | | Size of | after | |
| | | | | | 1st | formation | |
| | | 1st | | 2nd | pattern | of | Size of |
| | | resist | Overcoat | resist | as | 2nd | 2nd |
| | | composition | material | composition | developed | pattern | pattern |
| Example | 2-26 | Resist 1-1 | Overcoat 1 | Resist 2-8 | 40 nm | 41 nm | 41 nm |
| | 2-27 | Resist 1-1 | Overcoat 1 | Resist 2-9 | 40 nm | 43 nm | 42 nm |
| | 2-28 | Resist 1-1 | Overcoat 1 | Resist 2-10 | 40 nm | 42 nm | 42 nm |
| | 2-29 | Resist 1-1 | Overcoat 19 | Resist 2-10 | 40 nm | 42 nm | 42 nm |
| | 2-30 | Resist 1-1 | Overcoat 20 | Resist 2-10 | 40 nm | 42 nm | 42 nm |
| | 2-31 | Resist 1-1 | Overcoat 21 | Resist 2-1 | 41 nm | 41 nm | 40 nm |
| | 2-32 | Resist 1-1 | Overcoat 22 | Resist 2-1 | 40 nm | 41 nm | 40 nm |
| | 2-33 | Resist 1-1 | Overcoat 23 | Resist 2-1 | 40 nm | 40 nm | 41 nm |
| | 2-34 | Resist 1-1 | Overcoat 24 | Resist 2-1 | 40 nm | 40 nm | 41 nm |
| | 2-35 | Resist 1-1 | Overcoat 25 | Resist 2-1 | 40 nm | 40 nm | 41 nm |
| | 2-36 | Resist 1-1 | Overcoat 26 | Resist 2-1 | 40 nm | 42 nm | 41 nm |
| | 2-37 | Resist 1-1 | Overcoat 27 | Resist 2-1 | 40 nm | 41 nm | 41 nm |
| | 2-38 | Resist 1-1 | Overcoat 28 | Resist 2-1 | 40 nm | 41 nm | 41 nm |
| | 2-39 | Resist 1-1 | Overcoat 29 | Resist 2-1 | 40 nm | 40 nm | 40 nm |
| | 2-40 | Resist 1-1 | Overcoat 30 | Resist 2-1 | 40 nm | 40 nm | 40 nm |
| | 2-41 | Resist 1-1 | Overcoat 20 | Resist 2-1 | 40 nm | 41 nm | 41 nm |
| | 2-42 | Resist 1-1 | Overcoat 20 | Resist 2-1 | 40 nm | 40 nm | 41 nm |
| Comparative | 2-1 | Resist 1-1 | Overcoat 1 | Resist 1-1 | 40 nm | pattern | 41 nm |
| Example | | | | | | vanished | |
| | 2-2 | Resist 1-1 | Overcoat 2 | Resist 1-1 | 40 nm | 30 nm | 41 nm |
| | 2-3 | Resist 1-1 | Overcoat 6 | Resist 1-1 | 40 nm | 52 nm | 41 nm |

It is seen from the data in Tables 6 and 7 that in Examples, the first pattern remained dimensionally unchanged after the second pattern was formed. In Comparative Examples, the first pattern vanished or was dimensionally thickened or thinned.

### Double Patterning Test III

On a substrate (silicon wafer) having an antireflective coating (ARC-29A) of 80 nm thick, each of the first resist compositions shown in Table 1 was spin coated, then baked on a hot plate at 100° C. for 60 seconds to form a resist film of 100 nm thick. Using an ArF excimer laser scanner model NSR-S610C (Nikon Corp., NA 1.30, σ0.98/0.78, 20° dipole illumination, 6% halftone phase shift mask) with s-polarized illumination, the coated substrate was exposed to a X-direction 40-nm line-and-space pattern. Immediately after exposure, the resist film was baked (PEB) at 100° C. for 60 seconds and then developed for 30 seconds with a 2.38 wt % TMAH aqueous solution, obtaining a first line-and-space pattern having a line size of 40 nm.

Each of the overcoat materials (Overcoats 1 to 30) shown in Table 3 was coated onto the first resist pattern-bearing substrate and baked at 120° C. for 60 seconds. In Examples 3-1, 3-6 to 3-19, 3-21 to 3-26, the overcoat was stripped with deionized water. In Examples 3-2 to 3-5, the overcoat was developed with a 2.38 wt % TMAH aqueous solution for 10 seconds and rinsed with deionized water. In Example 3-20, the excess amine component was evaporated off during the baking step at 120° C., and stripping was unnecessary. In Examples 3-27 to 3-36, the first resist pattern-bearing substrate was irradiated with ArF excimer laser in a dose of 100 mJ/cm², after which the overcoat material was coated and baked at 120° C. for 60 seconds. In Example 3-37, the first pattern was irradiated under a high-pressure mercury lamp at a power of 250 W for 30 seconds, after which the overcoat material was coated and baked at 120° C. for 60 seconds. In Example 3-38, the first pattern was irradiated under a metal halide lamp at a power of 250 W for 30 seconds, after which the overcoat material was coated and baked at 120° C. for 60 seconds. In Examples 3-39 to 3-53, irradiation was omitted, and the overcoat material was coated and baked at 140° C. for 60 seconds.

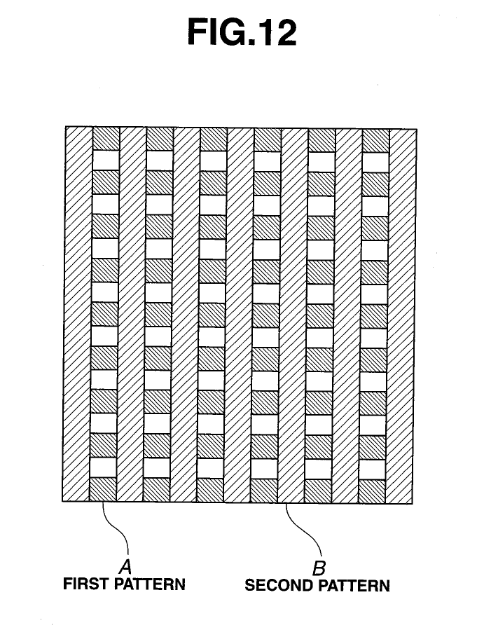

Next, each of the second resist compositions shown in Table 2 was coated onto the first resist pattern-bearing substrate and baked at 100° C. for 60 seconds. Using an ArF excimer laser scanner model NSR-S610C (Nikon Corp., NA 1.30, σ0.98/0.78, 20° dipole illumination, 6% halftone phase shift mask) with s-polarized illumination, the coated substrate was exposed to a Y-direction 40-nm line-and-space pattern. Immediately after exposure, the second resist film was baked (PEB) at 85° C. for 60 seconds and then developed for 30 seconds with a 2.38 wt % TMAH aqueous solution, obtaining a second line-and-space pattern having a line size of 40 nm. There were formed orthogonally crossing first pattern lines A and second pattern lines B as illustrated in FIG. 12. The line width of the first and second patterns was measured by a measuring SEM (S-9380, Hitachi, Ltd.). The results are shown in Tables 8 and 9.

TABLE 8

| | | | | | | Size of | |
|---|---|---|---|---|---|---|---|
| | | | | | | 1st | |
| | | | | | | pattern | |
| | | | | | Size of | after | |
| | | | | | 1st | formation | |
| | | 1st | | 2nd | pattern | of | Size of |
| | | resist | Overcoat | resist | as | 2nd | 2nd |
| | | composition | material | composition | developed | pattern | pattern |
| Example | 3-1 | Resist 1-1 | Overcoat 1 | Resist 2-1 | 41 nm | 42 nm | 40 nm |
| | 3-2 | Resist 1-1 | Overcoat 2 | Resist 2-1 | 40 nm | 41 nm | 40 nm |
| | 3-3 | Resist 1-1 | Overcoat 3 | Resist 2-1 | 40 nm | 43 nm | 41 nm |
| | 3-4 | Resist 1-1 | Overcoat 4 | Resist 2-1 | 40 nm | 42 nm | 41 nm |
| | 3-5 | Resist 1-1 | Overcoat 5 | Resist 2-1 | 40 nm | 42 nm | 41 nm |
| | 3-6 | Resist 1-1 | Overcoat 6 | Resist 2-1 | 40 nm | 42 nm | 40 nm |
| | 3-7 | Resist 1-1 | Overcoat 7 | Resist 2-1 | 40 nm | 42 nm | 41 nm |
| | 3-8 | Resist 1-1 | Overcoat 8 | Resist 2-1 | 40 nm | 42 nm | 41 nm |
| | 3-9 | Resist 1-1 | Overcoat 9 | Resist 2-1 | 40 nm | 42 nm | 40 nm |
| | 3-10 | Resist 1-1 | Overcoat 10 | Resist 2-1 | 40 nm | 43 nm | 39 nm |
| | 3-11 | Resist 1-1 | Overcoat 11 | Resist 2-1 | 40 nm | 43 nm | 40 nm |
| | 3-12 | Resist 1-1 | Overcoat 12 | Resist 2-1 | 40 nm | 42 nm | 40 nm |
| | 3-13 | Resist 1-1 | Overcoat 13 | Resist 2-1 | 40 nm | 43 nm | 41 nm |
| | 3-14 | Resist 1-1 | Overcoat 14 | Resist 2-1 | 40 nm | 42 nm | 41 nm |
| | 3-15 | Resist 1-1 | Overcoat 15 | Resist 2-1 | 40 nm | 42 nm | 40 nm |
| | 3-16 | Resist 1-1 | Overcoat 16 | Resist 2-1 | 40 nm | 44 nm | 40 nm |
| | 3-17 | Resist 1-1 | Overcoat 17 | Resist 2-1 | 40 nm | 43 nm | 41 nm |
| | 3-18 | Resist 1-1 | Overcoat 18 | Resist 2-1 | 40 nm | 43 nm | 39 nm |
| | 3-19 | Resist 1-1 | Overcoat 19 | Resist 2-1 | 40 nm | 42 nm | 39 nm |
| | 3-20 | Resist 1-1 | Overcoat 20 | Resist 2-1 | 40 nm | 30 nm | 38 nm |
| | 3-21 | Resist 1-1 | Overcoat 1 | Resist 2-11 | 41 nm | 42 nm | 40 nm |
| | 3-22 | Resist 1-1 | Overcoat 1 | Resist 2-12 | 41 nm | 42 nm | 40 nm |
| | 3-23 | Resist 1-1 | Overcoat 1 | Resist 2-13 | 41 nm | 42 nm | 41 nm |
| | 3-24 | Resist 1-1 | Overcoat 1 | Resist 2-14 | 42 nm | 42 nm | 42 nm |
| | 3-25 | Resist 1-1 | Overcoat 1 | Resist 2-15 | 43 nm | 42 nm | 42 nm |
| | 3-26 | Resist 1-1 | Overcoat 1 | Resist 2-16 | 43 nm | 42 nm | 42 nm |
| | 3-27 | Resist 1-1 | Overcoat 21 | Resist 2-1 | 41 nm | 42 nm | 40 nm |
| | 3-28 | Resist 1-1 | Overcoat 22 | Resist 2-1 | 41 nm | 42 nm | 40 nm |
| | 3-29 | Resist 1-1 | Overcoat 23 | Resist 2-1 | 41 nm | 42 nm | 41 nm |
| | 3-30 | Resist 1-1 | Overcoat 24 | Resist 2-1 | 42 nm | 42 nm | 42 nm |
| | 3-31 | Resist 1-1 | Overcoat 25 | Resist 2-1 | 43 nm | 42 nm | 42 nm |
| | 3-32 | Resist 1-1 | Overcoat 26 | Resist 2-1 | 43 nm | 42 nm | 42 nm |
| | 3-33 | Resist 1-1 | Overcoat 27 | Resist 2-1 | 41 nm | 42 nm | 40 nm |
| | 3-34 | Resist 1-1 | Overcoat 28 | Resist 2-1 | 41 nm | 42 nm | 40 nm |
| | 3-35 | Resist 1-1 | Overcoat 29 | Resist 2-1 | 41 nm | 42 nm | 41 nm |
| | 3-36 | Resist 1-1 | Overcoat 30 | Resist 2-1 | 42 nm | 42 nm | 42 nm |
| | 3-37 | Resist 1-1 | Overcoat 21 | Resist 2-1 | 43 nm | 42 nm | 40 nm |
| | 3-38 | Resist 1-1 | Overcoat 21 | Resist 2-1 | 43 nm | 41 nm | 42 nm |

TABLE 9

| | | | | | | Size of | |
|---|---|---|---|---|---|---|---|
| | | | | | | 1st | |
| | | | | | | pattern | |
| | | | | | Size of | after | |
| | | | | | 1st | formation | |
| | | 1st | | 2nd | pattern | of | Size of |
| | | resist | Overcoat | resist | as | 2nd | 2nd |
| | | composition | material | composition | developed | pattern | pattern |
| Example | 3-39 | Resist 1-1 | Overcoat 20 | Resist 2-1 | 41 nm | 39 nm | 40 nm |
| | 3-40 | Resist 1-1 | Overcoat 21 | Resist 2-1 | 40 nm | 39 nm | 40 nm |
| | 3-41 | Resist 1-1 | Overcoat 22 | Resist 2-1 | 40 nm | 36 nm | 41 nm |
| | 3-42 | Resist 1-1 | Overcoat 23 | Resist 2-1 | 40 nm | 36 nm | 41 nm |
| | 3-43 | Resist 1-1 | Overcoat 24 | Resist 2-1 | 40 nm | 37 nm | 41 nm |
| | 3-44 | Resist 1-1 | Overcoat 25 | Resist 2-1 | 40 nm | 36 nm | 40 nm |
| | 3-45 | Resist 1-1 | Overcoat 26 | Resist 2-1 | 40 nm | 35 nm | 41 nm |
| | 3-46 | Resist 1-1 | Overcoat 27 | Resist 2-1 | 40 nm | 35 nm | 41 nm |
| | 3-47 | Resist 1-1 | Overcoat 28 | Resist 2-1 | 40 nm | 35 nm | 40 nm |
| | 3-48 | Resist 1-1 | Overcoat 29 | Resist 2-1 | 40 nm | 36 nm | 40 nm |
| | 3-49 | Resist 1-1 | Overcoat 30 | Resist 2-1 | 40 nm | 36 nm | 40 nm |
| | 3-50 | Resist 1-1 | Overcoat 31 | Resist 2-1 | 40 nm | 39 nm | 40 nm |
| | 3-51 | Resist 1-1 | Overcoat 32 | Resist 2-1 | 40 nm | 39 nm | 41 nm |
| | 3-52 | Resist 1-1 | Overcoat 33 | Resist 2-1 | 40 nm | 37 nm | 41 nm |
| | 3-53 | Resist 1-1 | Overcoat 34 | Resist 2-1 | 40 nm | 37 nm | 40 nm |

In the patterning processes of Examples 1-1 to 1-12 and 2-1 to 2-42, the formation of a second resist pattern having lines located between lines of the first resist pattern was observed.

In Comparative Examples 1-2 and 2-1, a second resist pattern was formed, but the first resist pattern did not exist because it had been dissolved away upon coating of the second resist material.

In Comparative Example 1-1, the first resist pattern was dissolved in the developer as a result of deprotection of the protective group by the acid generated when the first pattern was also exposed to light for the second resist pattern exposure (see Table 5).

In Comparative Example 2-2, the size of the first resist pattern was thinned due to thermal deformation. In Comparative Example 2-3, the size of the first resist pattern after formation of the second resist pattern was thickened due to intermixing of the first and second resist patterns.

In the patterning processes of Examples 3-1 to 3-53, the formation of a second resist pattern having lines crossing lines of the first resist pattern was observed.

### Evaluation of Water Slip

A contact angle with water of the resist film was measured, using an inclination contact angle meter prop Master 500 by Kyowa Interface Science Co., Ltd. Specifically, the wafer covered with the resist film was kept horizontal, and 50 μL of pure water was dropped on the resist film to form a droplet. While the wafer was gradually inclined, the angle (sliding angle) at which the droplet started sliding down was determined as well as the receding contact angle. The results are shown in Table 10.

TABLE 10

| 1st resist | 2nd resist | Sliding angle | Receding contact angle |
|---|---|---|---|
| composition | composition | (°) | (°) |
| Resist 1-1 | | 14 | 75 |
| Resist 1-3 | | 12 | 77 |
| | Resist 2-1 | 24 | 64 |
| | Resist 2-2 | 25 | 63 |
| | Resist 2-3 | 18 | 70 |
| | Resist 2-6 | 25 | 63 |
| | Resist 2-7 | 18 | 72 |
| | Resist 2-8 | 17 | 73 |
| | Resist 2-9 | 16 | 74 |
| | Resist 2-10 | 17 | 72 |
| | Resist 2-13 | 17 | 72 |
| | Resist 2-21 | 16 | 74 |

A smaller sliding angle indicates an easier flow of water on the resist film. A larger receding contact angle indicates that fewer liquid droplets are left during high-speed scan exposure. The first resist compositions using PGMEA-based solvents and the second resist compositions using high-boiling alcohols or alcohol/ether mixtures are improved in water slip as demonstrated by a receding contact angle of at least 70 degrees.

While the invention has been described with reference to a preferred embodiment, it will be understood by those skilled in the art that various changes may be made and equivalents may be substituted for elements thereof without departing from the scope of the invention. Therefore, it is intended that the invention not be limited to the particular embodiment disclosed as the best mode contemplated for carrying out this invention, but that the invention will include all embodiments falling within the scope of the appended claims.

Japanese Patent Application Nos. 2008-325000 and 2009-100954 are incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A process for forming a pattern, comprising the steps of:
coating a first positive resist composition comprising a copolymer comprising recurring units having lactone as an adhesive group and recurring units having an acid labile group onto a substrate to form a first resist film, exposing the first resist film to high-energy radiation, post-exposure baking, and developing the first resist film with a developer to form a first resist pattern,
applying an amine or oxazoline compound to the first resist pattern to inactivate it to acid,
coating a second positive resist composition comprising a solvent which contains an alcohol of 3 to 8 carbon atoms and an optional ether of 6 to 12 carbon atoms and which does not dissolve away the first resist pattern onto the first resist pattern-bearing substrate to form a second resist film, exposing the second resist film to high-energy radiation, post-exposure baking, and developing the second resist film with a developer to form a second resist pattern.

2. A process for forming a pattern according to claim 1, comprising the steps of:
coating a first positive resist composition comprising a copolymer comprising recurring units having lactone as an adhesive group and recurring units having an acid labile group onto a substrate to form a first resist film, exposing the first resist film to high-energy radiation, post-exposure baking, and developing the first resist film with a developer to form a first resist pattern,
applying an amine or oxazoline compound to the first resist pattern to inactivate it to acid and baking to remove the excess amine or oxazoline compound,
coating a second positive resist composition comprising a solvent which contains an alcohol of 3 to 8 carbon atoms and an optional ether of 6 to 12 carbon atoms and which does not dissolve away the first resist pattern onto the first resist pattern-bearing substrate to form a second resist film, exposing the second resist film to high-energy radiation, post-exposure baking, and developing the second resist film with a developer to form a second resist pattern.

3. A process for forming a pattern according to claim 1, comprising the steps of:
coating a first positive resist composition comprising a copolymer comprising recurring units having lactone as an adhesive group and recurring units having an acid labile group onto a substrate to form a first resist film, exposing the first resist film to high-energy radiation, post-exposure baking, and developing the first resist film with a developer to form a first resist pattern,
applying an amine or oxazoline compound to the first resist pattern to inactivate it to acid, baking, and applying a solution selected from the group consisting of water, aqueous alkaline developer, an alcohol of 3 to 8 carbon atoms and an ether of 6 to 12 carbon atoms to remove the excess amine or oxazoline compound,
coating a second positive resist composition comprising a solvent which contains an alcohol of 3 to 8 carbon atoms and an optional ether of 6 to 12 carbon atoms and which does not dissolve away the first resist pattern onto the first resist pattern-bearing substrate to form a second resist film, exposing the second resist film to high-energy radiation, post-exposure baking, and developing the second resist film with a developer to form a second resist pattern.

4. The process of claim 1 wherein the step of applying an amine or oxazoline compound to the first resist pattern includes spin coating a solution containing the amine or oxazoline compound onto the first resist pattern to inactivate it to acid.

5. The process of claim 1 wherein the step of applying an amine or oxazoline compound to the first resist pattern includes spraying a vapor containing the amine or oxazoline compound to the first resist pattern to inactivate it to acid.

6. The process of claim 1, further comprising the step of irradiating the first resist pattern with radiation having a wavelength of 140 to 400 nm, prior to the step of applying an amine or oxazoline compound to the first resist pattern to inactivate it to acid.

7. The process of claim 1 wherein the first resist pattern includes spaces where no pattern features are formed, and the second resist pattern is formed in the spaces of the first resist pattern, thereby reducing the distance between the first and second pattern features.

8. The process of claim 1 wherein the first resist pattern crosses the second resist pattern.

9. The process of claim 1 wherein the second resist pattern is formed in an area where the first resist pattern is not formed and in a different direction from the first resist pattern.

10. The process of claim 1 wherein one or both of the exposure steps to form the first and second resist patterns are by immersion lithography using water.

11. The process of claim 1 wherein said second positive resist composition comprises a base polymer having a 2,2,2-trifluoro-1-hydroxyethyl group.

12. The process of claim 11 wherein the base polymer in said second positive resist composition comprises recurring units having a 2,2,2-trifluoro-1-hydroxyethyl group, represented by the general formula (1): 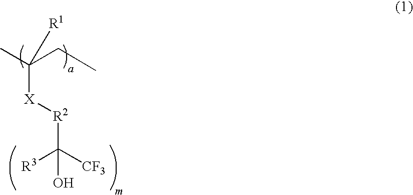
wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², and m is 1 or 2.

13. The process of claim 11 wherein the base polymer in said second positive resist composition is a copolymer comprising recurring units (a) having a 2,2,2-trifluoro-1-hydroxyethyl group and recurring units (b) having an acid labile group, represented by the general formula (2): 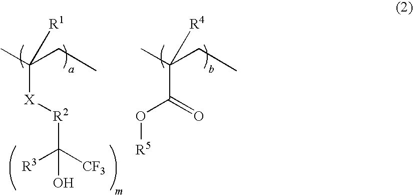
wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², R⁴ is hydrogen or methyl, R⁵ is an acid labile group, m is 1 or 2, a and b are numbers in the range: 0<a<1.0, 0<b<1.0, and 0<a+b≦1.0.

14. The process of claim 11 wherein the base polymer in said second positive resist composition is a copolymer comprising recurring units (a) having a 2,2,2-trifluoro-1-hydroxyethyl group, recurring units (b) having an acid labile group, and recurring units (c−1) having a hydroxynaphthyl group, represented by the general formula (3): 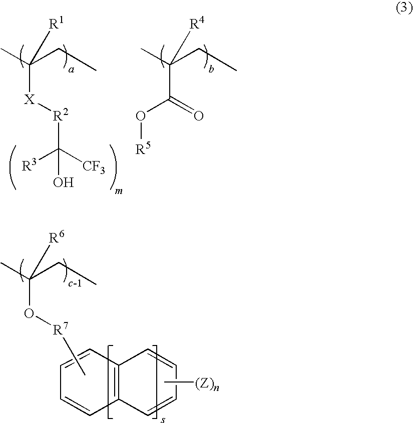
wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², R⁴ is hydrogen or methyl, R⁵ is an acid labile group, R⁶ is hydrogen or methyl, Y is a single bond or —C(═O)—O—, R⁷ is a single bond or a straight or branched C₁-C₆ alkylene group, m and n each are 1 or 2, s is 0 or 1, Z is hydroxy or carboxyl, a, b and c−1 are numbers in the range: 0<a<1.0, 0<b<1.0, 0<(c−1)<1.0, and 0<a+b+(c−1)≦1.0.

15. The process of claim 11 wherein the base polymer in said second positive resist composition is a copolymer comprising recurring units (a) having a 2,2,2-trifluoro-1-hydroxyethyl group, recurring units (b) having an acid labile group, and recurring units (c−2) derived from hydroxyacenaphthylene, represented by the general formula (4): 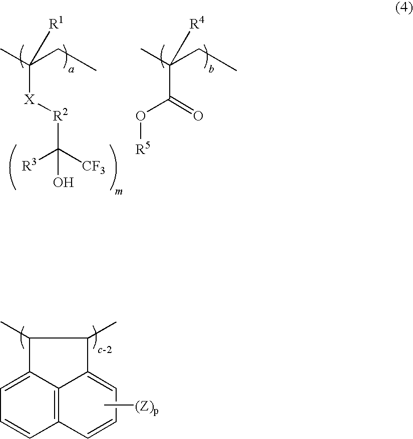
wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², R⁴ is hydrogen or methyl, R⁵ is an acid labile group, m and p each are 1 or 2, Z is hydroxy or carboxyl, a, b and c−2 are numbers in the range: 0<a<1.0, 0<b<1.0, 0<(c−2)<1.0, and 0<a+b+(c−2)≦1.0.

16. The process of claim 11 wherein the alcohol of 3 to 8 carbon atoms is selected from the group consisting of n-propanol, isopropyl alcohol, 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2,2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, 1-heptanol, cyclohexanol, and octanol, and mixtures of two or more of the foregoing.

17. The process of claim 11 wherein the ether of 6 to 12 carbon atoms is selected from the group consisting of methyl cyclopentyl ether, methyl cyclohexyl ether, diisopropyl ether, diisobutyl ether, diisopentyl ether, di-n-pentyl ether, methyl cyclopentyl ether, methyl cyclohexyl ether, di-n-butyl ether, di-sec-butyl ether, di-sec-pentyl ether, di-tert-amyl ether, di-n-hexyl ether, anisole, 2-methylanisole, 3-methylanisole, 4-methylanisole, 2,3-dimethylanisole, 2,4-dimethylanisole, 3,4-dimethylanisole, 2,5-dimethylanisole, 2,6-dimethylanisole, 3,5-dimethylanisole, 3,6-dimethylanisole, 2,3,4-trimethylanisole, 2,3,6-trimethylanisole, 2,4,6-trimethylanisole, 2,4,5,6-tetramethylanisole, 2-ethylanisole, 3-ethylanisole, 4-ethylanisole, 2-isopropylanisole, 3-isopropylanisole, 4-isopropylanisole, 4-propylanisole, 2-butylanisole, 3-butylanisole, 4-butylanisole, 2-tert-butylanisole, 3-tert-butylanisole, 4-tert-butylanisole, pentamethylanisole, 2-vinylanisole, 3-vinylanisole, 4-methoxystyrene, ethyl phenyl ether, propyl phenyl ether, butyl phenyl ether, ethyl 3,5-xylyl ether, ethyl 2,6-xylyl ether, ethyl 2,4-xylyl ether, ethyl 3,4-xylyl ether, ethyl 2,5-xylyl ether, methyl benzyl ether, ethyl benzyl ether, isopropyl benzyl ether, propyl benzyl ether, methyl phenethyl ether, ethyl phenethyl ether, isopropyl phenethyl ether, propyl phenethyl ether, butyl phenethyl ether, vinyl phenyl ether, allyl phenyl ether, vinyl benzyl ether, allyl benzyl ether, vinyl phenethyl ether, allyl phenethyl ether, 4-ethylphenetole, and tert-butyl phenyl ether, and mixtures of two or more of the foregoing.

18. The process of claim 1 wherein in the second positive resist composition, the solvent which contains an alcohol of 3 to 8 carbon atoms and an optional ether of 6 to 12 carbon atoms and which does not dissolve away the first resist pattern is such that components of the second resist composition are dissolvable therein, and the first resist film experiences a slimming of not more than 10 nm when the solvent is dispensed on the first resist film for 30 seconds and then removed by spin drying and baking at a temperature not higher than 130° C.

19. A resist composition comprising a base resin and a solvent, wherein
the base resin is a copolymer comprising recurring units (a) having a 2,2,2-trifluoro-1-hydroxyethyl group and recurring units (b) having an acid labile group, represented by the general formula (2): 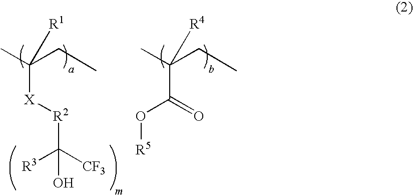
wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², R⁴ is hydrogen or methyl, R⁵ is an acid labile group, m is 1 or 2, a and b are numbers in the range: 0<a<1.0, 0<b<1.0, and 0<a+b≦1.0, and
the solvent contains 50 to 98% by weight of 2-methyl-1-butanol or 3-methyl-1-butanol and 2 to 50% by weight of 1-hexanol, 1-heptanol or 1-octanol.

20. A resist composition comprising a base resin and a solvent, wherein
the base resin is a copolymer comprising recurring units (a) having a 2,2,2-trifluoro-1-hydroxyethyl group and recurring units (b) having an acid labile group, represented by the general formula (2): 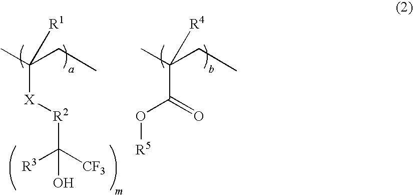
wherein R¹ is hydrogen or methyl, X is —O— or —C(═O)—O—, R² is a straight, branched or cyclic C₁-C₁₀ alkylene group which may contain an ester group, ether group or fluorine atom, or R² may bond with R³ to form a ring, R³ is hydrogen, C₁-C₆ alkyl or trifluoromethyl, or R³ is C₁-C₆ alkylene when it bonds with R², R⁴ is hydrogen or methyl, R⁵ is an acid labile group, m is 1 or 2, a and b are numbers in the range: 0<a<1.0, 0<b<1.0, and 0<a+b 1.0, and
the solvent contains 50 to 98% by weight of 2-methyl-1-butanol or 3-methyl-1-butanol and 2 to 50% by weight of an ether selected from the group consisting of anisole, 2-methylanisole, 3-methylanisole, 4-methylanisole, 2,3-dimethylanisole, 2,4-dimethylanisole, 3,4-dimethylanisole, 2,5-dimethylanisole, 2,6-dimethylanisole, 3,5-dimethylanisole, 3,6-dimethylanisole, 2,3,4-trimethylanisole, 2,3,6-trimethylanisole, 2,4,6-trimethylanisole, 2,4,5,6-tetramethylanisole, 2-ethylanisole, 3-ethylanisole, 4-ethylanisole, 2-isopropylanisole, 3-isopropylanisole, 4-isopropylanisole, 4-propylanisole, 2-butylanisole, 3-butylanisole, 4-butylanisole, 2-tert-butylanisole, 3-tert-butylanisole, 4-tert-butylanisole, pentamethylanisole, 2-vinylanisole, 3-vinylanisole, 4-methoxystyrene, ethyl phenyl ether, propyl phenyl ether, butyl phenyl ether, ethyl 3,5-xylyl ether, ethyl 2,6-xylyl ether, ethyl 2,4-xylyl ether, ethyl 3,4-xylyl ether, ethyl 2,5-xylyl ether, methyl benzyl ether, ethyl benzyl ether, isopropyl benzyl ether, propyl benzyl ether, methyl phenethyl ether, ethyl phenethyl ether, isopropyl phenethyl ether, propyl phenethyl ether, butyl phenethyl ether, vinyl phenyl ether, allyl phenyl ether, vinyl benzyl ether, allyl benzyl ether, vinyl phenethyl ether, allyl phenethyl ether, 4-ethylphenetole, and tert-butyl phenyl ether.
